(19) United States
(12) Patent Application Publication
(10) Pub. No.: US 2010/0230583 A1
(43) Pub. Date: Sep. 16, 2010

(54) SOLID STATE IMAGE PICKUP DEVICE, METHOD OF MANUFACTURING THE SAME, IMAGE PICKUP DEVICE, AND ELECTRONIC DEVICE

(75) Inventors: Masashi Nakata, Kanagawa (JP); Shinichiro Izawa, Kanagawa (JP); Kazuyoshi Yamashita, Kanagawa (JP)

Correspondence Address: SONNENSCHEIN NATH & ROSENTHAL LLP, P.O. BOX 061080, WACKER DRIVE STATION, WILLIS TOWER, CHICAGO, IL, 60606-1080, US

(73) Assignee: SONY CORPORATION, Tokyo (JP)

(21) Appl. No.: 12/729,295

(22) Filed: Mar. 23, 2010

(30) Foreign Application Priority Data
Nov. 6, 2008 (JP) 2008-285909
Mar. 30, 2009 (JP) 2009-081100
Oct. 19, 2009 (JP) 2009-240774

(51) Int. Cl. H01L 31/0232; H01L 31/18; H01L 27/146

(52) U.S. Cl. 250/227.2; 438/70; 257/432; 257/E31.127

(57) ABSTRACT

A solid state image pickup device includes a pixel section defined by unit pixels arrayed in line and row directions of a semiconductor substrate. Each of the unit pixels includes a photoelectric transducer that is formed on the semiconductor substrate and converts incident light into a signal charge, a waveguide that is formed above the photoelectric transducer and guides the incident light to the photoelectric transducer, and a microlens that is formed above the waveguide and guides the incident light to an end of light incident side of the waveguide. The waveguide has a columnar body with a constant cross section from the end of light incident side to an end of light exit side, and is arranged such that a center of rays of the incident light incident from the microlens on the end of light incident side of the waveguide is aligned with a central axis of the waveguide.

### BACKGROUND OF THE INVENTION

1. Field of the Invention

The present invention relates to a solid state image pickup device, a method of manufacturing the solid state image pickup device, an image pickup device, and an electronic device such as a camera including the solid state image pickup device.

2. Description of the Related Art

Solid state image pickup devices include an amplifying solid state image pickup device which is represented by, for example, a metal oxide semiconductor (MOS) image sensor, like a complementary metal oxide semiconductor (CMOS). Also, solid state image pickup devices include a charge-transfer solid state image pickup device which is represented by a charge coupled device (CCD) image sensor. These types of solid state image pickup devices are widely used in digital still cameras and digital video cameras. Since the supply voltage and power consumption of the MOS solid state image pickup device are low, the solid state image pickup devices are often used in mobile devices, such as a camera-equipped mobile phone and a personal digital assistant (PDA).

A typical MOS solid state image pickup device includes a plurality of arrayed unit pixels, each unit pixel having as a group a photo diode serving as a photoelectric transducer and a plurality of pixel transistors. In recent years, miniaturization in pixel size progresses. To decrease the number of pixel transistors per unit pixel and to increase the area of the photo diode, a MOS solid state image pickup device is developed, in which unit pixel groups are arrayed, each of the unit pixel groups having a pixel transistor shared by a plurality of pixels (see Japanese Unexamined Patent Application Publication Nos. 2006-54276 and 2009-135319).

Also, a solid state image pickup device is suggested, in which a waveguide that guides incident light to a corresponding photo diode to improve sensitivity characteristic (see Japanese Unexamined Patent Application Publication No. 2008-166677). Further, a solid state image pickup device is suggested, in which pupil correction is performed for an on chip lens to correct shading (Japanese Patent No. 2600250).

A solid state image pickup device includes a waveguide provided above a photo diode that photoelectrically converts incident light, and an on chip lens that guides incident light to the waveguide. In addition, a color filter layer is formed between the on chip lens and the waveguide. The color filter layer divides the incident light into, for example, color light including red (R) light, green (G) light, and blue (B) light. To decrease the effect of color aberration, the curvature radii of on chip lenses for the colors of RGB are adjusted. Further, the pupil correction amounts at high image height positions for the on chip lenses and the color filters are determined to become smaller than a lens chief ray angle (CRA), to decrease the effect of color aberration.

For example, when an on chip lens with a high chief ray angle (e.g., 25°) is used, color aberration at a high image height position may cause shading (difference between image focus positions (depths)) and color mixture to be generated.

When the method of adjusting the curvature radii of the on chip lenses depending on the color, like the related art, is used, the number of fabrication steps for the on chip lenses may be increased. As a pixel is further miniaturized, the curvature radius of an on chip lens is increased. It is difficult to adjust the curvature radii depending on the colors.

In a high incidence angle portion, the center of image formation (including F light) is deflected from the center of a photo diode to the optical center (e.g., toward the center of a pixel section). As a result, shading and color mixture are generated. In the related art, if the curvature radii of the on chip lenses are not adjusted depending on the colors, the spot diameters of incident light on ends of light incident side of the waveguides may vary depending on the colors due to color aberration. It is more difficult to perform correction to attain balanced positions for all colors as the pixel is further miniaturized. If the pupil correction amounts for the on chip lenses and the color filter layers vary depending on the colors, a gap or an overlapping portion may be generated. As a result, shading and color mixture may be generated. Owing to this, pupil correction is performed for the on chip lens and the color filter layer so as to efficiently condense even oblique light. Unfortunately, such a structure may still cause luminance shading, in which sensitivity is decreased in the periphery of an angular field, and color shading resulted from the difference in shape of shading among the respective colors, to occur.

A technique is disclosed for a waveguide that guides incident light to a photoelectric transducer even when the incidence angle of incident light is large. With the technique, an angular field is divided into four quadrants, and taper positions of waveguides are changed in accordance with the positions thereof in the four quadrants, so that the waveguides guide incident light at different incidence angles (for example, see Japanese Unexamined Patent Application Publication No. 2005-175234).

However, if even a part of a waveguide is tapered, the inventors have found that light which vertically enters the waveguide is reflected by an inclined surface in the tapered waveguide, and hence the sensitivity is decreased. Thus, even a part of the waveguide should not be tapered because the tapered shape results in the sensitivity being decreased. In addition, to form the waveguide with the tapered part, the number of processes and the number of masks are increased as compared with a case in which a normal waveguide is formed. Further, since this technique merely divides the angular field into the four quadrants and changes the shapes of the waveguides, the technique does not decrease the shading characteristic.

FIG. 1 illustrates an example of a MOS solid state image pickup device 1 of two-pixel-sharing type that two pixels share one floating diffusion, one amplifier transistor, and one select transistor, according to related art. The solid state image pickup device 1 includes a unit pixel group 2 of two-pixel-sharing type that two pixels share one floating diffusion, one amplifier transistor, and one select transistor. The unit pixel group 2 includes two photo diodes PD1 and PD2, two transfer transistors Tr11 and Tr12, a floating diffusion FD, a reset transistor Tr2, and an amplifier transistor Tr3. In this example, a color filter with the Bayer pattern is used. Unit pixel groups 2 of two-pixel-sharing type are arrayed such that a first green pixel Gb is arranged next to a blue pixel B, and a second green pixel Gr is arranged next to a red pixel R. In FIG. 1, a unit pixel group 2 of two-pixel-sharing type including the red pixel R and the first green pixel Gb, and a unit pixel group 2 of two-pixel-sharing type including the blue pixel B and the second green pixel Gr are repeatedly arrayed.

The transfer transistors Tr11 and Tr12 include respective transfer gate electrodes 3 made of polysilicon, respective photo diodes PD (PD1, PD2), and a floating diffusion FD. The reset transistor Tr2 includes a reset gate electrode 4 made of polysilicon, the floating diffusion FD, and a source region 5. The amplifier transistor Tr3 includes an amplifier gate electrode 6 made of polysilicon, a source region 7, and a drain region 8. The floating diffusion FD and the amplifier gate electrode 6 are connected to one another by a wiring portion 9. The source region 7 of the amplifier transistor Tr3 is connected to a vertical signal line (not shown).

In the solid state image pickup device 1, the layout of the transfer gate electrode 3 of the first green pixel Gb is asymmetric to the layout of the transfer gate electrode 3 of the second green pixel Gr. The layouts cause a difference in sensitivity to be generated between the first and second green pixels Gb and Gr. For example, the difference between the layouts of the base layers due to the transfer gate electrodes 3 causes a difference to be generated between the amounts of incident light on both green pixels Gb and Gr because part of obliquely incident light is eclipsed by the transfer gate electrode of one of the green pixels. In the MOS solid state image pickup device, the difference in sensitivity between both pixels becomes noticeable as the miniaturization of the pixel progresses. The difference in sensitivity is a bottleneck for the miniaturization.

Also, referring to FIG. 2, a solid state image pickup device 10 is suggested, in which unit pixel groups 2 of two-pixel-sharing type that two pixels share one floating diffusion, one amplifier transistor, and one select transistor are arrayed in a staggered manner. Since the unit pixel groups 2 of two-pixel-sharing type are arrayed in a staggered manner in the solid state image pickup device 10, the layouts of transfer gate electrodes of first and second green pixels Gb and Gr are symmetric to one another. Thus, the difference in sensitivity between the green pixels Gb and Gr is being decreased.

The difference in sensitivity between the first and second green pixels Gb and Gr may cause noise, such as grating noise, to occur, and may also cause color shading to occur. It is desirable to eliminate the difference in sensitivity.

### SUMMARY OF THE INVENTION

Meanwhile, in the solid state image pickup device 10 shown in FIG. 2, the layout of a pixel transistor and the layout of a floating diffusion FD are restricted to keep the symmetrical layouts of the transfer gate electrodes of the first and second green pixels Gb and Gr. The restriction may be a bottleneck for the miniaturization. For example, the unit pixel group 2 merely attains two-pixel sharing, and hence the numbers of pixel transistors and floating diffusions are twice the numbers of pixel transistors and floating diffusions in the layout of four-pixel sharing. Accordingly, the area of photo diodes PD for photoelectric transduction is decreased. The decrease in area of the photo diodes PD results in a loss in sensitivity. In addition, in the solid state image pickup device 10, the layouts of the transfer gate electrodes 3 of the green pixels Gb and Gr are asymmetric to the layouts of transfer gate electrodes 3 of a red pixel R and a blue pixel B. Thus, it is difficult to prevent color shading from occurring.

As described above, optical asymmetry occurs among pixels due to a base layer having an asymmetric arrangement with respect to the boundary between predetermined adjacent pixels.

In light of the situations, it is desirable to provide a solid state image pickup device and an electronic device such as a camera including the solid state image pickup device, the device which improves optical asymmetry among pixels due to an asymmetric arrangement of a base layer including electrodes and wiring portions.

A solid state image pickup device according to an embodiment of the present invention includes a pixel section in which pixels are arrayed; a base layer that is formed in a group of a plurality of pixels at a position below a light incidence surface of the group and has layouts including electrodes and wirings, the layouts being asymmetric with respect to a boundary between predetermined adjacent pixels; and adjusting means for causing optical asymmetry between pixels due to the base layer to be optical symmetry.

As a desirable embodiment for the solid state image pickup device, the pixel section may include a plurality of unit pixel groups, each of the unit pixel groups having a plurality of pixels that share a single predetermined transistor. The base layer may be a base layer including a gate electrode and a wiring portion of the pixel transistor.

With the solid state image pickup device of the embodiment, the effect of the base layer to incident light is decreased or eliminated in accordance with an adjustment direction and an adjustment amount of a positional shift of the adjusting means. The incidence efficiencies of incident light on the photoelectric transducers of the respective pixels can be equalized.

With the solid state image pickup device of the desirable embodiment, the pixel section may include the plurality of unit pixel groups of pixel-sharing type. Thus, the incidence efficiencies of incident light on photoelectric transducers of at least common color pixels, from which the same color signals are output, can be equalized in the pixel unit group or in a plurality of adjacent unit pixel groups.

An electronic device according to an embodiment of the present invention includes a solid state image pickup device, an optical system that guides incident light onto a photoelectric transducer of the solid state image pickup device, and a signal processing circuit that processes an output signal from the solid state image pickup device. The solid state image pickup device is any of the above-described solid state image pickup devices.

With the electronic device of this embodiment, the effect of the base layer to incident light is decreased or eliminated because the solid state image pickup device is used. The incidence efficiencies of incident light on the photoelectric transducers of the respective pixels can be equalized.

As the disadvantages of the related art, it is difficult to perform correction to attain balanced positions for all colors as the pixels are further miniaturized, because the spot diameters of incident light on ends of light incident side of the waveguides may vary depending on the colors due to color aberration. Also, if the pupil correction amounts for the on chip lenses and the color filter layers vary depending on the colors, a gap or an overlapping portion may be generated. As a result, shading and color mixture may be generated.

The device performs pupil correction for on chip lenses and a color filter layer not depending on the colors of incident light transmitted through the color filter layer, but performs pupil correction on the basis of a reference color of incident light. Thus, even when the spot diameters of incident light vary depending on the colors due to color aberration, the incident light can be efficiently incident on the ends of light incident side of the waveguide.

A solid state image pickup device according to an embodiment of the present invention includes a pixel section defined by unit pixels arrayed in line and row directions of a semiconductor substrate. Each of the unit pixels includes a photoelectric transducer that is formed on the semiconductor substrate and converts incident light into a signal charge, a waveguide that is formed above the photoelectric transducer and guides the incident light to the photoelectric transducer, and a microlens that is formed above the waveguide and guides the incident light to an end of light incident side of the waveguide. The waveguide has a columnar body with a constant cross section from the end of light incident side to an end of light exit side, and is arranged such that a center of rays of the incident light incident from the microlens on the end of light incident side of the waveguide is aligned with a central axis of the waveguide.

With the solid state image pickup device of this embodiment, the waveguide has the columnar body with the constant cross section from the end of light incident side to the end of light exit side. The light vertically incident on the end of light incident side of the waveguide is not reflected by a side wall of the waveguide but is transmitted through a waveguide 16. Thus, decrease in sensitivity is restricted. Also, the center of rays of incident light incident on the end of light incident side of the waveguide is aligned with the central axis of the waveguide. Thus, pupil correction is performed for the waveguide. Accordingly, the incident light from the microlens is efficiently guided to the waveguide.

A method of manufacturing a solid state image pickup device according to an embodiment of the present invention includes the steps of forming in a wiring layer a waveguide hole, the waveguide hole guiding incident light onto a photoelectric transducer that converts the incident light into a signal charge, the photoelectric transducer being formed at a semiconductor substrate, the wiring layer formed at the semiconductor substrate and including an interlayer insulating film having a plurality of layers of wiring portions; filling the waveguide hole with a waveguide material film having a higher refractive index than a refractive index of the interlayer insulating film and forming a waveguide in the waveguide hole; forming a color filter layer that divides the incident light, on the waveguide material film with a planarizing and insulating film interposed therebetween; and forming a microlens on the color filter layer, the microlens guiding the incident light onto the photoelectric transducer. A plurality of unit pixels each having the photoelectric transducer are arrayed in line and row directions of the semiconductor substrate, to define a pixel section. The waveguide formed for the corresponding photoelectric transducer has a columnar body with a constant cross section from an end of light incident side to an end of light exit side, and is arranged such that a center of rays of the incident light incident on the end of light incident side of the waveguide is aligned with a central axis of the waveguide.

With the method of manufacturing the solid state image pickup device of this embodiment, the waveguide has the columnar body with the constant cross section from the end of light incident side to the end of light exit side. The light vertically incident on the end of light incident side of the waveguide is not reflected by the side wall of the waveguide but is transmitted through the waveguide 16. Thus, decrease in sensitivity is restricted. Also, the center of rays of incident light incident on the end of light incident side of the waveguide is aligned with the central axis of the waveguide. Thus, pupil correction is performed for the waveguide. Accordingly, the incident light from the lens is efficiently guided to the waveguide.

An image pickup device according to an embodiment of the present invention includes a light condensing optical unit that condenses incident light; an image pickup unit including a solid state image pickup device that receives the light condensed by the light condensing optical unit and performs photoelectric transduction for the light; and a signal processing unit that processes a signal obtained by the photoelectric transduction by the solid state image pickup device. The solid state image pickup device includes a pixel section defined by unit pixels arrayed in line and row directions of a semiconductor substrate. The unit pixel group includes a photoelectric transducer that is formed on the semiconductor substrate and converts incident light into a signal charge; a waveguide that is formed above the photoelectric transducer and guides the incident light to the photoelectric transducer; and a microlens that is formed above the waveguide and guides the incident light to an end of light incident side of the waveguide. The waveguide has a columnar body with a constant cross section from the end of light incident side to an end of light exit side, and is arranged such that a center of rays of the incident light incident from the microlens on the end of light incident side of the waveguide is aligned with a central axis of the waveguide.

With the image pickup device of this embodiment, since the aforementioned solid state image pickup device is used, the decrease in sensitivity is restricted, and the incident light from the microlens can be efficiently guided to the waveguide.

Since the pupil correction is performed even for the waveguide in the solid state image pickup device, the incident light of the respective colors is completely condensed to the waveguide. Accordingly, color unevenness (color shading) due to shading depending on a wavelength can be decreased. Since shading is decreased, when a sensitivity is defined as an output average value of the entire screen, the sensitivity can be increased. For example, an exposure time can be decreased, and image capturing in a dark environment can be performed.

With the method of manufacturing the solid state image pickup device, since the pupil correction is performed even for the waveguide, the incident light of the respective colors is completely condensed to the waveguide. Accordingly, color unevenness (color shading) due to shading depending on a wavelength can be decreased. Since shading is decreased, when a sensitivity is defined as an output average value of the entire screen, the sensitivity can be increased. For example, an exposure time can be decreased, and image capturing in a dark environment can be performed. Thus, the effect of color aberration can be decreased without increasing the number of processes.

Also, in miniaturized pixels, light that does not enter a waveguide is reduced by adjusting a pupil correction amount for each color. Shading and color mixture can be decreased.

Since the image pickup device according to this embodiment uses the aforementioned solid state image pickup device, the color unevenness (color shading) due to shading depending on a wavelength can be decreased. The sensitivity can be increased, and hence an image with high quality can be obtained.

With the solid state image pickup device, the incidence efficiencies of incident light to the respective photoelectrical transducers can be equalized. The photoelectric transducers of the respective pixels can obtain optical symmetry. For example, if a solid state image pickup device of pixel-sharing type is used, the effect of the asymmetric base layer is decreased or eliminated, and the difference in sensitivity between common color pixels, from which the same color signals are output, can be decreased. In addition, color shading can be decreased.

With the electronic device, optical symmetry can be provided in the photoelectric transducers of the respective pixels in the solid state image pickup device. The quality of the electronic device can be increased, and the image quality thereof can be increased.

### BRIEF DESCRIPTION OF THE DRAWINGS

FIG. 1 is a schematic configuration diagram showing a primary portion of an exemplary solid state image pickup device of two-pixel-sharing type that two pixels share one floating diffusion, one amplifier transistor, and one select transistor, according to related art;

FIG. 2 is a schematic configuration diagram showing a primary portion of another exemplary solid state image pickup device of two-pixel-sharing type that two pixels share one floating diffusion, one amplifier transistor, and one select transistor, according to related art;

FIGS. 3A to 3C are schematic cross-sectional views and a plan layout diagram showing a first exemplary configuration of a solid state image pickup device according to a first embodiment of the present invention;

FIGS. 4A and 4B are schematic cross-sectional views showing an exemplary method of calculating a pupil correction amount according to an embodiment of the present invention;

FIGS. 5A and 5B are schematic cross-sectional views showing an exemplary configuration of a solid state image pickup device according to related art;

FIGS. 6A and 6B are schematic cross-sectional views showing an exemplary method of calculating a pupil correction amount according to related art;

FIGS. 7A to 7C are schematic cross-sectional views showing pupil correction for waveguides of respective colors;

FIG. 8 is a plan layout diagram showing a second exemplary configuration of a solid state image pickup device according to the first embodiment of the present invention;

FIGS. 9A to 9C are schematic cross-sectional views showing the second exemplary configuration of the solid state image pickup device according to the first embodiment of the present invention;

FIGS. 10A to 10D are schematic cross-sectional views showing a third exemplary configuration of a solid state image pickup device according to the first embodiment of the present invention;

FIG. 11 is a schematic cross-sectional view showing the third exemplary configuration of the solid state image pickup device according to the first embodiment of the present invention;

FIG. 12 is a cross-sectional view showing a manufacturing step in a first exemplary manufacturing method of a solid state image pickup device according to a second embodiment of the present invention;

FIG. 13 is a cross-sectional view showing a manufacturing step in the first exemplary manufacturing method of the solid state image pickup device;

FIG. 14 is a cross-sectional view showing a manufacturing step in the first exemplary manufacturing method of the solid state image pickup device;

FIG. 15 is a cross-sectional view showing a manufacturing step in the first exemplary manufacturing method of the solid state image pickup device;

FIG. 16 is a cross-sectional view showing a manufacturing step in the first exemplary manufacturing method of the solid state image pickup device;

FIG. 17 is a cross-sectional view showing a manufacturing step in the first exemplary manufacturing method of the solid state image pickup device;

FIG. 18 is a cross-sectional view showing a manufacturing step in the first exemplary manufacturing method of the solid state image pickup device;

FIG. 19 is a cross-sectional view showing a manufacturing step in the first exemplary manufacturing method of the solid state image pickup device;

FIG. 20 is a cross-sectional view showing a manufacturing step in the first exemplary manufacturing method of the solid state image pickup device;

FIG. 21 is a cross-sectional view showing a manufacturing step in the first exemplary manufacturing method of the solid state image pickup device;

FIG. 22 is a cross-sectional view showing a manufacturing step in a second exemplary manufacturing method of a solid state image pickup device according to the second embodiment of the present invention;

FIG. 23 is a cross-sectional view showing a manufacturing step in the second exemplary manufacturing method of the solid state image pickup device;

FIG. 24 is a cross-sectional view showing a manufacturing step in the second exemplary manufacturing method of the solid state image pickup device;

FIG. 25 is a cross-sectional view showing a manufacturing step in the second exemplary manufacturing method of the solid state image pickup device;

FIG. 26 is a cross-sectional view showing a manufacturing step in the second exemplary manufacturing method of the solid state image pickup device;

FIG. 27 is a cross-sectional view showing a manufacturing step in the second exemplary manufacturing method of the solid state image pickup device;

FIG. 28 is a cross-sectional view showing a manufacturing step in the second exemplary manufacturing method of the solid state image pickup device;

FIG. 29 is a block diagram showing an example image pickup device according to a third embodiment of the present invention;

FIG. 30 is a schematic configuration diagram showing a pixel section in a solid state image pickup device according to a fourth embodiment of the present invention;

FIGS. 31A and 31B are schematic configuration diagrams showing a primary portion of the solid state image pickup device according to the fourth embodiment of the present invention;

FIG. 32 is a schematic cross-sectional view taken along line XXXII-XXXII in FIG. 31A;

FIG. 33 is a graph plotting the wavelengths and outputs of green pixels Gb and Gr according to the fourth embodiment shown in FIGS. 31A and 31B;

FIGS. 34A and 34B are schematic configuration diagrams showing a primary portion of a solid state image pickup device according to a fifth embodiment of the present invention;

FIG. 35 is a schematic configuration diagram showing a primary portion of a solid state image pickup device in a final state according to a sixth embodiment of the present invention;

FIGS. 36A and 36B are configuration diagrams showing the primary portion of the solid state image pickup device to explain movement of waveguides according to the sixth embodiment;

FIG. 37 is a schematic configuration diagram showing a primary portion of a solid state image pickup device according to a seventh embodiment of the present invention;

FIG. 38 is a configuration diagram showing a primary portion of a solid state image pickup device according to a comparative example to explain the seventh embodiment;

FIGS. 39A and 39B are schematic configuration diagrams showing a primary portion of a solid state image pickup device according to an eighth embodiment of the present invention;

FIGS. 40A to 40B are cross-sectional views showing the primary portion of the solid state image pickup device to explain pupil correction for waveguides according to the eighth embodiment;

FIGS. 41A to 41C are cross-sectional views showing the primary portion of the solid state image pickup device to explain the pupil correction for the waveguides according to the eighth embodiment;

FIGS. 42A and 42B are plan views showing the primary portion of the solid state image pickup device to explain the pupil correction for the waveguides according to the eighth embodiment;

FIG. 43 is a plan view showing a pixel section of the solid state image pickup device to explain the pupil correction for the waveguides according to the eighth embodiment;

FIG. 44 is a schematic configuration diagram showing a primary portion of a solid state image pickup device according to a ninth embodiment of the present invention;

FIG. 45 is a configuration diagram showing a primary portion of a solid state image pickup device according to a comparative example to explain the ninth embodiment;

FIG. 46 is a schematic configuration diagram showing a primary portion of a solid state image pickup device according to a tenth embodiment of the present invention;

FIGS. 47A and 47B are schematic cross-sectional views respectively taken along line XLVIIA-XLVIIA and line XLVIIB-XLVIIB in FIG. 46;

FIG. 48 is a configuration diagram showing a primary portion of a solid state image pickup device according to a comparative example to explain the tenth embodiment;

FIGS. 49A and 49B are schematic cross-sectional views respectively taken along line XLIXA-XLIXA and line XLIXB-XLIXB in FIG. 48;

FIG. 50 is a schematic configuration diagram showing a primary portion of a solid state image pickup device according to an eleventh embodiment of the present invention;

FIGS. 51A and 51B are schematic cross-sectional views respectively taken along line LIA-LIA and line LIB-LIB in FIG. 50;

FIG. 52 is a configuration diagram showing a primary portion of a solid state image pickup device according to a comparative example to explain the eleventh embodiment;

FIGS. 53A and 53B are schematic cross-sectional views respectively taken along line LIIIA-LIIIA and line LIIIB-LIIIB in FIG. 52;

FIG. 54 is a schematic configuration diagram showing a primary portion of a solid state image pickup device according to a twelfth embodiment of the present invention;

FIGS. 55A and 55B are schematic cross-sectional views respectively taken along line LVA-LVA and line LVB-LVB in FIG. 54;

FIG. 56 is a configuration diagram showing a primary portion of a solid state image pickup device according to a comparative example to explain the twelfth embodiment;

FIGS. 57A and 57B are schematic cross-sectional views respectively taken along line LVIIA-LVIIA and line LVIIB-LVIIB in FIG. 56;

FIG. 58 is a schematic configuration diagram showing a primary portion of a solid state image pickup device according to a thirteenth embodiment of the present invention;

FIGS. 59A and 59B are schematic cross-sectional views respectively taken along line LIXA-LIXA and line LIXB-LIXB in FIG. 58;

FIG. 60 is a schematic configuration diagram showing a color filter with the Bayer pattern as an exemplary color filter of a solid state image pickup device according to a fourteenth embodiment of the present invention;

FIG. 61 is a schematic configuration diagram showing a color filter with the honeycomb pattern as another exemplary color filter of a solid state image pickup device according to the fourteenth embodiment of the present invention;

FIG. 62 is a schematic configuration diagram showing a primary portion of a solid state image pickup device according to a comparative example;

FIG. 63 is a cross-sectional view taken along line LXIII-LXIII in FIG. 62;

FIG. 64 is a graph plotting the wavelengths and outputs of green pixels Gb and Gr according to the comparative example shown in FIG. 62;

FIGS. 65A and 65B are schematic configuration diagrams showing a primary portion of the solid state image pickup device according to the comparative example; and

FIG. 66 is a schematic configuration diagram showing an electronic device according to a fifteenth embodiment of the present invention.

### DESCRIPTION OF THE PREFERRED EMBODIMENTS

Embodiments of the present invention will be described below.

### 1. First Embodiment

First Exemplary Configuration of Solid State Image Pickup Device

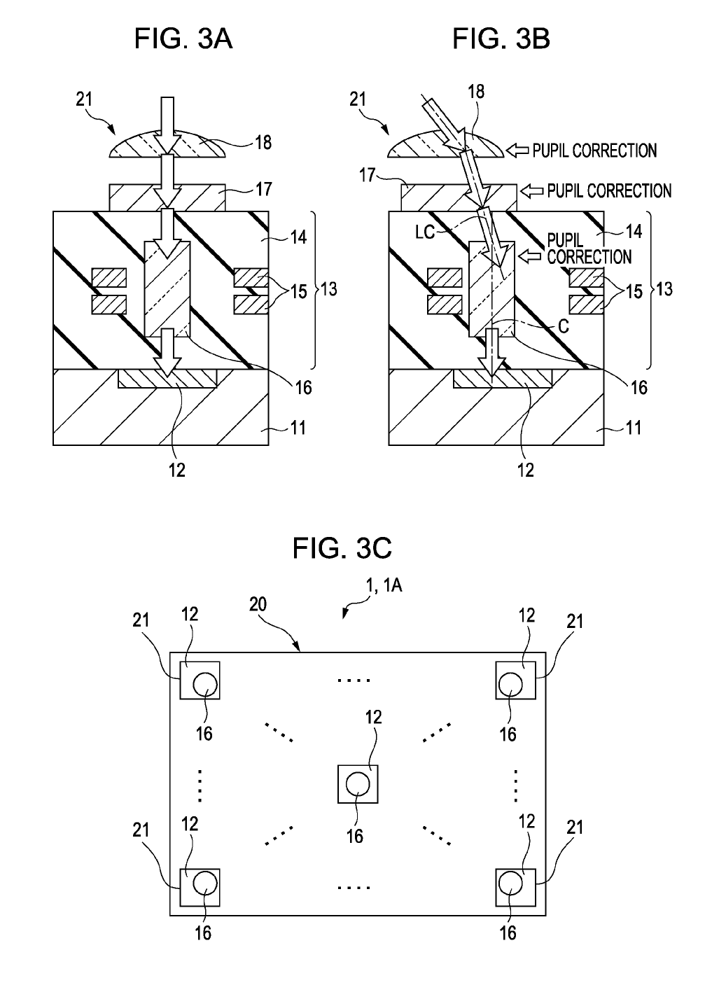

A first exemplary configuration of a solid state image pickup device according to a first embodiment of the present invention will be described with reference to schematic cross-sectional views and a plan layout diagram in FIGS. 3A to 3C. FIG. 3A illustrates a unit pixel at the center of an angular field, FIG. 3B illustrates a unit pixel at an edge of the angular field, and FIG. 3C illustrates a pixel section including a plurality of unit pixels.

Hereinafter, reference sign 1 denotes a solid state image pickup device, 11 denotes a semiconductor substrate, 12 denotes a photoelectric transducer, 14 denotes an interlayer insulating film, 16 denotes a waveguide, 17 denotes a color filter layer, 18 denotes a microlens, 19 denotes a waveguide hole, 20 denotes a pixel section, 21 denotes a unit pixel, 53 denotes a waveguide material film, 200 denotes an image pickup device, 201 denotes an image pickup unit, 202 denotes a light condensing optical unit, 203 denotes a signal processing unit, and 210 (1) denotes a solid state image pickup device.

Referring to FIGS. 3A to 3C, a photoelectric transducer 12 is formed on a surface (light incident side) of a semiconductor substrate 11. The photoelectric transducer 12 converts incident light into a signal charge. The semiconductor substrate 11 uses a silicon substrate. Alternatively, the semiconductor substrate 11 may use a silicon on insulator (SOI) substrate. In this case, the photoelectric transducer 12 is formed on a silicon layer of the SOI substrate. A wiring layer 13 is formed above the photoelectric transducer 12. For example, the wiring layer 13 is formed such that a plurality of layers including wiring portions 15 are formed in an interlayer insulating film 14. The wiring portions 15 are not formed in an area above the photoelectric transducer 12. The surface of the interlayer insulating film 14 is planarized.

In addition, a waveguide 16 is formed in the wiring layer 13 in the area above the photoelectric transducer 12. The waveguide 16 guides the incident light to the photoelectric transducer 12. The waveguide 16 is formed such that a waveguide hole is formed in the interlayer insulating film 14 in the area above the photoelectric transducer 12, and the waveguide hole is filled with a light-transmissive material having a higher refractive index than that of the interlayer insulating film 14. The material is, for example, a silicon nitride film, a diamond film, or a resin material.

A microlens 18 (also called on chip lens) is formed on the interlayer insulating film 14 in an area above the waveguide 16 with a color filter layer 17 interposed therebetween. The color filter layer 17 divides the incident light. The microlens 18 guides the incident light emitted from the color filter layer 17 to an end of light incident side of the waveguide 16. The microlens 18 and the color filter layer 17 have been subjected to pupil correction so as to efficiently condense even oblique light. The pupil correction amount becomes larger from the center of the angular field (e.g., the center of the pixel section) toward an edge of the angular field. The color filter layer 17 divides the incident light into, for example, red light, green light, and blue light. Thus, color filters for the respective colors are provided. The microlens 18 is also called on chip lens. The microlens 18 has a convex lens shape and is provided in the top layer.

The photoelectric transducer 12, the waveguide 16, the color filter layer 17, the microlens 18, a transfer gate (not shown), etc., define a unit pixel 21. A plurality of such unit pixels 21 are arranged in line and row directions of the semiconductor substrate 11, and define a pixel section 20. A pixel amplifying unit (not shown, also referred to as pixel transistor unit) is provided every unit pixel, every two unit pixels, or every four unit pixels. The pixel amplifying unit amplifies the signal charge read by the transfer gate and outputs the amplified signal charge.

Waveguides 16 are formed in the pixel section 20 to respectively correspond to photoelectric transducers 12. Each waveguide 16 has a columnar body with a constant cross section from an end of light incident side to an end of light exit side. For example, the columnar body with a constant cross section may be a cylinder or an oval cylinder (including an elliptic cylinder). Alternatively, the waveguide 16 may be a prism with rounded corners. The center LC of rays of the incident light which is incident on the end of light incident side of the waveguide 16 is aligned with the central axis C of the waveguide 16.

In this case, in the unit pixel 21 at the center of the angular field (see FIG. 3A), the incident light is incident on the microlens 18 in the central-axis direction. The incident light condensed by the microlens 18 is transmitted through and divided by the color filter layer 17, and is incident on the end of light incident side of the waveguide 16. The incident light is guided along the central axis C of the waveguide 16 and exited from the end of light exit side of the waveguide 16. The light is emitted on the center of the photoelectric transducer 12. That is, the incident light transmitted through the center of the microlens 18 is transmitted along the center of the color filter layer 17 and the central axis C of the waveguide 16, and emitted on the center of the photoelectric transducer 12. Thus, pupil correction has not been performed for the waveguide 16.

In the unit pixel 21 at a position shifted from the center of the angular field (see FIG. 3B), as described above, the microlens 18 and the color filter layer 17 have been subjected to pupil correction so as to efficiently condense even oblique light. Also, the waveguide 16 is arranged such that the center LC of rays of the incident light which is incident on the end of light incident side of the waveguide 16 is aligned with the central axis C of the waveguide 16. That is, pupil correction has been performed for the waveguide 16.

In the photoelectric transducers 12, on which incident light with equivalent wavelengths is incident, in the pixel section 20, the shift amount of the central axis C of each waveguide 16 with respect to the center of the corresponding photoelectric transducer 12 becomes larger from the photoelectric transducer 12 at the center of the pixel section 20 toward the outside. That is, the incidence angle of the incident light condensed by the microlens 18 becomes larger from the center of the pixel section 20 toward the outside. The pupil correction has been performed for the microlens 18, however, the pupil correction amount is not sufficient. Owing to this, for the incident light with the equivalent wavelengths, the shift amount of the central axis of the waveguide 16 with respect to the center of the photoelectric transducer 12 is increased, so that the center of rays of light from the microlens 18 is aligned with the central axis C of the waveguide 16.

The waveguide 16 has a diameter which allows the incident light from the end of light exit side of the waveguide 16 to be emitted on an area within the surface of the photoelectric transducer 12. Hence, the size of the waveguide 16 is not equivalent to the size of the surface of the photoelectric transducer 12, unlike the waveguide of related art. The diameter of the waveguide 16 is desirably larger than the spot diameter of the incident light transmitted through the color filter layer 17 on the end of light incident side of the waveguide 16. The spot diameter varies depending on the wavelength of incident light. For example, when the color filter layer 17 divides the incident light into red light, green light, and blue light, the spot diameter of the red light is the largest, the spot diameter of the green light is smaller than that of the red light, and the spot diameter of the blue light is smaller than that of the green light. If the diameter of the waveguide 16 is determined depending on the color, the layout may become complicated. In some cases, the waveguide 16 may reach the wiring portion 15 of the wiring layer 13. For example, the diameter of the waveguide 16 is determined on the basis of the green light which has an intermediate wavelength range of the incident light. Alternatively, if a margin is provided between the waveguide 16 and the wiring portion 15 of the wiring layer 13, the diameter of the waveguide 16 may be determined on the basis of the red light.

As described above, the margin for the pupil correction can be increased by decreasing the diameter of the waveguide 16 to be smaller than the diameter of the waveguide of related art. In addition, the margin for the pupil correction of the waveguide 16 can be further increased by decreasing the width of the wiring portion 15 arranged around the waveguide 16. For example, the line width of the wiring portion 15 can be decreased within a range, the range which prevents clock delay from occurring due to increase in resistance of the wiring portion 15 because the line width is decreased, as much as possible in view of the process. For example, if the line width of the wiring portion 15 is decreased by 10 nm, the margin for the pupil correction can be increased by 10 nm.

The solid state image pickup device 1 (1A) is configured as described above.

Exemplary Calculation of Pupil Correction

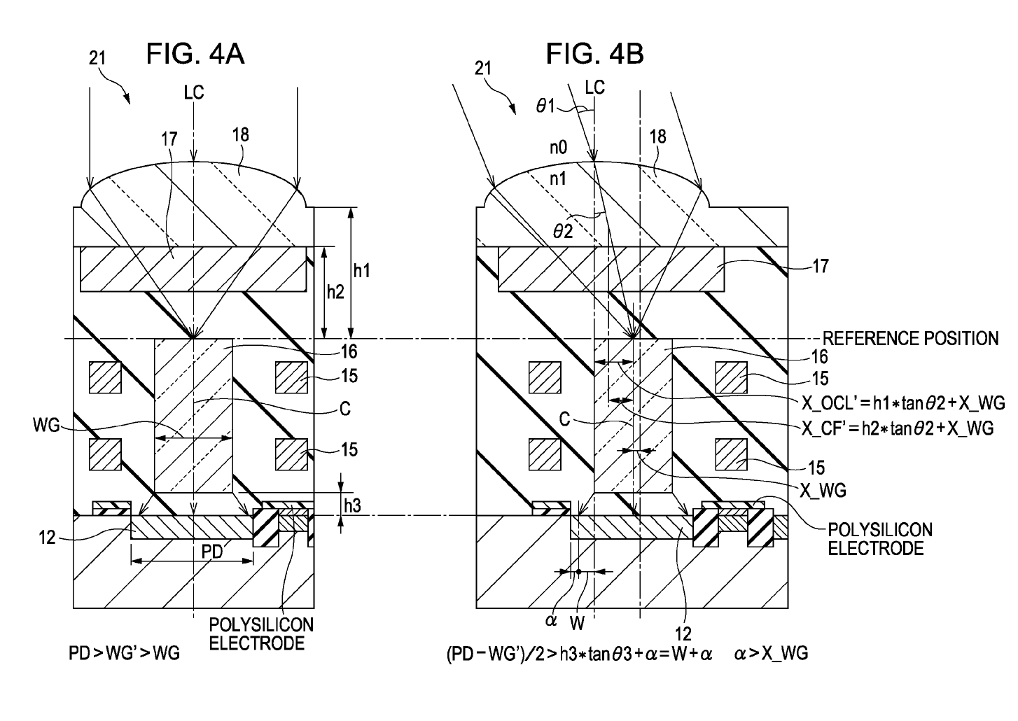

Next, an exemplary method of calculating the pupil correction amount of the solid state image pickup device 1 will be described with reference to a schematic cross-sectional view in FIGS. 4A and 4B. FIG. 4A illustrates a unit pixel at the center of an angular field. FIG. 4B illustrates a unit pixel at an edge of the angular field.

Referring to FIG. 4A, in the unit pixel 21 at the center of the angular field, the incident light is incident on the microlens 18 in the central-axis direction. The incident light condensed by the microlens 18 is transmitted through and divided by the color filter layer 17, and is incident on the end of light incident side of the waveguide 16. The incident light is guided along the central axis C of the waveguide 16 and exited from the end of light exit side of the waveguide 16. The light is emitted on the center of the photoelectric transducer 12. That is, the incident light transmitted through the center of the microlens 18 is transmitted along the center of the color filter layer 17 and the central axis C of the waveguide 16, and emitted on the center of the photoelectric transducer 12. Thus, pupil correction is not performed for the waveguide 16.

In contrast, in the unit pixel 21 at the edge of the angular field, referring to FIG. 4B, a pupil correction amount at a position, at which an incidence angle θ1 of incident light incident on the microlens 18 is, for example θ1=25°, is calculated.

A refractive index n of the microlens 18 is n=1.5.

If a refractive index n0 of the atmosphere of the microlens 18 is n0=1, and a refractive index n1 of the microlens 18 is n1=1.6, a relationship is established as follows,

sin θ2=(n0/n1)*sin θ1

If θ1=25°, the result is as follows,

$$\begin{matrix}θ 2 = sin - 1 \{ n 0 / n 1 ) * sin θ 1 \} \\ = sin - 1 \{ ( 1 / 1.6 ) * sin 25 \} \\ = 15.3 °\end{matrix}$$

For example, when the end of light incident side of the waveguide 16 serves as a reference position (reference level), a height h1 represents a height from the reference position to a formation plane of the microlens 18, and a height h2 represents a height from the reference position to an incidence plane of the color filter layer 17.

For example, it is assumed that h1=2 μm, h2=1.5 μm. In this case, a difference X_OCL′ between the central axis C of the waveguide 16 and the central axis LC of the microlens 18 is as follows,

$$\begin{matrix}{X\_OCL}^{′} = h 1 * tan θ 2 + X\_WG \\ = 2 * tan 15.3 ° + X\_WG \\ = 0.547 μm + X\_WG\end{matrix}$$

where X_WG is a difference between the center of the photoelectric transducer 12 and the central axis C of the waveguide 16.

Also, a difference X_CF′ between the central axis C of the waveguide 16 and the central axis FC of the color filter layer 17 is as follows,

$$\begin{matrix}{X\_CF}^{′} = h 2 * tan θ 2 + X\_WG \\ = 1.5 * tan 15.3 ° + X\_WG \\ = 0.411 μm + X\_WG\end{matrix}$$

If a diffraction angle θ3 at the end of light exit side of the waveguide 16 is θ3=13.0°, a diffusing width W to the surface of the photoelectric transducer 12 is as follows,

W=h3*tan θ3

If a distance h3 from the photoelectric transducer 12 to the end of light exit side of the waveguide 16 is, for example, h3=0.5 μl, the result is as follows,

W=h3*tan θ3=0.5*tan 13.0°=0.115 μm

For example, if a width PD of the photoelectric transducer 12 is PD=1.1 μl, and a diameter WG′ of the waveguide 16 is WG′=0.6 μl, a distance a from an end of diffracted light to a projection position on the surface of the semiconductor substrate 11 of the transfer gate which is formed next to the photoelectric transducer 12 is expressed as follows,

(PD−WG′)/2>W+α

With the expression, the values becomes as follows,

(1.1−0.6)/2>0.11+α

Thus, a pupil correction X_WG can be provided until the condition is attained as follows,

α<0.25−0.115=0.135 μm

Next, a method of calculating the diffraction angle 03 will be described.

On the basis of Young's experiment, if d is pixel pitch×2, n is 1 (first order diffracted light), and λ is a wavelength of incident light, an expression is provided as follows,

d*sin θ=nλ

Thus, the result is as follows,

θ=sin−1(nλ/d)

For example, if d=1.4 μm×2=2.80 μm and n=1, and if a wavelength λ of red light is λ=630 nm (red), a diffraction angle θ of the red light is as follows,

θ=sin−1(0.63/2.8)=13.00°

As reference, if a wavelength λblue of blue light is λblue=450 nm (blue), a diffraction angle of the blue light is as follows,

θblue=sin−1(0.45/2.8)=9.25°

Also, if a wavelength λgreen of green light is λgreen=550 nm (green), a diffraction angle of the green light is as follows,

θgreen=sin−1(0.55/2.8)=11.33°

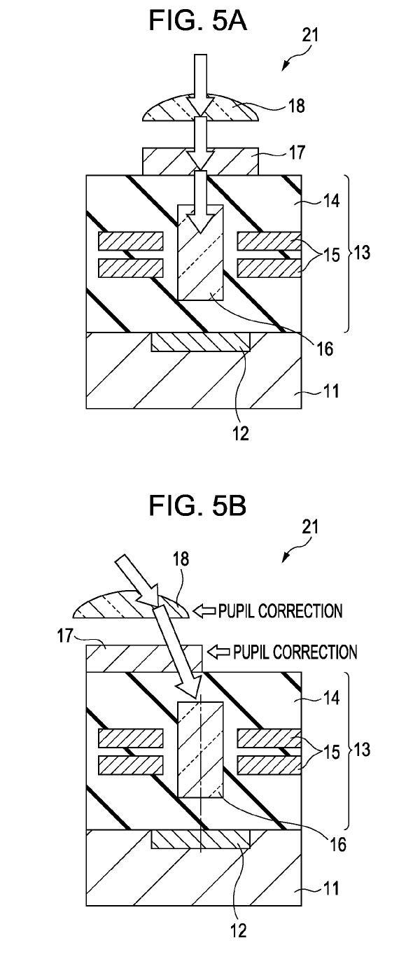

Next, a structure of a solid state image pickup device according to related art will be described as a comparative example with reference to schematic cross-sectional views in FIGS. 5A and 5B. FIG. 5A illustrates a unit pixel at the center of an angular field. FIG. 5B illustrates a unit pixel at an edge of the angular field.

Referring to FIGS. 5A and 5B, in a unit pixel 21, a photoelectric transducer 12 is formed on a surface (light incidence side) of a semiconductor substrate 11. The photoelectric transducer 12 converts incident light into a signal charge. A wiring layer 13 is formed above the photoelectric transducer 12. For example, the wiring layer 13 is formed such that a plurality of layers including wiring portions 15 are formed in an interlayer insulating film 14. The wiring portions 15 are not formed in an area above the photoelectric transducer 12. The surface of the interlayer insulating film 14 is planarized.

In addition, a waveguide 16 is formed in the wiring layer 13 in the area above the photoelectric transducer 12. The waveguide 16 guides the incident light to the photoelectric transducer 12. A microlens 18 (also called on chip lens) is formed on the interlayer insulating film 14 in an area above the waveguide 16 with a color filter layer 17 interposed therebetween. The color filter layer 17 divides the incident light. The microlens 18 guides the incident light emitted from the color filter layer 17 to an end of light incident side of the waveguide 16. The color filter layer 17 divides the incident light into, for example, red light, green light, and blue light. Thus, color filters for respective colors are provided. The microlens 18 is also called on chip lens. The microlens 18 has a convex lens shape and is provided in the top layer.

Referring to FIG. 5A, in the unit pixel 21 at the center of the angular field, the incident light is incident on the microlens 18 in the central-axis direction. The incident light condensed by the microlens 18 is transmitted through and divided by the color filter layer 17, and is incident on the end of light incident side of the waveguide 16. The incident light is guided along the central axis C of the waveguide 16 and exited from the end of light exit side of the waveguide 16. The light is emitted on the center of the photoelectric transducer 12. That is, the incident light transmitted through the center of the microlens 18 is transmitted along the center of the color filter layer 17 and the central axis C of the waveguide 16, and emitted on the center of the photoelectric transducer 12. Thus, pupil correction has not been performed for the microlens 18 or the color filter layer 17.

In contrast, referring to FIG. 5B, in the unit pixel 21 at a position shifted from the center of the angular field, the microlens 18 and the color filter layer 17 have been subjected to pupil correction so as to efficiently condense even oblique light. The pupil correction amount is increased from the center of an angular field toward an edge of the angular field.

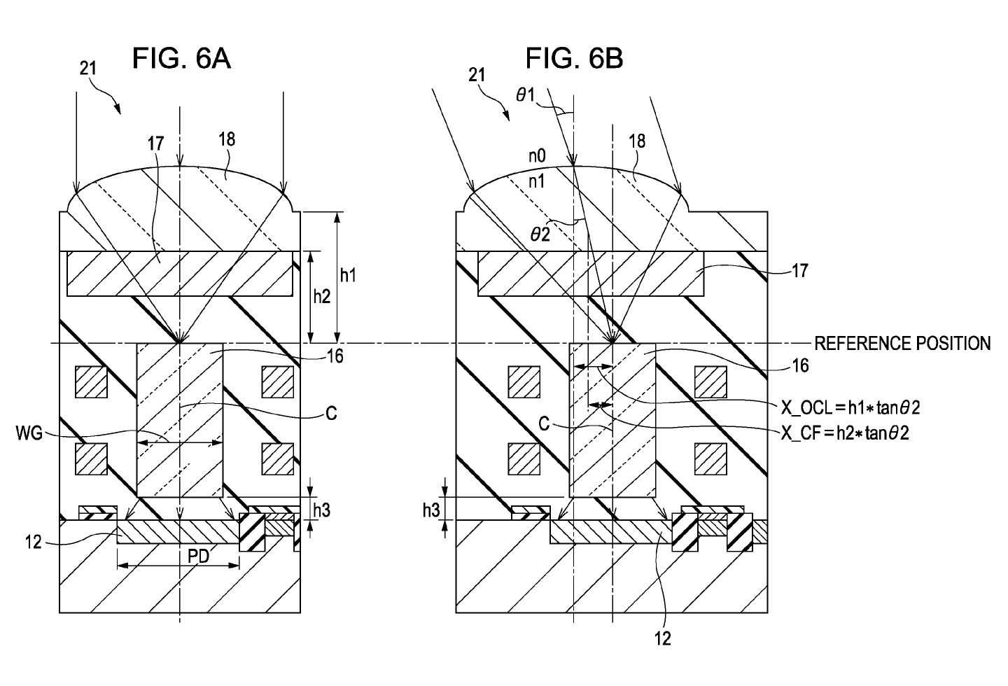

Next, a method of calculating a pupil correction amount according to the comparative example will be described with reference to schematic cross-sectional views in FIGS. 6A and 6B. FIG. 6A illustrates a unit pixel at the center of an angular field. FIG. 6B illustrates a unit pixel at an edge of the angular field.

Referring to FIG. 6A, in the unit pixel 21 at the center of the angular field, the incident light is incident on the microlens 18 in the central-axis direction. The incident light condensed by the microlens 18 is transmitted through and divided by the color filter layer 17, and is incident on the end of light incident side of the waveguide 16. The incident light is guided along the central axis C of the waveguide 16 and exited from the end of light exit side of the waveguide 16. The light is emitted on the center of the photoelectric transducer 12. That is, the incident light transmitted through the center of the microlens 18 is transmitted along the center of the color filter layer 17 and the central axis C of the waveguide 16, and emitted on the center of the photoelectric transducer 12. Thus, pupil correction has not been performed for the waveguide 16.

In contrast, referring to FIG. 6B, in the solid state image pickup device of related art, pupil correction has not been performed for the waveguide 16 even in the unit pixel 21 at the edge of the angular field. Here, pupil correction amounts for the microlens 18 and the color filter layer 17 at a position, at which an incidence angle θ1 of incident light incident on the microlens 18 is, for example θ1=25°, are calculated.

For example, the F-number of the microlens 18 is F=2.8, and the refractive index n of the microlens 18 is n=1.5.

Also, an angle θ3 of marginal rays is θ3=6.8°.

If a refractive index n0 of the atmosphere of the microlens 18 is n0=1, and a refractive index n1 of the microlens 18 is n1=1.6, a relationship is established as follows,

sin θ2=(n0/n1)*sin θ1

If θ1=25°, the result is as follows,

$$\begin{matrix}θ 2 = sin - 1 \{ ( n 0 / n 1 ) * sin θ1 \} \\ = sin - 1 \{ ( 1 / 1.6 ) * sin 25 \} \\ = 15.3 °\end{matrix}$$

For example, when the end of light incident side of the waveguide 16 serves as a reference position (reference level), a height h1 represents a height from the reference position to a formation plane of the microlens 18, and a height h2 represents a height from the reference position to an incidence plane of the color filter layer 17.

For example, it is assumed that h1=2 μm, h2=1.5 μm.

In this case, a difference X_OCL between the central axis C of the waveguide 16 (center of the photoelectric transducer) and the central axis LC of the microlens 18 is as follows,

X_{—}OCL=h1*tan θ2=2*tan 15.3°=0.547 μm

Also, a difference X_CF between the central axis C of the waveguide 16 and the central axis FC of the color filter layer 17 is as follows,

X_{—}CF=h2*tan θ2=1.5*tan 15.3°=0.411 μm

In this embodiment, pupil correction is not performed for the waveguide 16. Hence, a problem described with reference to FIGS. 3A to 3C may occur.

In the solid state image pickup device 1, the waveguide 16 has a columnar body with a constant cross section from the end of light incident side to the end of light exit side thereof. The light vertically incident on the end of light incident side of the waveguide 16 is not reflected by a side wall of the waveguide 16 but is transmitted through the waveguide 16. Since the light is not reflected by the side wall of the waveguide 16, decrease in sensitivity is restricted. Also, since the center of rays of the incident light incident on the end of light incident side of the waveguide 16 is aligned with the central axis of the waveguide 16, the incident light is efficiently guided to the waveguide 16. That is, pupil correction is performed even for the waveguide 16.

Since the pupil correction is performed even for the waveguide 16 in the solid state image pickup device 1, the incident light of the respective colors is completely condensed to the waveguide 16. Accordingly, color unevenness (color shading) due to shading depending on a wavelength can be decreased.

In addition, the distance from the surface of the photoelectric transducer 12 to the end of light exit side of the waveguide 16 should be a predetermined distance to prevent a white spot from appearing. For example, if the interlayer insulating film 14 formed between the photoelectric transducer 12 and the waveguide 16 is made of silicon oxide, the predetermined distance from the photoelectric transducer 12 to the waveguide 16 may be, for example, about 500 nm.

The diameter of the waveguide 16 is determined such that the incident light emitted from the end of light exit side of the waveguide 16 and having a diffusing property because of diffraction is emitted on an area within the surface of the photoelectric transducer 12. Hence, since the diffusing portion of the light emitted from the waveguide 16 is also emitted on the photoelectric transducer 12, the sensitivity is increased.

Since shading is decreased, when a sensitivity is defined as an output average value of the entire screen, the sensitivity can be increased, and an exposure time can be decreased. As an actual result, the sensitivity of the green light is increased by 4%, the sensitivity of the red light is increased by 3%, and the sensitivity of the blue light is increased by 2%.

In related art, the size of the waveguide 16 has been increased as much as possible within the range of a margin with respect to the wiring portion 15, to increase the sensitivity. The incident light emitted from the end of light exit side of the waveguide 16 is diffused by diffraction and emitted. Accordingly, if the diameter of the waveguide 16 is substantially equivalent to the size of the surface of the photoelectric transducer 12, the diffusing portion of the outgoing light is not emitted on the photoelectric transducer 12. This diffusing portion results in the sensitivity being decreased.

Next, decrease in diameter of the waveguide 16 will be described. As described above, the waveguide 16 has a diameter which allows the incident light from the end of light exit side of the waveguide 16 to be emitted on an area within the surface of the photoelectric transducer 12. Hence, the size of the waveguide 16 is not equivalent to the size of the surface of the photoelectric transducer 12, unlike the waveguide of related art. In addition, the diameter of the waveguide is decreased. For example, although the structure is like related art in which a space between the wiring portion 15 and the waveguide 16 is substantially only an overlay margin, pupil correction can be performed for the waveguide 16 by decreasing the diameter of the waveguide 16. For example, it is assumed that a diameter of the waveguide 16 of related art is 1.5 μl. By decreasing the diameter of the waveguide 16 to 1 μm, the diameter is decreased by 0.25 μm for each side. Pupil correction by 0.25 μm can be performed. As described above, the diameter of the waveguide 16 is desirably larger than the spot diameter of the incident light transmitted through the color filter layer 17 on the end of light incident side of the waveguide 16. For example, the diameter of the waveguide 16 is determined on the basis of the green light which has an intermediate wavelength range of the incident light. Alternatively, if a margin is provided between the waveguide 16 and the wiring portion 15 of the wiring layer 13, the diameter of the waveguide 16 may be determined on the basis of the red light.

In the case of the aforementioned miniaturized pixel, the pupil correction amount is determined in accordance with the distance from the waveguide 16 to the wiring portion 15. For example, the diameter of the waveguide 16 is decreased to a desirable value so as to be larger than the spot diameter of the incident light which is incident on the waveguide 16. The amount to be decreased is determined to attain the desirable pupil correction amount. However, if the pupil correction amount is not sufficient, as described above, the line width of the wiring portion 15 is decreased to increase the pupil correction amount. The pupil correction for the waveguide 16 in this embodiment of the present invention is not simply performed for the waveguide 16 having the structure of related art, but the pupil correction amount of the waveguide 16 is provided, for example, by decreasing the diameter of the waveguide 16, or by decreasing the line width of the wiring portion 15. Thus, a sufficient pupil correction amount is provided. Color shading can be markedly decreased. The ratio of the pupil correction amount for the waveguide 16 to the pupil correction amount for the microlens 18 or the color filter layer 17 is constant. For example, the pupil correction amount for the waveguide 16 may be 0.2 times the pupil correction amount for the microlens 18.

In the solid state image pickup device 1 described in the first exemplary example, the idea on the waveguide 16 of related art is significantly changed. Specifically, in related art, the diameter of the waveguide 16 is increased as much as possible within the range of the margin with respect to the wiring portion 15, to increase the sensitivity. In contrast, in the above-described solid state image pickup device 1, the diameter of the waveguide 16 (the diameter of the end of light incident side) is decreased as much as possible as long as the diameter of the waveguide 16 is larger than the spot diameter of the incident light on the end of light incident side, so that all outgoing light emitted from the waveguide 16 is emitted on the photoelectric transducer 12. This is the point that is significantly different from the waveguide of related art. In addition, as described above, another point that the pupil correction is performed for the waveguide 16 is markedly different from the waveguide of related art.

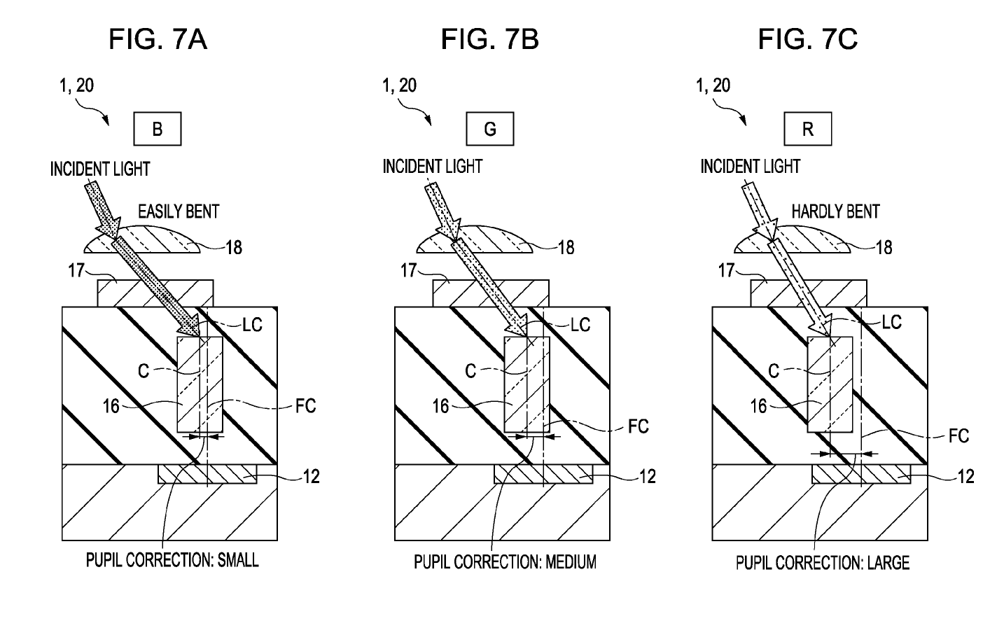

The solid state image pickup device 1 may desirably have different pupil correction amounts for the waveguides 16 depending on the colors of the incident light divided by the color filter layers 17. This point will be described with reference to schematic cross-sectional views in FIGS. 7A to 7C. FIGS. 7A to 7C illustrate unit pixels located at equivalent distances from the center of the angular field (for example, the center of the pixel section) and having color filter layers 17 of different colors. FIG. 7A illustrates a unit pixel of the blue color, FIG. 7B is a unit pixel of the green color, and FIG. 7C is a unit pixel of the red color.

In the solid state image pickup device 1, referring to FIGS. 7A to 7C, in the photoelectric transducers 12, on which incident light with equivalent wavelengths is incident, in the pixel section 20, the shift amount of the central axis C of each waveguide 16 with respect to the central axis FC of the corresponding photoelectric transducer 12 becomes larger from the photoelectric transducer 12 at the center of the pixel section 20 toward the outside. In other words, regarding the photoelectric transducers 12 at the equivalent distances from the center of the pixel section 20, the shift amount of the central axis C of each waveguide 16 with respect to the central axis FC of the corresponding photoelectric transducer 12 is smaller as the wavelength of the light that is divided by the color filter layer 17 and incident on the photoelectric transducer 12 is larger.

To be more specific, when a solid state image pickup device 1 having photoelectric transducers 12 at a pitch of about 1 to 3 μm and waveguides 16 with a diameter of about 0.5 to 2.5 μl, the pupil correction amounts for the waveguides 16 satisfy the relationship of “blue light (B)<green light (G)<red light (R).” It is noted that, for the convenience of illustration in the plan layout, the waveguide 16 is smaller than the photoelectric transducer 12. For example, pupil correction by about 20 to 50 nm is performed for the waveguide 16 on which the blue light is incident, pupil correction by about 50 to 80 nm is performed for the waveguide 16 on which the green light is incident, and pupil correction by about 80 to 110 nm is performed for the waveguide 16 on which the red light is incident. As a result, shading can be optimized by each of the waveguides 16.

Typically, the incidence angle of the incident light condensed by the microlens 18 is increased as the position is shifted from the center of the pixel section 20 toward the outside. The pupil correction is performed for the microlens 18, however, the pupil correction amount is not sufficient. Owing to this, as described above, for the incident light with the equivalent wavelength, the shift amount of the central axis of each waveguide 16 with respect to the center of the corresponding photoelectric transducer 12 is increased, so that the center of rays of light from the microlens 18 is aligned with the central axis of the waveguide 16.

Typically, the microlens 18 and the color filter layer 17 are subjected to the pupil correction so that the incident light is incident on the photoelectric transducer 12 in the central-axis direction. For example, the pupil correction is performed for the microlens 18 and the color filter layer 17 of incident light with a reference wavelength (for example, green light). In this case, referring to FIG. 7A, since the blue light is easily bent by the microlens 18, the incidence angle of the blue light when being incident on the end of light incident side of the waveguide 16 becomes large. Accordingly, even when the microlens 18 and the color filter layer 17 are largely shifted to the center of the pixel section relative to the central axis FC of the photoelectric transducer 12 by the pupil correction, the light emitted from the color filter layer 17 is incident on the end of light incident side of the waveguide 16, at a position close to the central axis FC of the photoelectric transducer 12. Thus, almost all incident light incident on the end of light incident side of the waveguide 16 is guided to the waveguide 16. In this case, the position of the waveguide 16 is corrected such that the central axis LC of rays of the incident light which is incident on the end of light incident side of the waveguide 16 is aligned with the central axis C of the waveguide 16.

In contrast, referring to FIG. 7C, since the red light is hardly bent by the microlens 18 as compared with the blue light, the incidence angle of the red light when being incident on the end of light incident side of the waveguide 16 becomes smaller than that of the blue light. Also, since the microlens 18 and the color filter layer 17 have been largely shifted to the center of the pixel section relative to the central axis FC of the photoelectric transducer 12 by the pupil correction, the light emitted from the color filter layer 17 is incident on the end of light incident side of the waveguide 16, at a position distant from the central axis FC of the photoelectric transducer 12. In some cases, the light may be incident such that major part of the light protrudes from the end of light incident side of the waveguide 16. However, in this embodiment of the present invention, the position of the waveguide 16 is corrected such that the central axis LC of rays of the incident light which is incident on the end of light incident side of the waveguide 16 is aligned with the central axis C of the waveguide 16. Thus, almost all incident light emitted from the color filter layer 17 is incident on the end of light incident side of the waveguide 16 and is guided into the waveguide 16.

Also, referring to FIG. 7B, the green light is hardly bent by the microlens 18 as compared with the blue light, and is easily bent by the microlens 18 as compared with the red light. The incidence angle of the incident light which is incident on the end of light incident side of the waveguide 16 is smaller than that of the blue light, and larger than that of the red light. Since the microlens 18 and the color filter layer 17 have been shifted to the center of the angular field relative to the central axis FC of the photoelectric transducer 12 by the pupil correction, the light emitted from the color filter layer 17 is incident on the end of light incident side of the waveguide 16, at a position distant from the central axis FC of the photoelectric transducer 12. However, in this embodiment of the present invention, the position of the waveguide 16 is corrected such that the central axis LC of rays of the incident light which is incident on the end of light incident side of the waveguide 16 is aligned with the central axis C of the waveguide 16. Thus, almost all incident light emitted from the color filter layer 17 is incident on the end of light incident side of the waveguide 16 and is guided into the waveguide 16.

As described above, the shift amount of the central axis C of each waveguide 16 with respect to the center of the corresponding photoelectric transducer 12 is smaller as the wavelength of the light that is divided by the color filter layer 17 is smaller. Accordingly, even when the wavelengths of the incident light on the ends of light incident side of the waveguides 16 are different from one another, the waveguides 16 are respectively arranged in accordance with the wavelengths, the sensitivities of the unit pixels 21 are equivalent, and color shading does not Occur.

Second Exemplary Configuration of Solid State Image Pickup Device

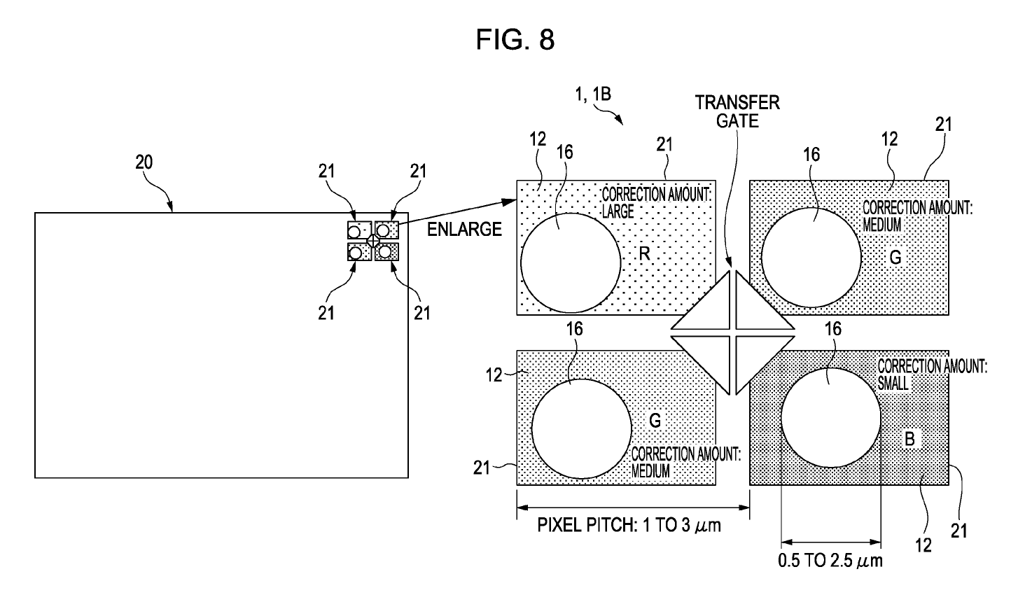

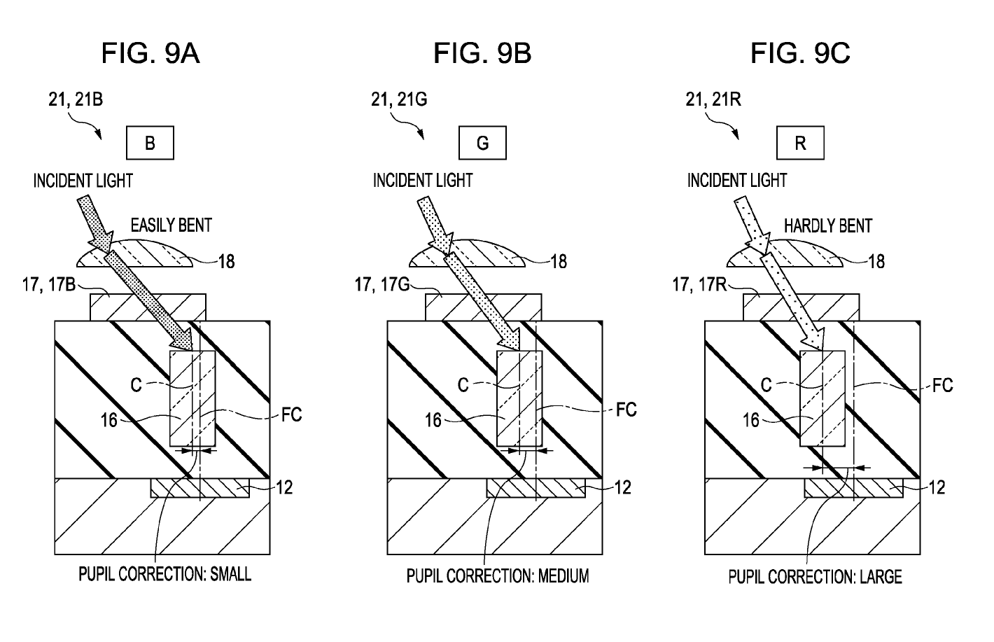

A second exemplary configuration of a solid state image pickup device according to the first embodiment of the present invention will be described with reference to a plan layout diagram in FIG. 8 and cross-sectional views in FIGS. 9A to 9C. In FIGS. 8, and 9A to 9C, for example, four unit pixels share a pixel transistor unit. The four unit pixels define a unit pixel group.

Referring to FIGS. 8, and 9A to 9C, a unit pixel group 22 includes, for example, two first unit pixels 21 (21G), a single second unit pixel 21 (21B), and a single third unit pixel 21 (21R). The first unit pixel 21G includes a photoelectric transducer 12 (12G) on which light with a first wavelength (for example, green light, G) divided by a color filter layer 17 (17G) is incident. The second unit pixel 21B includes a photoelectric transducer 12B on which light with a second wavelength (blue light, B) divided by a color filter layer 17B is incident. The second wavelength is smaller than the first wavelength (green light). The third unit pixel 21R includes a photoelectric transducer 12R on which light with a third wavelength (red light, R) divided by a color filter layer 17R is incident. The third wavelength is larger than the first wavelength.

Regarding the shift amount of the central axis C of each waveguide 16 with respect to the central axis FC of the corresponding photoelectric transducer 12 in the unit pixel group 22, the shift amount of the central axis C of the waveguide 16 with respect to the center of the photoelectric transducer 12 is smaller as the wavelength of the light that is divided by the color filter layer 17 is smaller. Also, the shift amount of the central axis C of each waveguide 16 with respect to the central axis FC of the corresponding photoelectric transducer 12 is smaller toward the center of the pixel section 20. In other words, the shift amount becomes larger from the center of the angular field (for example, the center of the pixel section) toward the edge of the angular field, and the shift direction from the center of the photoelectric transducer 12 is toward the center of the angular field.

The solid state image pickup device 1 (1B) is configured as described above. It is to be noted that the first unit pixel 21G, the second unit pixel 21B, and the third unit pixel 21R each have a basic structure similar to that described in the first exemplary configuration of the solid state image pickup device 1.

The solid state image pickup device 1B is so-called plural-pixel-sharing type (four-pixel-sharing type) that plural (or four) pixels share one floating diffusion, one amplifier transistor, and one select transistor. The shift amount of the central axis of each waveguide 16 with respect to the center of the corresponding photoelectric transducer 12 is smaller as the wavelength of the incident light that is incident on the end of light incident side of the waveguide 16 is larger. In such four-pixel-sharing type, regarding the four pixels (unit pixels 21), the shift amount (pupil correction amount) of the waveguide 16 of the third unit pixel 21R is larger than that of the first unit pixel 21G, and the shift amount (pupil correction amount) of the waveguide 16 of the second unit pixel 21B is smaller than that of the first unit pixel 21G.

Typically, the microlens 18 and the color filter layer 17 are subjected to the pupil correction so that the incident light is incident on the photoelectric transducer 12 in the central-axis direction. For example, the pupil correction is performed for the microlens 18 and the color filter layer 17 of incident light with a reference wavelength (for example, green light). In this case, since the blue light is easily bent by the microlens 18, the incidence angle of the blue light when being incident on the end of light incident side of the waveguide 16 becomes large. Even when the microlens 18 and the color filter layer 17 are largely shifted to the center of the angular field (for example, the center of the pixel section) relative to the central axis FC of the photoelectric transducer 12 by the pupil correction, the light emitted from the color filter layer 17 is incident on the end of light incident side of the waveguide 16, at a position close to the central axis FC of the photoelectric transducer 12. As a result, almost all incident light incident on the end of light incident side of the waveguide 16 is guided to the waveguide 16. In contrast, since the red light is hardly bent by the microlens 18 as compared with the blue light, the incidence angle of the red light when being incident on the end of light incident side of the waveguide 16 becomes smaller than that of the blue light. Since the microlens 18 and the color filter layer 17 have been shifted to the center of the pixel section relative to the central axis FC of the photoelectric transducer 12 by the pupil correction, the light emitted from the color filter layer 17 is incident on the end of light incident side of the waveguide 16, at a position distant from the central axis FC of the photoelectric transducer 12. In some cases, the light may be incident such that major part of the light protrudes from the end of light incident side of the waveguide 16. However, in this embodiment of the present invention, the position of the waveguide 16 is corrected such that the central axis LC of rays of the incident light which is incident on the end of light incident side of the waveguide 16 is aligned with the central axis C of the waveguide 16. Thus, the incident light emitted from the color filter layer 17 is incident on the end of light incident side of the waveguide 16 and is guided into the waveguide 16. Also, the green light is hardly bent by the microlens 18 as compared with the blue light, and is easily bent by the microlens 18 as compared with the red light. The incidence angle of the incident light which is incident on the end of light incident side of the waveguide 16 is smaller than that of the blue light, and larger than that of the red light. Since the microlens 18 and the color filter layer 17 have been shifted to the center of the angular field relative to the central axis FC of the photoelectric transducer 12 by the pupil correction, the light emitted from the color filter layer 17 is incident on the end of light incident side of the waveguide 16, at a position distant from the central axis FC of the photoelectric transducer 12. However, with this embodiment, the position of the waveguide 16 is corrected such that the center of rays of the incident light which is incident on the end of light incident side of the waveguide 16 is aligned with the central axis C of the waveguide 16. The incident light emitted from the color filter layer 17 is incident on the end of light incident side of the waveguide 16 and is guided into the waveguide 16. As described above, regarding the waveguides 16 within the unit pixel group 22, the shift amount of the central axis C of each waveguide 16 with respect to the central axis FC of the corresponding photoelectric transducer 12 is smaller as the wavelength that is divided by the color filter layer 17 is smaller. Accordingly, even when the wavelengths of the incident light on the ends of light incident side of the waveguides 16 are different from one another, the waveguides 16 are respectively arranged in accordance with the wavelengths, the sensitivities of the unit pixels 21 are equivalent, and color shading does not occur.

Third Exemplary Configuration of Solid State Image Pickup Device

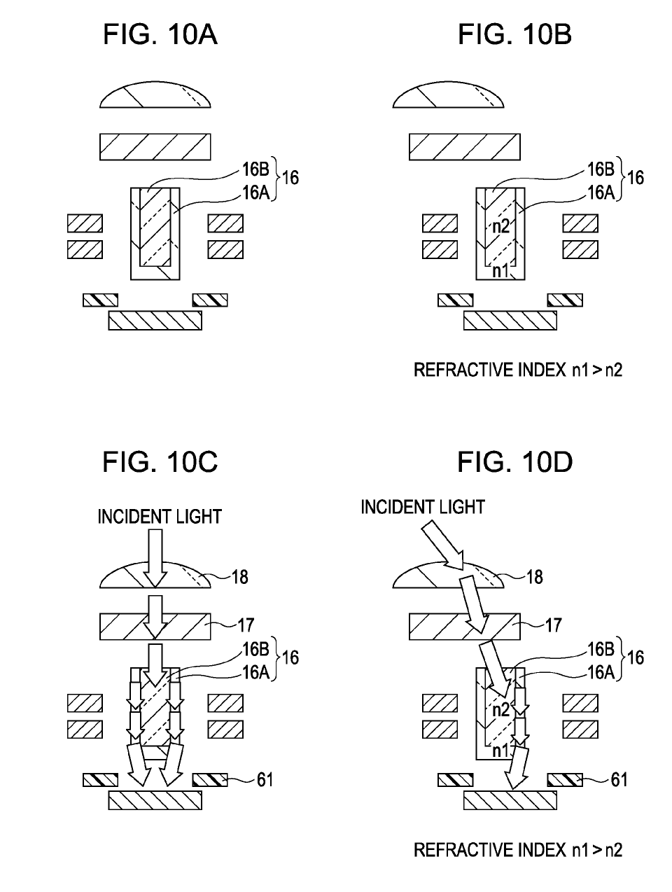

A third exemplary configuration of a solid state image pickup device according to the first embodiment of the present invention will be described below with reference to cross-sectional views in FIGS. 10A to 10D. Referring to FIGS. 10A to 10D, the solid state image pickup device of this third example has a similar configuration to that of the solid state image pickup device 1 of the first example except for the configuration of a waveguide 16.

Referring to FIGS. 10A and 10B, a unit pixel 21 includes a waveguide 16 having a first waveguide 16A and a second waveguide 16B. The first waveguide 16A defines a peripheral portion of the waveguide 16. The second waveguide 16B is formed inside the first waveguide 16A and has a refractive index lower than that of the first waveguide 16A. The first waveguide 16A may be also formed at a bottom portion of the second waveguide 16B. FIG. 10A illustrates a unit pixel 21 at a center portion of an angular field. FIG. 10B illustrates a unit pixel 21 at a position distant from the center of the angular field and close to an edge of the angular field. Similar to the solid state image pickup device 1 of the first example, pupil correction is performed for the waveguide 16 as the waveguide 16 is located closer to the edge of the angular field.

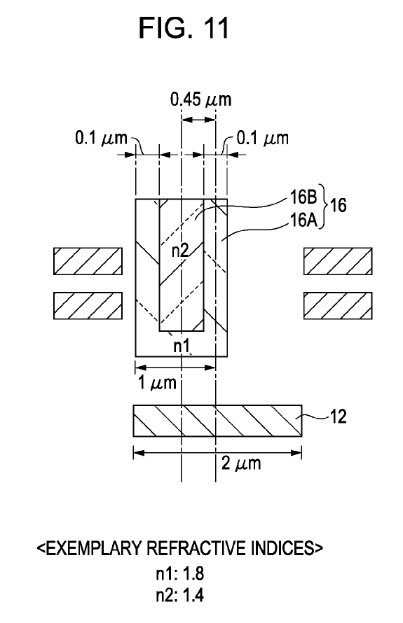

For example, referring to FIG. 11, a structure may include a waveguide 16 with a diameter of 1 μm for a photoelectric transducer 12 (for example, photo diode) with a size of 2 μm. The structure may be designed such that pupil correction is performed by 0.45 μm for a portion closest to the edge of the angular field. A first waveguide 16A is formed within the first waveguide 16A to define side wall portions of the waveguide 16, by using a film (for example, a film made of a material selected from nitrides) having a refractive index n1 of about 1.8. The second waveguide 16B is formed with a film made of a material selected from resins and having a refractive index n2 of about 1.4. A side wall portion of the first waveguide 16A has a film thickness of about 100 nm. Accordingly, both side wall portions of the first waveguide 16 has a thickness of 200 nm. The second waveguide 16B has a diameter of 800 nm. If the film of the first waveguide 16A is formed with a film made of a material selected from nitrides (for example, silicon nitride film), the film can have an effect of a passivation film.

Next, optical paths of incident light will be described with reference to FIGS. 10C and 10D. FIG. 10C illustrates the unit pixel 21 at the center portion of the angular field. FIG. 10D illustrates the unit pixel 21 at the position distant from the center of the angular field and close to the edge of the angular field. Referring to FIG. 10C, incident light transmitted through a microlens 18 and a color filter layer 17 is mainly condensed to the first waveguide 16A serving as the side wall portions because, in the waveguide 16 at the center of the angular filed, the first waveguide 16A in the side wall portions has the higher refractive index than that of the second waveguide 16B in the center portion.

In contrast, referring to FIG. 10D, when pupil correction is performed for the waveguide 16, rays of the incident light transmitted through a microlens 18 and a color filter layer 17 can be brought to the center of a photoelectric transducer 12 although the waveguide 16 is located at the position close to the edge of the angular field (the refractive indices satisfy n1>n2 as illustrated). In particular, obliquely incident light which is incident on the waveguide 16 enters from the second waveguide 16B to the first waveguide 16A, is reflected within the first waveguide 16A having a higher refractive index than that of the second waveguide 16B, is guided to an end of light exit side, and is emitted to the photoelectric transducer 12. Since light is guided through the waveguide 16, it is reasonable to determine the refractive index of the material for the waveguide 16 (the first waveguide 16A) to be higher than a refractive index of a material for other member around the waveguide 16 (the first waveguide 16A). In particular, pupil correction has been performed for the waveguide 16 at the edge of the angular field such that the central axis C of the waveguide 16 is aligned with the central axis LC of rays of the incident light on the end of light incident side of the waveguide 16. Hence, the central axis C of the waveguide 16 has been shifted toward the center of the angular field with respect to the center of the photoelectric transducer 12. Accordingly, even if the incident light, which is incident on the end of light incident side of the waveguide 16, is incident on the second waveguide 16B, the light enters the first waveguide 16A having the higher refractive index than that of the second waveguide 16B. The light propagates within the first waveguide 16A and is emitted from the emission end toward the photoelectric transducer 12. Also, since the oblique incident light is emitted from a position near the center of the angular field toward a position near the edge of the angular field, the incident light is incident on the second waveguide 16B in an oblique manner toward the edge of the angular field. Thus, the light propagates through a portion near the edge of the angular field of the first waveguide 16A. That is, since the portion near the edge of the angular field of the first waveguide 16A is located close to the center of the photoelectric transducer 12, the incident light incident on the second waveguide 16B propagates through the first waveguide 16A and is efficiently emitted to the photoelectric transducer 12.

Since the waveguide 16 has the structure including the first waveguide 16A and the second waveguide 16B, the amount of leak light until the light reaches from the bottom portion of the waveguide 16 to the photoelectric transducer 12 can be minimized. Even if a polysilicon electrode 61 or the like is arranged near the photoelectric transducer 12, the light is incident on the center of the photoelectric transducer 12 or a position near the center, the amount of components eclipsed by the polysilicon electrode 61 can be decreased. If the waveguide 16 has the aforementioned structure made of a single material, by decreasing the diameter of the waveguide 16, the amount of light eclipsed by the polysilicon electrode 61 can be decreased.

Also, pupil correction may be performed for the photoelectric transducer 12, a pixel transistor (not shown), and a wiring portion 15 of a wiring layer 13 (not shown). Accordingly, the amount of light eclipsed by the pixel transistor can be decreased, and color shading can be decreased.

### 2. Second Embodiment

First Exemplary Method of Manufacturing Solid State Image Pickup Device

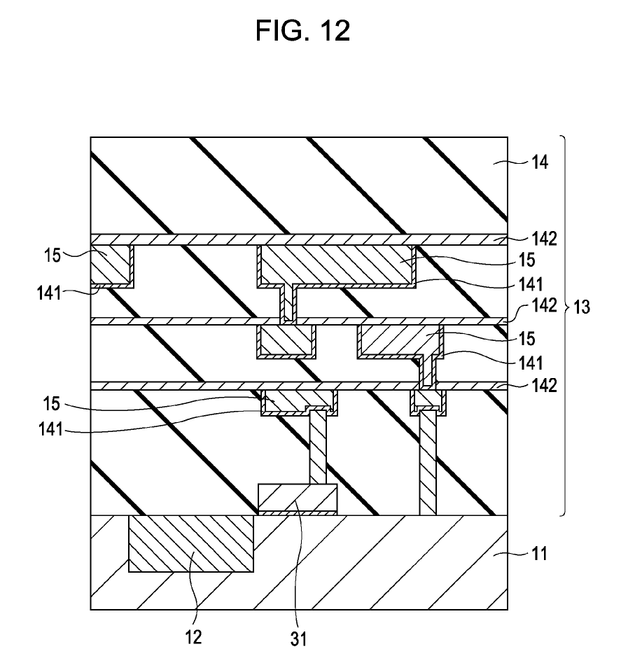

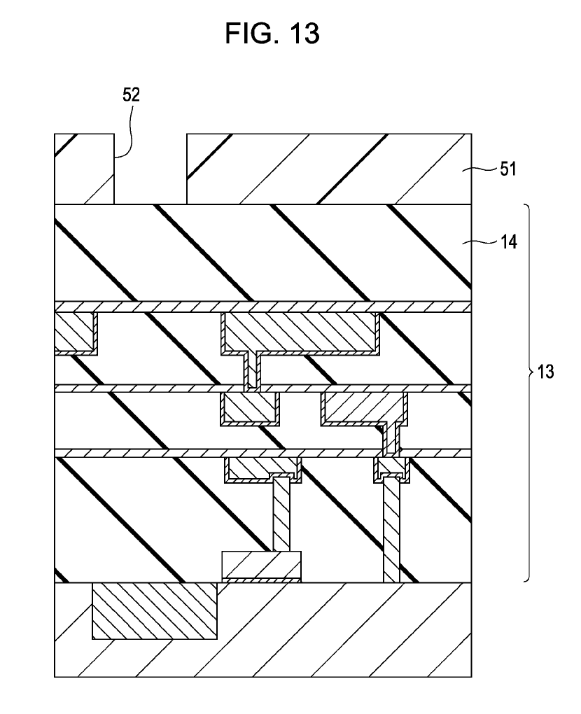

Next, a first exemplary method of manufacturing a solid state image pickup device according to a second embodiment of the present invention will be described with reference to FIGS. 12 to 21.

Referring to FIG. 12, a photoelectric transducer 12 is formed on a surface (light incident side) of a semiconductor substrate 11. The photoelectric transducer 12 converts incident light into a signal charge. Also, a transfer gate 31 is formed on the semiconductor substrate 11. The transfer gate 31 reads the signal charge which has been subjected to the photoelectric transduction by the photoelectric transducer 12. Further, though not shown, a pixel transistor and a peripheral circuit unit are formed on the semiconductor substrate 11. The pixel transistor amplifies and outputs the signal charge which has been subjected to the photoelectric transduction by the photoelectric transducer 12. The peripheral circuit unit processes the amplified and output signal. The semiconductor substrate 11 uses, for example, a silicon substrate. Alternatively, the semiconductor substrate 11 may use a silicon on insulator (SOI) substrate. In this case, the photoelectric transducer 12, the transfer gate 31, etc., are formed on a silicon layer of the SOI substrate.

A plurality of unit pixels 21 each having the photoelectric transducer 12 are arranged in an array in line and row directions of the semiconductor substrate 11 to define a pixel section 20.

An insulating film is formed on the semiconductor substrate 11 to cover the photoelectric transducer 12, the transfer gate 31, the pixel transistor, the peripheral circuit unit, etc., thereby forming a wiring layer 13. For example, the wiring layer 13 is formed such that a plurality of layers including wiring portions 15 are formed in an interlayer insulating film 14. Barrier metal layers 141 are formed around the wiring portions 15. In the interlayer insulating film 14, for example, silicon carbide (SiC) films are formed as diffusion preventing films 142 that prevent metal and the like from being diffused from the wiring portions 15. The interlayer insulating film 14 may be formed of a silicon oxide (SiO₂) film. The surface of the interlayer insulating film 14 is planarized. The wiring portions 15 are not formed in an area above the photoelectric transducer 12.

Next, referring to FIG. 13, a resist film 51 is formed on the interlayer insulating film 14 located at the top of the wiring layer 13, through a typical resist process. With a lithography technique, an opening 52 is formed in the resist film 51 in an area above a region where a waveguide is to be formed. When the layout of the opening 52 is attained, pupil correction is performed for a waveguide as described with reference to FIGS. 3A to 3C, 4A and 4B, etc. In particular, the opening 52 is formed such that the central axis of the waveguide to be formed below the opening 52 is aligned with the center of rays of incident light which is incident on an end of light incident side of the waveguide.

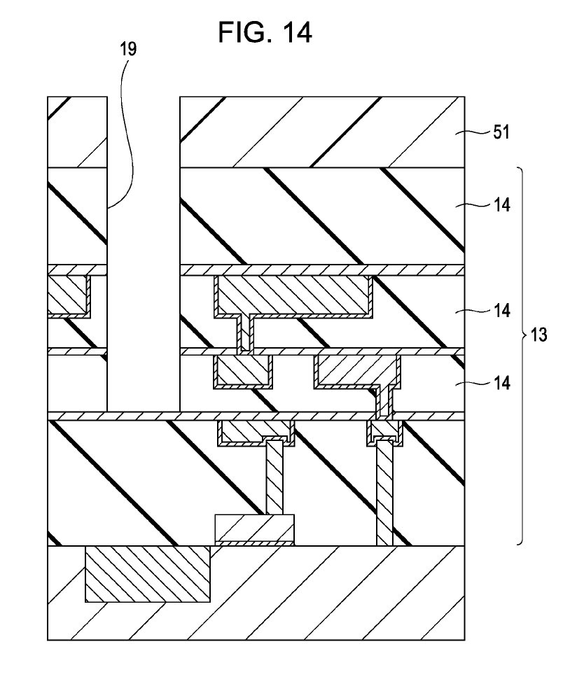

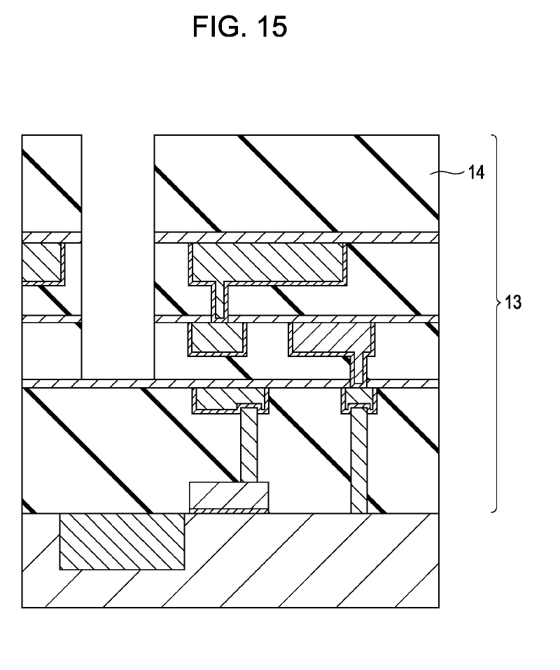

Next, referring to FIG. 14, a waveguide hole 19 for formation of a waveguide is made in the interlayer insulating film 14 in the wiring layer 13 by dry etching with the resist film 51 serving as an etching mask. At this time, the waveguide hole 19 is formed such that the side walls of the waveguide hole 19 are vertical and the depth of the waveguide hole 19 is about 4 to 5 μl. Also, the waveguide hole 19 has a constant cross section from the opening toward the bottom portion. The shape of the opening may be a circle, an oval (including an ellipse), or the like. Alternatively, the shape of the opening of the waveguide hole 19 may be a rectangular, such as a square, with rounded corners.

Next, referring to FIG. 15, the resist film 51 (see FIG. 14) is removed, to allow the surface of the interlayer insulating film 14 in the wiring layer 13 to be exposed.

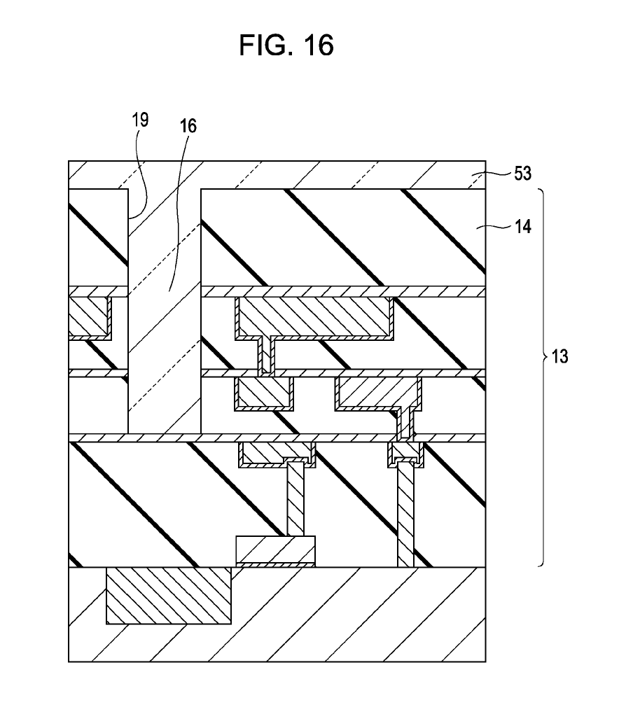

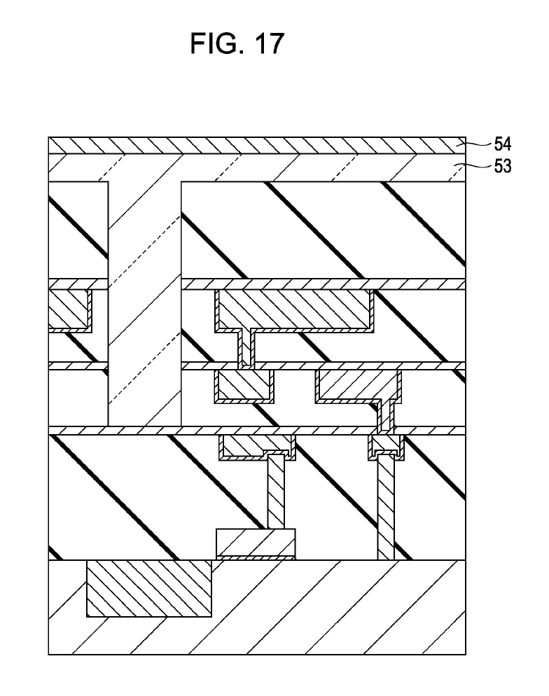

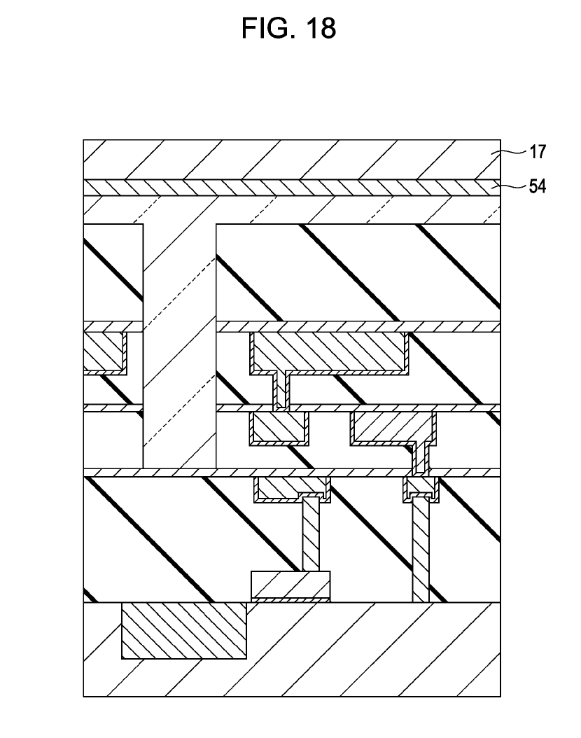

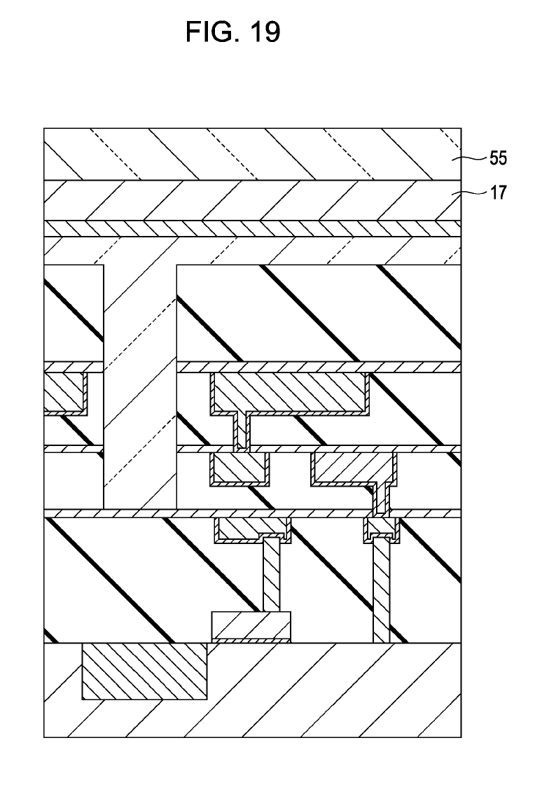

Next, referring to FIG. 16, the waveguide hole 19 is filled with a waveguide material film 53.

For the waveguide material, a material with a higher refractive index than the material of the interlayer insulating film 14 in the wiring layer 13 is selected. For example, when the interlayer insulating film 14 is a film made of a material selected from silicon oxides and having a refractive index of 1.4, the waveguide material film 53 is a film with a refractive index of 1.4 or higher. The waveguide material film 53 uses a film made of a material selected from nitrides and having a refractive index of about 1.8. For example, a silicon nitride film may be used. The waveguide material film 53 is also formed on the interlayer insulating film 14. The waveguide material film 53 is formed by coating, chemical vapor deposition, etc. Thus, the waveguide 16 is formed with the waveguide material film 53 filled in the waveguide hole 19.

Next, referring to FIG. 17, a planarizing and insulating film 54 for planarizing the surface of the waveguide material film 53 is formed. The planarizing and insulating film 54 is formed of, for example, a resin layer.

Next, referring to FIG. 18, a color filter layer 17 is formed on the planarizing and insulating film 54. The color filter layer 17 is formed by applying a color filter material, and then, by patterning through exposing, developing, etc. The color filter layer 17 uses, for example, a red color filter, a green color filter, and a blue color filter, to correspond to colors to be sensed by respective photoelectric transducers 12. The layout of the color filter layer 17 is also subjected to pupil correction.

Next, referring to FIG. 19, a lens forming film 55 is formed on the color filter layer 17. The lens forming film 55 is a material for a microlens (also called on chip lens). The lens forming film 55 is formed of, for example, a light-transmissive resin film.

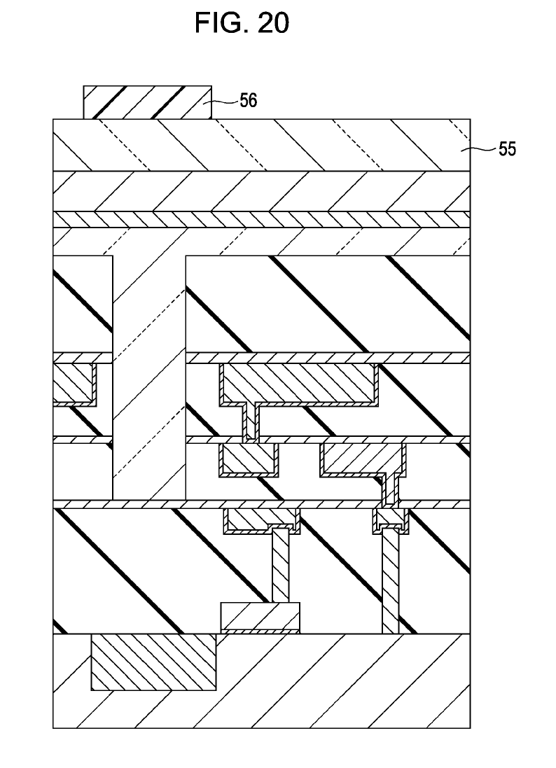

Next, referring to FIG. 20, a resist pattern 56 for a microlens is formed on the lens forming film 55. The layout of the resist pattern 56 is subjected to pupil correction. Then, though not shown, the resist pattern 56 is molded to have a lens shape. Then, the shape of the resist pattern 56 molded to have the lens shape is transferred to the lens forming film 55 by etch back.

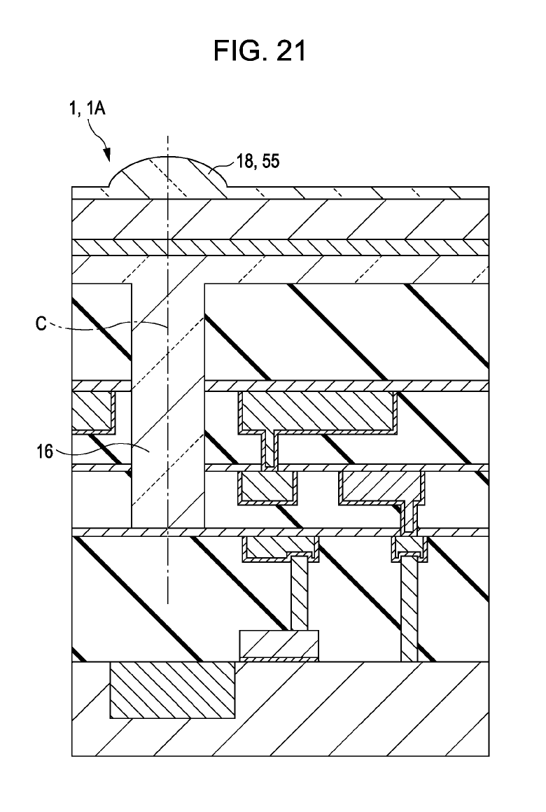

As a result, referring to FIG. 21, a microlens 18 is formed in the lens forming film 55.

In the above-described manufacturing method, the waveguide 16 has a columnar body with a constant cross section from an end of light incident side to an end of light exit side. The light vertically incident on the end of light incident side of the waveguide 16 is not reflected by a side wall of the waveguide 16 but is transmitted through the waveguide 16. Thus, decrease in sensitivity is restricted. Also, since the center of rays of the incident light incident on the end of light incident side of the waveguide 16 is aligned with the central axis of the waveguide 16, the incident light is efficiently guided to the waveguide 16. Accordingly, a solid state image pickup device 1 (1A) that can be manufactured, which provides an effect and an advantage similar to those provided by the solid state image pickup device described in the first example of the first embodiment.

Second Exemplary Method of Manufacturing Solid State Image Pickup Device

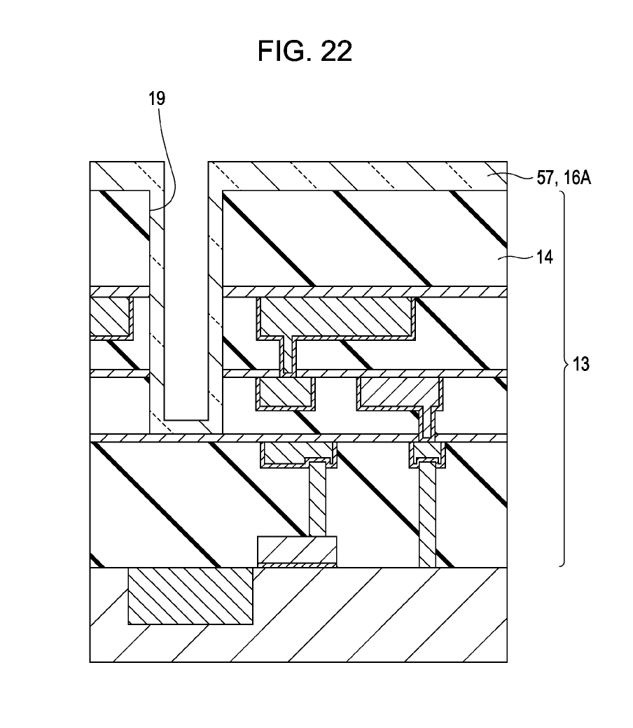

Next, a second exemplary method of manufacturing a solid state image pickup device according to a second embodiment of the present invention will be described with reference to FIGS. 22 to 28.

Referring to FIG. 22, a waveguide hole 19 is formed in a wiring layer 13 in a manner similar to that of the first exemplary manufacturing method. Then, a first waveguide material film 57 for a first waveguide 16A is formed on the inner side of the waveguide hole 19. The first waveguide material film 57 is also formed on the interlayer insulating film 14. The first waveguide material film 57 is made of a material having a higher refractive index than that of the interlayer insulating film 14. For example, the first waveguide material film 57 may be a film made of a material selected from nitrides. For example, such a film may be a silicon nitride (SiN) film or a silicon oxynitride film. Also, if the first waveguide material film 57 is formed with a silicon nitride film, the film serves as a passivation film. Although the material of the first waveguide material film 57 does not have to be a film of a material selected from nitrides, a silicon nitride film with a high refractive index of, for example, n=1.8 may be used. Regarding the film thickness, for example, a side wall portion may have a thickness of about 100 nm. The film thickness of the first waveguide material film 57 may be desirably determined as long as a second waveguide, which is formed next, can be formed inside the first waveguide 16A. The film forming method may be coating. Of course, the film forming method may be other method, such as chemical vapor deposition.

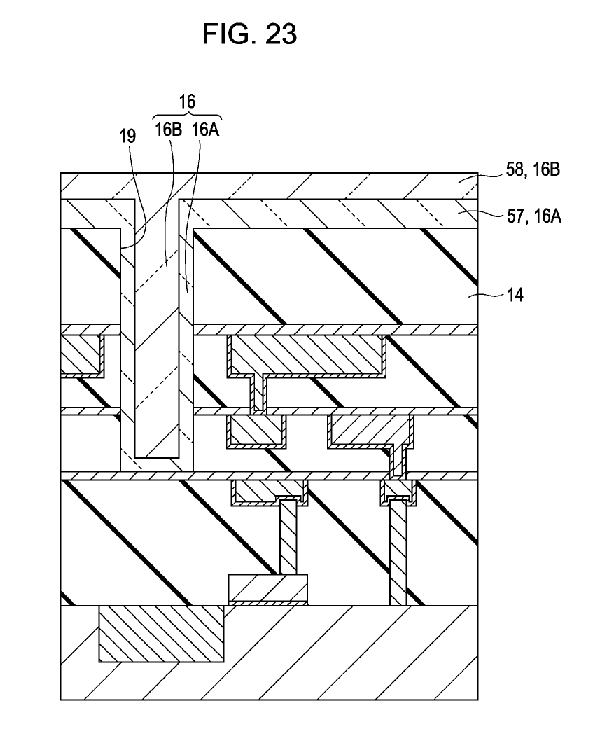

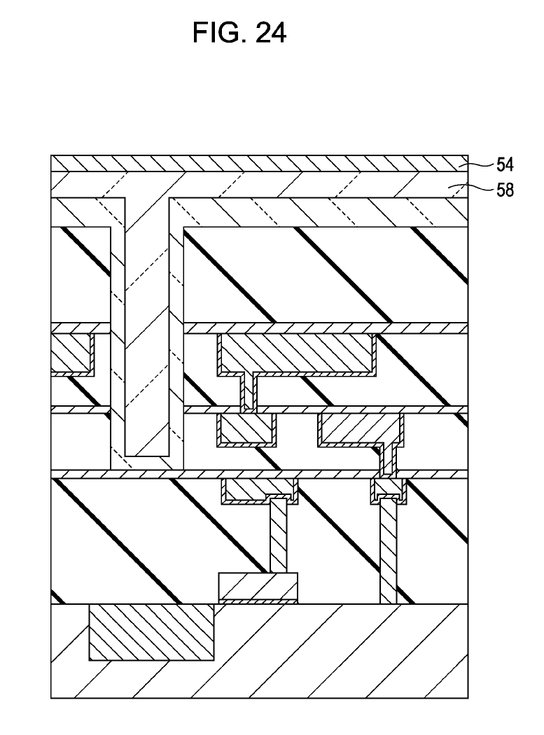

Next, referring to FIG. 23, the waveguide hole 19, in which the first waveguide material film 57 has been formed, is filled with a second waveguide material film 58, thereby forming the second waveguide 16B. The second waveguide material film 58 is a material having a lower refractive index than that of the first waveguide material film 57. For example, a resin film with a refractive index of about 1.4 (for example, resin with good light transmissivity, such as PMMA) or a film made of a material selected from silicon oxides may be selected. The waveguide material film 53 is also formed on the interlayer insulating film 14. The each of the waveguide material films described above may be formed by coating, chemical vapor deposition, etc. In this way, the first waveguide 16A made of the first waveguide material film 57 is formed on the inner side of the waveguide hole 19, and the second waveguide 16B made of the second waveguide material film 58 is formed on the inner side of the first waveguide 16A.

Next, referring to FIG. 24, a planarizing and insulating film 54 for planarizing the surface of the second waveguide material film 58 is formed. The planarizing and insulating film 54 is formed of, for example, a resin layer.

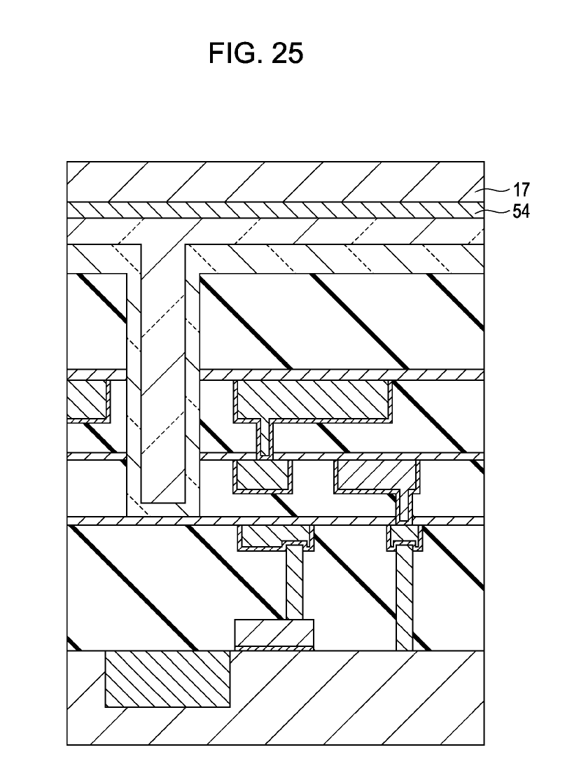

Next, referring to FIG. 25, a color filter layer 17 is formed on the planarizing and insulating film 54. The color filter layer 17 is formed by applying a color filter material, and then, by patterning through exposing, developing, etc. The color filter layer 17 uses, for example, a red color filter, a green color filter, and a blue color filter, to correspond to colors to be sensed by respective photoelectric transducers 12. The layout of the color filter layer 17 is also subjected to pupil correction.

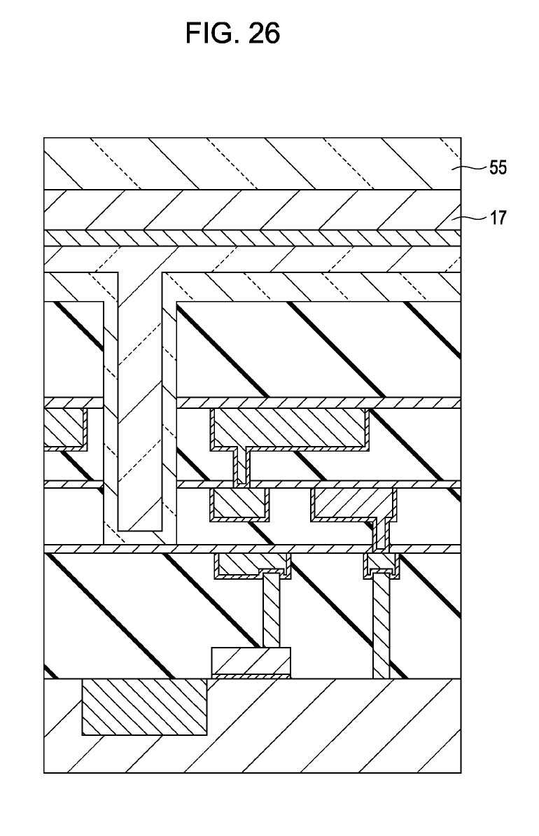

Next, referring to FIG. 26, a lens forming film 55 is formed on the color filter layer 17. The lens forming film 55 is a material for a microlens (also called on chip lens). The lens forming film 55 is formed of, for example, a light-transmissive resin film.

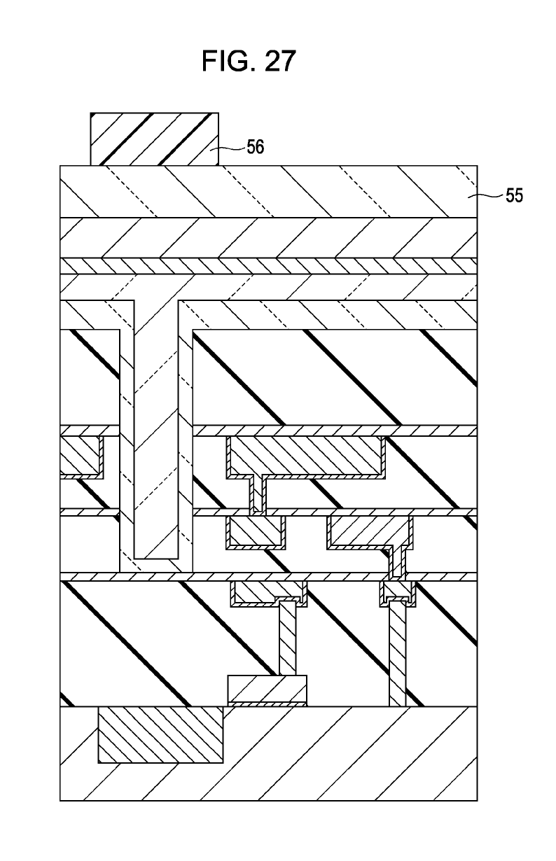

Next, referring to FIG. 27, a resist pattern 56 for a microlens is formed on the lens forming film 55. The layout of the resist pattern 56 is subjected to pupil correction. Then, though not shown, the resist pattern 56 is molded to have a lens shape. Then, the shape of the resist pattern 56 molded to have the lens shape is transferred to the lens forming film 55 by etch back.

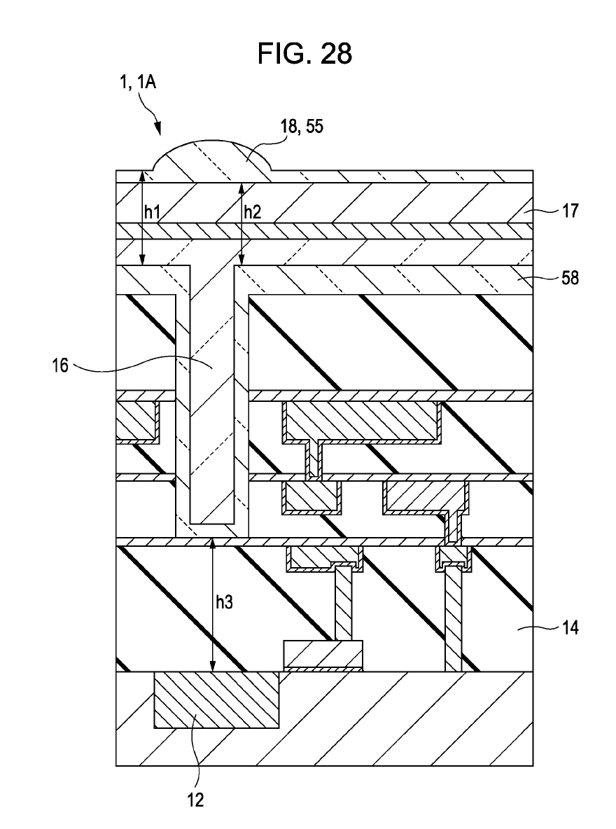

As a result, referring to FIG. 28, a microlens 18 is formed in the lens forming film 55. A height h1 from the surface of the second waveguide material film 58 to the base portion of the microlens 18 is, for example, 1 to 3 μm. Also, a height h2 from the surface of the second waveguide material film 58 to the bottom surface of the color filter layer 17 is, for example, 0.5 to 2.5 μm. Further, a height h3 from the surface of the photoelectric transducer 12 to the end of light exit side for incident light of the waveguide 16 is, for example, 0.3 to 2 μl.

With the second manufacturing method, the waveguide 16 is formed such that the second waveguide 16B is formed inside whereas the first waveguide 16A with a relatively higher refractive index is formed around the second waveguide 16B. Light entering from the second waveguide 16B to the first waveguide 16A propagates through the first waveguide 16A and is emitted therefrom.

Accordingly, a solid state image pickup device 1 (1B) that can provide an effect and an advantage similar to those provided by the solid state image pickup device described in the first example of the first embodiment.

### 3. Third Embodiment

Example Configuration of Image Pickup Device

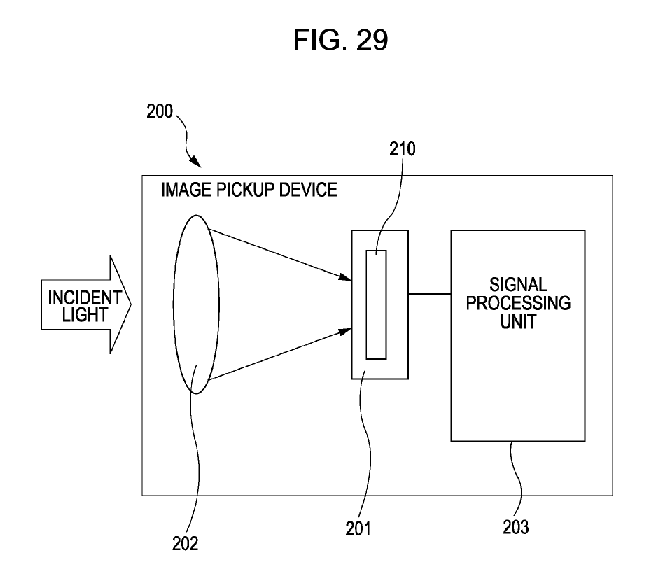

Next, an exemplary configuration of an image pickup device according to a third embodiment of the present invention will be described with reference to FIG. 29. This image pickup device uses a solid state image pickup device according to the embodiment of the present invention.

Referring to FIG. 29, an image pickup device 200 includes an image pickup unit and a solid state image pickup device 210. A light condensing optical unit 202 for forming an image is provided at the light-condensing side of the image pickup unit 201. The image pickup unit 201 is connected to a signal processing unit 203. The signal processing unit 203 includes a drive circuit that drives the image pickup unit 201; and a signal processing circuit that processes a signal, which has been subjected to photoelectric transduction by the solid state image pickup device 210, to be an image. The image signal processed by the signal processing unit 203 may be stored in an image storage unit (not shown). In such an image pickup device 200, the solid state image pickup device 210 may use the solid state image pickup device 1 described according to the aforementioned embodiment.

Since the image pickup device 200 according to this embodiment uses the solid state image pickup device 1 according to the aforementioned embodiment, the color unevenness (color shading) due to shading depending on a wavelength in the solid state image pickup device 1 can be decreased. The sensitivity can be increased, and hence an image with high quality can be obtained.

The image pickup device 200 may be formed as one chip, or a module in which an image pickup unit and a signal processing unit or an optical system packaged and hence which has an image pickup function. The image pickup device 200 is, for example, a camera or a mobile device having an image pickup function. Also, “image pickup” includes not only capturing an image during normal shooting with a camera, but also detecting a finger print etc., in the broad sense.

### 4. Fourth Embodiment

Exemplary Configuration of Solid State Image Pickup Device

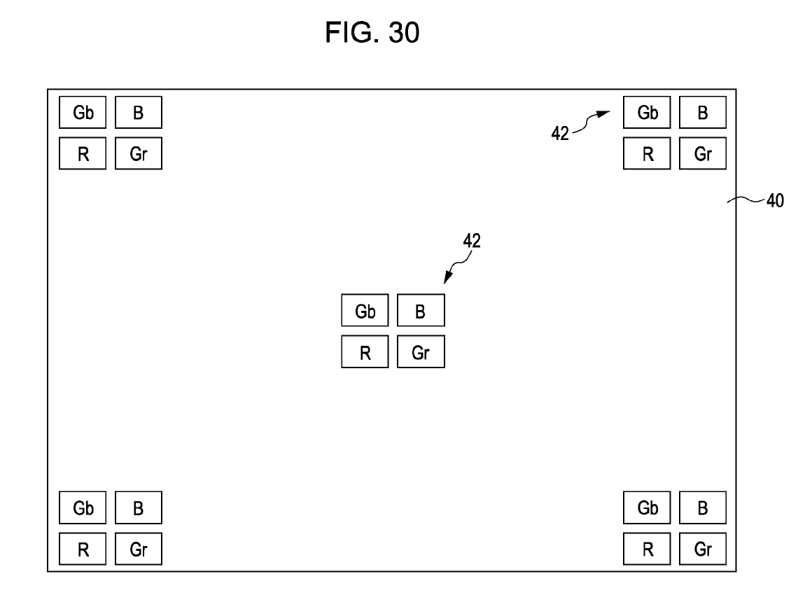

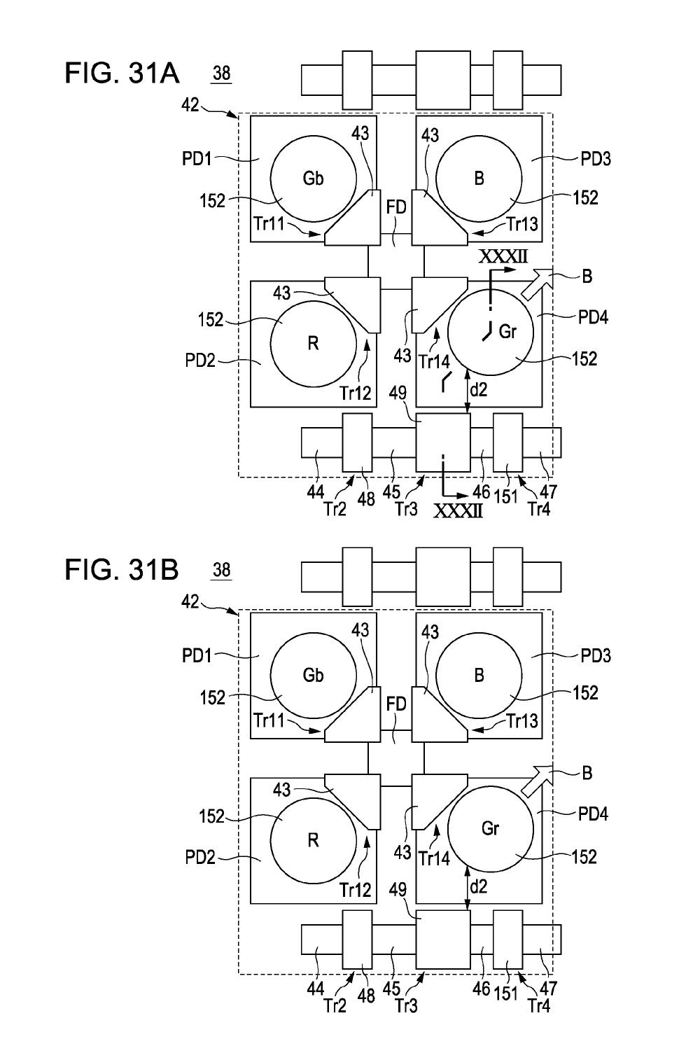

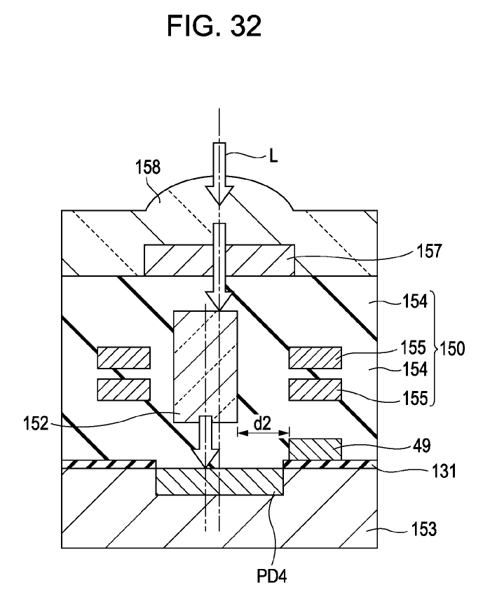

FIGS. 30 to 32 each illustrate a solid state image pickup device according to a forth embodiment of the present invention. A solid state image pickup device of this embodiment is a MOS solid state image pickup device of four-pixel-sharing type that four pixels share one floating diffusion, one amplifier transistor, and one select transistor. FIG. 30 is a plan view showing a pixel section in which a plurality of unit pixel groups of four-pixel-sharing type are two-dimensionally arrayed. FIGS. 31A and 31B are plan views showing unit pixel groups at the center of an angular field and at an edge of the angular field of the pixel section. FIG. 32 is a cross-sectional view taken along line XXXII-XXXII in FIG. 31A.

Hereinafter, reference sign 40 denotes a pixel section, 38 denotes a solid state image pickup device, 42 denotes a unit pixel group, PD (PD1 to PD4) denotes photoelectric transducers, Tr11 to Tr14, Tr2, Tr3, and Tr4 denote pixel transistors, 43 denotes a transfer gate electrode, 48 denotes a reset gate electrode, 49 denotes an amplifier gate electrode, 151 denotes a select gate electrode, 152 denotes a waveguide, 154 denotes an interlayer insulating film, 155 denotes a wiring portion, 155a denotes a protruding portion, 150 denotes a wiring layer, 157 denotes a color filter layer, 158 denotes a microlens, and L denotes incident light.

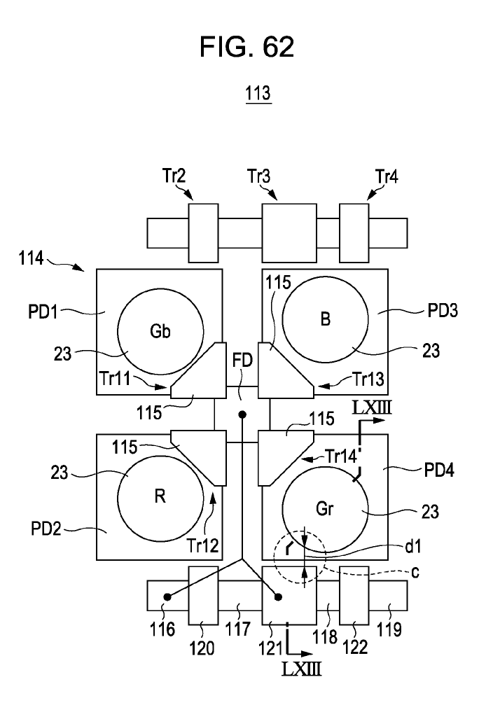

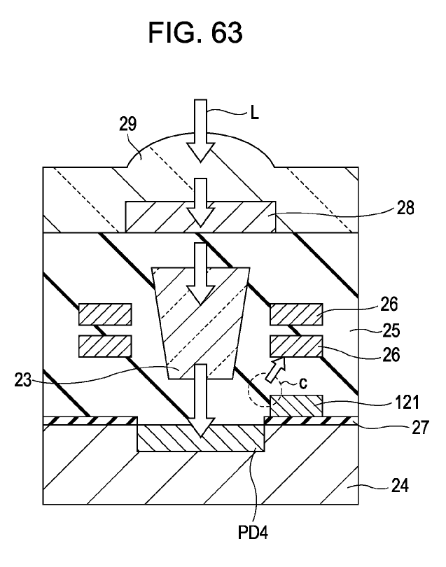

First, for the convenience of understanding of the fourth embodiment, a comparative example before improvement will be described with reference to FIGS. 62 and 63. This comparative example is a MOS solid state image pickup device of four-pixel-sharing type that four pixels share one floating diffusion, one amplifier transistor, and one select transistor. A MOS solid state image pickup device 113 of the comparative example includes a pixel section in which a plurality of unit pixel groups are arrayed. In each of the unit pixel groups, a plurality of pixels share a single pixel transistor. In particular, the MOS solid state image pickup device 113 includes a unit pixel group 114 of four-pixel-sharing type, in which four photo diodes PD serving as photoelectric transducers share a single pixel transistor unit. More specifically, the unit pixel group 114 includes four photo diodes PD (PD1 to PD4), four transfer transistors Tr (Tr11 to Tr14), and a single floating diffusion FD. Further, the unit pixel group 114 includes a single reset transistor Tr2, an amplifier transistor Tr3, and a select transistor Tr4. Transfer gate electrodes 115 made of polysilicon are arranged between the floating diffusion FD, which is located at the center of the unit pixel group 114, and the photo diodes PD1 to PD4. Thus, the four transfer transistors Tr11 to Tr14 for the four photo diodes PD are formed.

The reset transistor Tr2, the amplifier transistor Tr3, and the select transistor Tr4 are continuously horizontally arranged below the photo diodes PD1 to PD4. The reset transistor Tr2 includes a diffusion region 116, a diffusion region 117, and a reset gate electrode 120. The amplifier transistor Tr3 includes the diffusion region 117, a diffusion region 118, and an amplifier gate electrode 121. The select transistor Tr4 includes the diffusion region 118, a diffusion region 119, and a select gate electrode 122. In the unit pixel group 114, a base layer including gate electrodes made of polysilicon has an asymmetrical arrangement with respect to the boundary of adjacent pixels. In particular, the pixel transistor unit including the reset transistor Tr2, the amplifier transistor Tr3, and the select transistor Tr4 are asymmetrically arranged with respect to the boundary between the pixels Gb and R, and the pixels Gr and B. Also, the transfer gate electrodes 115 of pixels Gr, R, Gb, and B are asymmetrically arranged with respect to the respective boundaries of the pixels Gr, R, Gb, and B.

Waveguides 23 are respectively formed for the photo diodes PD1 to PD4. In this example, a Bayer pattern color filter layer is used. In the layer, plural unit pixel groups 114 of four-pixel-sharing type that four pixels share one floating diffusion, one amplifier transistor, and one select transistor are repeatedly arrayed. Each of the unit pixel groups 114 includes a red pixel R, a first green pixel Gb, a blue pixel B, and a second green pixel Gr.

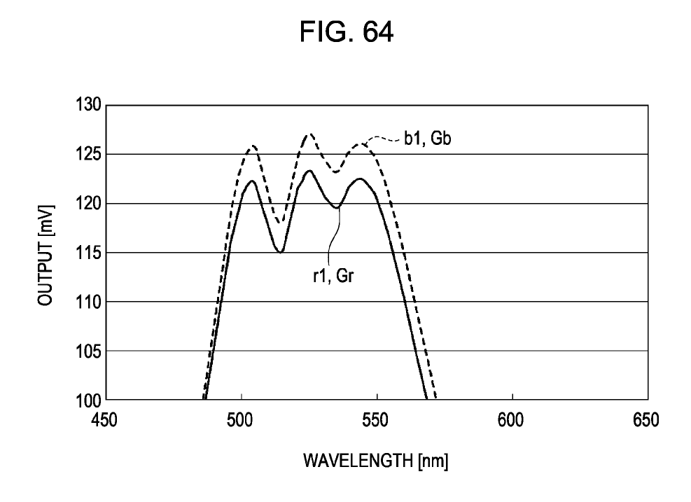

FIG. 63 is a cross-sectional view taken along line LXIII-LXIII passing through the second pixel Gr in FIG. 62. Referring to FIG. 64, a photo diode PD4 as a photoelectric transducer is formed on a surface of a semiconductor substrate 24, and a plurality of layers including wiring portions 26 are formed above the semiconductor substrate 24 with an interlayer insulating film 25 interposed therebetween. A waveguide 23 is formed above the photo diode PD4 such that the waveguide 23 is embedded in the interlayer insulating film 25. A color filter layer 28 is formed above the waveguide 23. A microlens 29 (also called on chip lens) is formed on the color filter layer 28. Also, an amplifier gate electrode 121 is formed near the photo diode PD4. A gate insulating film 27 is arranged between the amplifier gate electrode 121 and the photo diode PD4.

In the solid state image pickup device 113 of the comparative example, incident light L is transmitted through the microlens 29 and the waveguide 23, and is incident on the photo diode PD of each pixel. At this time, in the second green pixel Gr, part of the incident light L transmitted through the waveguide 23 is eclipsed by the amplifier gate electrode 121 arranged near the second green pixel Gr and having a large gate length, as indicated by circle c in FIGS. 62 and 63. In the first green pixel Gb, the incident light L transmitted through the waveguide 23 is incident on the photo diode PD1 without being affected by the reset gate electrode 120 or the amplifier gate electrode 121. Owing to this, as shown in a graph plotting the wavelengths and outputs in FIG. 64, the sensitivity of the second green pixel Gr (see curve r1) is lower than the sensitivity of the first green pixel Gb (see curve b1). Thus, a difference in sensitivity appears between the green pixels Gr and Gb.

In contrast, the solid state image pickup device according to the fourth embodiment can control the sensitivity such that the sensitivities of first and second green pixels Gb and Gr are equivalent within a unit pixel group of four-pixel-sharing type that four pixels share one floating diffusion, one amplifier transistor, and one select transistor.

Referring to FIG. 31, a solid state image pickup device 38 according to the fourth embodiment includes a pixel section in which a plurality of unit pixel groups 41 are arrayed. In each of the unit pixel groups 42, a plurality of pixels share a single pixel transistor. In particular, the solid state image pickup device 38 includes a unit pixel group 42 of four-pixel-sharing type that four pixels share one floating diffusion, one amplifier transistor, and one select transistor, in which four photo diodes PD serving as photoelectric transducers share a single pixel transistor unit. More specifically, the unit pixel group 42 includes four photo diodes PD (PD1 to PD4), four transfer transistors Tr (Tr11 to Tr14), and a single floating diffusion FD. Further, the unit pixel group 42 includes a single reset transistor Tr2, an amplifier transistor Tr3, and a select transistor Tr4. The floating diffusion FD is arranged at the center of the four photo diodes PD1 to PD4 in an array of 2×2. Transfer gate electrodes 43 made of polysilicon are arranged between the floating diffusion FD and the photo diodes PD1 to PD4. Thus, the four transfer transistors Tr11 to Tr14 for the four photo diodes PD are formed.

The reset transistor Tr2, the amplifier transistor Tr3, and the select transistor Tr4 are continuously horizontally arranged below the four photo diodes PD1 to PD4. The reset transistor Tr2 includes a diffusion region 44, a diffusion region 45, and a reset gate electrode 48. The amplifier transistor Tr3 includes the diffusion region 45, a diffusion region 46, and an amplifier gate electrode 49. The select transistor Tr4 includes the diffusion region 46, a diffusion region 47, and a select gate electrode 151.

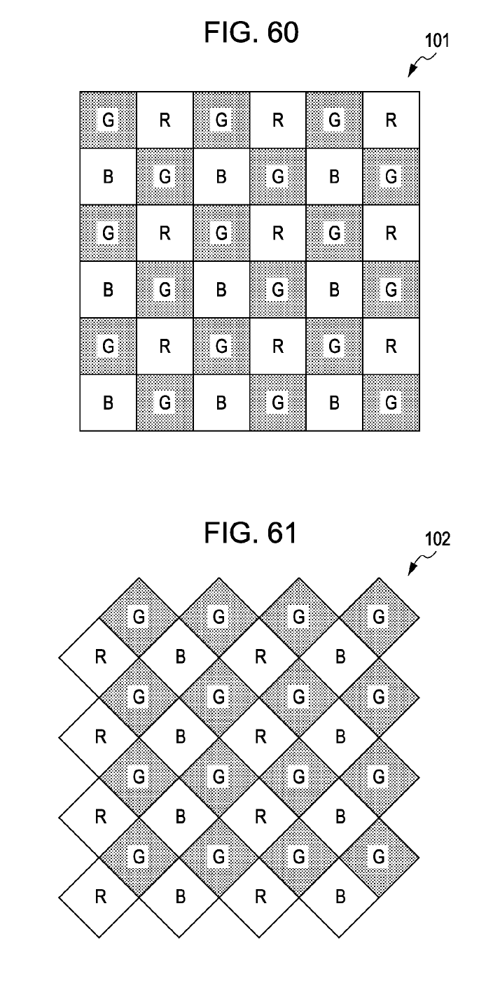

Waveguides 152 are respectively formed for the photo diodes PD1 to PD4. In this embodiment, a color filter layer 157 uses a Bayer pattern color filter 101 shown in FIG. 60. Thus, in this embodiment, referring to FIG. 30, plural unit pixel groups 42 of four-pixel-sharing type that four pixels share one floating diffusion, one amplifier transistor, and one select transistor are repeatedly arrayed, thereby forming a pixel section 40. Each of the unit pixel groups 42 includes a red pixel R, a first green pixel Gb, a blue pixel B, and a second green pixel Gr.

The pixels R, Gb, B, and Gr have a basic structure similar to that shown in FIG. 32. In particular, the pixels R, Gb, B, and Gr each have a photo diode PD as a photoelectric transducer on a surface of a semiconductor substrate 153. A wiring layer 150 is formed above the semiconductor substrate 153. In the wiring layer 150, a plurality of layers including wiring portions 155 are arranged with an interlayer insulating film 154 interposed therebetween in an area except the area above the photo diode PD. A waveguide 152 is formed above the photo diode PD such that the waveguide 152 is embedded in the interlayer insulating film 154. The waveguide 152 guides incident light to the photo diode PD. The surface of the interlayer insulating film 154 is planarized. A color filter layer 157 that divides incident light to correspond to the waveguide 152 is formed on the planarized surface. A microlens 158 (also called on chip lens) is formed on the color filter layer 157. Gate electrodes 43, 48, 49, and 151 made of polysilicon of a pixel transistor are formed with a gate insulating film 131 interposed therebetween. Referring to the cross-sectional view in FIG. 32, the amplifier gate electrode 49 is formed near the photo diode PD4. The gate insulating film 131 is arranged between the amplifier gate electrode 121 and the photo diode PD4.

The waveguide 152 formed to correspond to the photo diode PD has a columnar body with a constant cross section from an end of light incident side to an end of light exit side. For example, the columnar body may be a cylinder or an oval cylinder (including an elliptic cylinder). The waveguide 152 has a diameter (width) smaller than the width of the photo diode PD and the opening width of the wiring portion 155 for the photo diode PD, so that the waveguide 152 can be adjusted by shifting, which will be described later. The waveguide 152 may have a tapered columnar shape with a cross section decreasing from an end of light incident side to an end of light exit side.

In the unit pixel group 42, a base layer arranged below the light incidence surface has an asymmetric arrangement. In this embodiment, the base layer including the transfer gate electrodes 43, the base layer which is formed below the waveguides 152, has an asymmetric arrangement with respect to the boundaries of the adjacent pixels Gr, R, Gb, and B. That is, the transfer gate electrodes 43 of the pixels Gr, R, Gb, and B are asymmetrically arranged in the unit pixel group 42. Also, in the unit pixel group 42, the pixel transistor unit including the reset transistor Tr2, the amplifier transistor Tr3, and the select transistor Tr4 are asymmetrically arranged with respect to the boundary between the pixels Gb and R, and the pixels Gr and B.

In a state before the waveguide 152 of a predetermined pixel is adjusted by shifting (state equivalent to the comparative example in FIG. 62), the waveguides 152 are arranged at a regular interval in the entire area of the pixel section 40, and the positional relationship between the photo diode PD and the waveguide 152 is equivalent in the entire pixel section 40. For example, there are a case in which the center of the photo diode PD is slightly shifted from the central axis of the waveguide 152, and a case in which the center of the photo diode PD is aligned with the central axis of the waveguide 152. In either case, the positional relationship between the center of the photo diode PD and the waveguide 152 is equivalent in the entire pixel section 40.

The color filter layer 157 and the microlens 158 of each color may be subjected to pupil correction, or may not be subjected to pupil correction. If pupil correction is performed for the color filter layer 157 and the microlens 158, the pupil correction is performed such that the shift amount of the center of the color filter layer 157 or the microlens 158 with respect to the center of the photo diode PD becomes larger from the center toward the periphery of the pixel section 40.

In this embodiment, the waveguide 152 serves as adjusting means for obtaining optical symmetry for the photo diode PD in the unit pixel group 42. In this embodiment, the waveguide 152 of the second green pixel Gr is shifted away from the amplifier gate electrode 49 from a reference position at which the waveguides 152 of the pixels are arranged at a regular interval in the entire area of the pixel section 40. In this case, the adjustment direction and the adjustment amount of the positional shift is determined such that the sensitivity of the second green pixel Gr is equivalent to the sensitivity of the first green pixel Gb. In this embodiment, the waveguide 152 of the second green pixel Gr is shifted to the oblique upper left side as indicated by arrow B in FIGS. 31A and 31B such that a distance d1 (see the comparative example in FIG. 62) as the initial state or reference state becomes a distance d2 larger than the distance d1. The adjustment direction (shift direction) and the adjustment amount (shift amount) of the positional shift of the waveguide 152 of the second green pixel Gr is equivalent in the entire pixel section including the waveguide 152 at an edge of the angular field. The positions of the waveguides 152 of the other red pixels R, blue pixels B, and first green pixels Gb are not changed from the initial state.

Accordingly, the waveguide 152 of the second green pixel Gr in the unit pixel group 42 of four-pixel-sharing type that four pixels share one floating diffusion, one amplifier transistor, and one select transistor is asymmetrically arranged to the waveguides 152 of the other red pixels R, blue pixels B, and first green pixels Gb with respect to the boundaries between the second green pixel Gr and the other red pixels R, blue pixels B, and first green pixels Gb.

The entire layout of the waveguides 152 in the unit pixel group 42 is provided in advance in an exposure mask for forming the waveguides 152 presupposing the shift position of the waveguide 152 of the second green pixel Gr. Thus, by using the exposure mask, the waveguide layout can be formed in which only the waveguide 152 of the second green pixel Gr is intentionally shifted in the unit pixel group 42 by a predetermined distance in a predetermined direction as compared with the waveguides 152 of the other pixels Gb, R, and B.

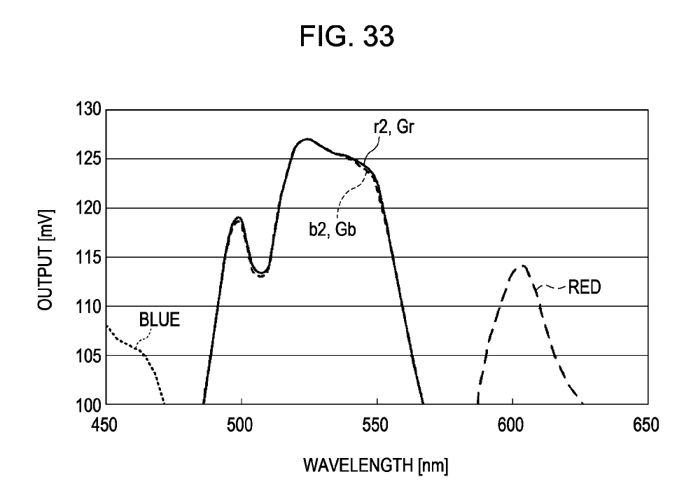

With the solid state image pickup device 38 according to the fourth embodiment, only the waveguide 152 of the second green pixel Gr is intentionally shifted away from the amplifier gate electrode 49 made of polysilicon in the base layer. Accordingly, the incident light L can be prevented from being eclipsed by the amplifier gate electrode 49. Thus, the difference in sensitivity between the first and second green pixels Gb and Gr can be decreased or eliminated, and as a result, the optical symmetry for the green pixels Gb and Gr can be obtained. Referring to curves r2 and b2 in a graph plotting the wavelengths and outputs in FIG. 33, the sensitivities of the first and second green pixels Gb and Gr can be equivalent to one another. Accordingly, by decreasing the difference in sensitivity between the first and second green pixels Gb and Gr, noise such as grating noise can be decreased, and a solid state image pickup device with high image quality can be provided.

### 5. Fifth Embodiment

Exemplary Configuration of Solid State Image Pickup Device

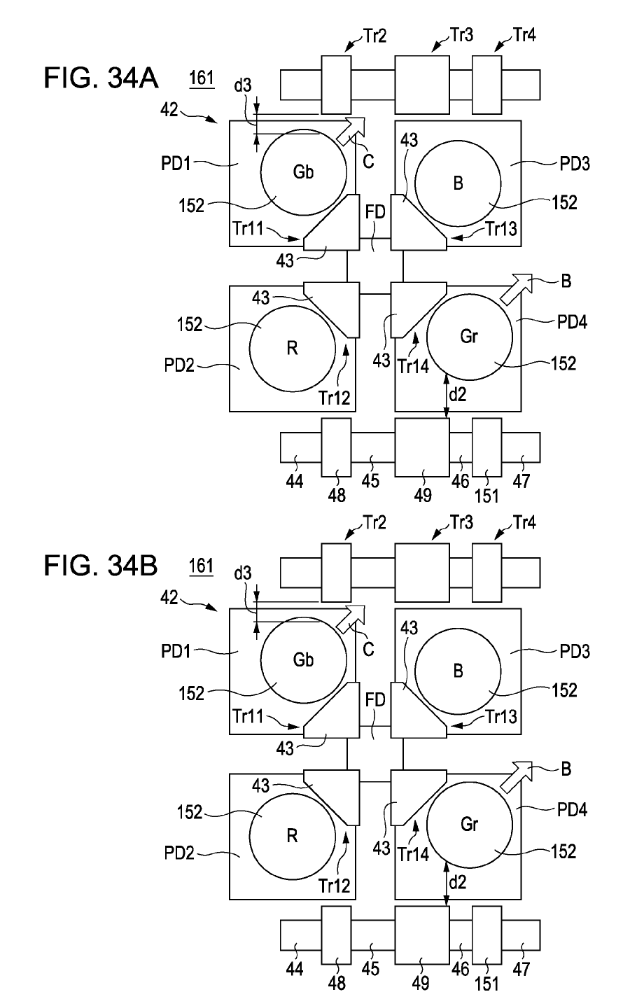

FIGS. 34A and 34B each illustrate a solid state image pickup device according to a fifth embodiment of the present invention. A solid state image pickup device of this embodiment is a MOS solid state image pickup device of four-pixel-sharing type that four pixels share one floating diffusion, one amplifier transistor, and one select transistor. FIGS. 34A and 34B are plan views showing unit pixel groups at the center of an angular field and at an edge of the angular field in a pixel section.

The shift amount as the adjustment amount of the waveguide 152 is determined on the basis of a margin to the opening width of a wiring portion 155 corresponding to the photo diode PD. Thus, the shift amount is restricted. With this restriction, the difference in sensitivity between the first and second green pixels Gb and Gr may not be decreased even if only the waveguide 152 of the second green pixel Gr is shifted. The fifth embodiment improves this point.

In a solid state image pickup device 161 according to the fifth embodiment, similar to the fourth embodiment, a waveguide 152 of a second green pixel Gr is shifted away from an amplifier gate electrode 49 by a predetermined distance toward an oblique upper right side indicated by arrow B in FIGS. 34A and 34B. At the same time, a waveguide 152 of a first green pixel Gb is shifted so as to be close to a reset gate electrode 48 by a predetermined distance d3 toward an oblique upper right side indicated by arrow C in FIGS. 34A and 34B. The layout of the waveguides 152 in the unit pixel group 42 is equivalent in an entire pixel section 40. In this embodiment, the waveguide 152 of the first green pixel Gb is shifted in the same direction as the shift direction of the second green pixel Gr as indicated by arrow C. The shift direction of the first and second green pixels Gb and Gr is not limited thereto. An optimal direction may be determined depending on the layout of the pixel transistors Tr11 to Tr14.

The other configuration is similar to that described according to the fourth embodiment. Like reference signs refer like components in FIGS. 31A and 31B.

With the solid state image pickup device 161 according to the fifth embodiment, the sensitivity of the second green pixel Gr is increased by moving the waveguide 152 thereof away from the amplifier gate electrode 49 in the base layer, and the sensitivity of the first green pixel Gb is intentionally decreased by moving the waveguide 152 thereof toward the reset gate electrode 48 in the base layer. As a result, the optical symmetry is likely obtained for the first and second green pixels Gb and Gr. That is, the difference in sensitivity between the first and second green pixels Gb and Gr can be further decreased or eliminated. The sensitivities of both green pixels Gb and Gr can be equalized. Accordingly, by decreasing the difference in sensitivity between the first and second green pixels Gb and Gr, noise such as grating noise can be decreased, and a solid state image pickup device with high image quality can be provided.

### 6. Sixth Embodiment

Exemplary Configuration of Solid State Image Pickup Device

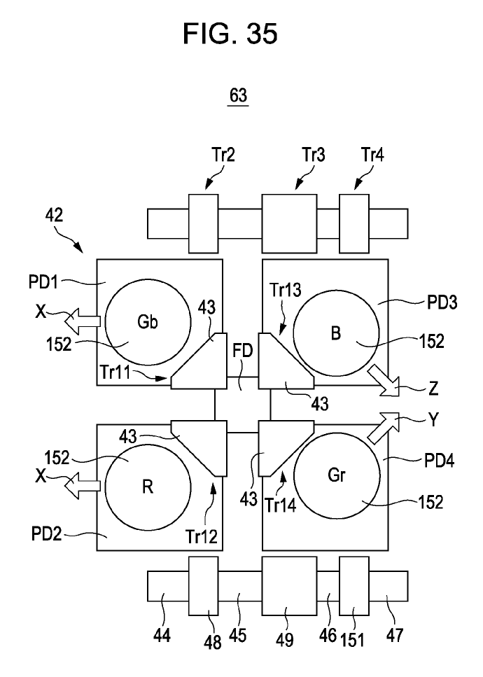

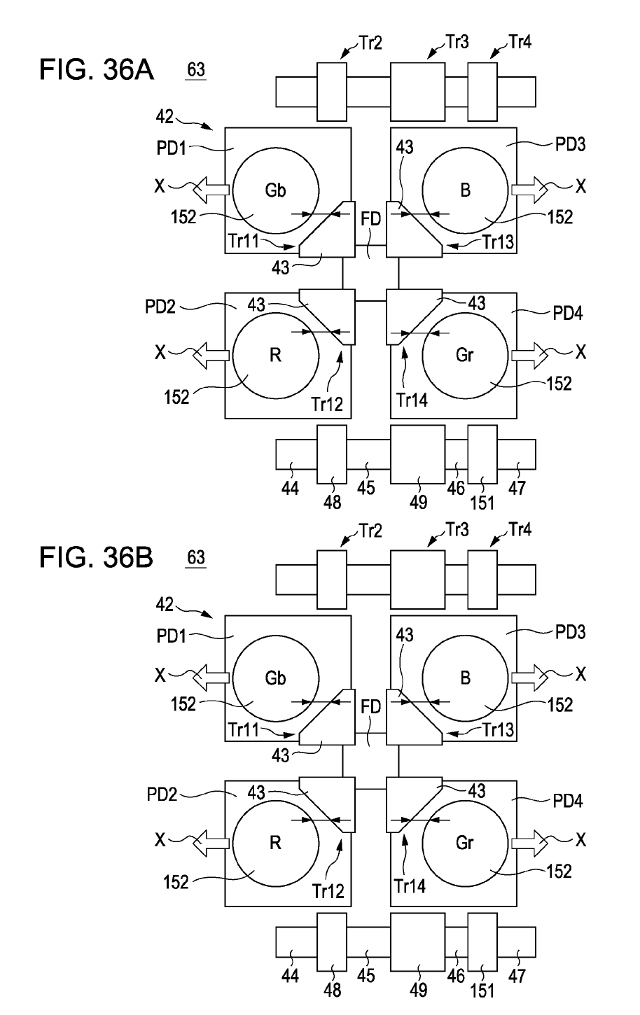

FIGS. 35, 36A, and 36B each illustrate a solid state image pickup device according to a sixth embodiment of the present invention. A solid state image pickup device of this embodiment is a MOS solid state image pickup device of four-pixel-sharing type that four pixels share one floating diffusion, one amplifier transistor, and one select transistor. FIG. 35 is a schematic configuration diagram showing a unit pixel group in a final state according to the sixth embodiment. FIGS. 36A and 36B are schematic plan views showing unit pixel groups at the center of an angular field and at an edge of the angular field of a pixel section to provide an improvement for obliquely incident light.

The solid state image pickup device according to the sixth embodiment can provide control for color shading in addition to control for the difference in sensitivity between both green pixels Gb and Gr.

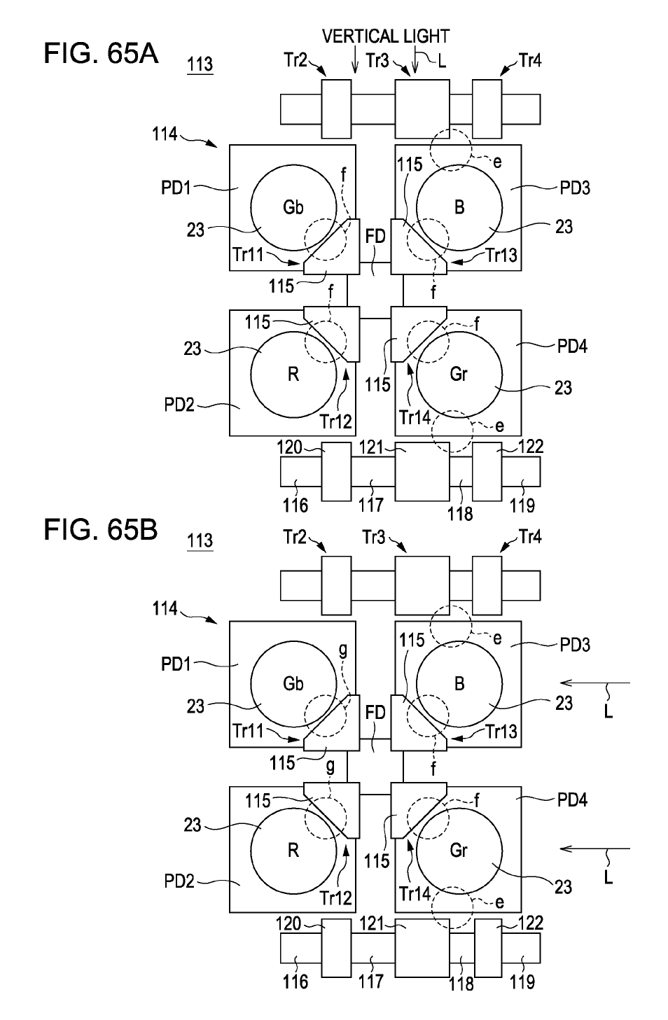

First, for the convenience of understanding of the sixth embodiment, a comparative example before improvement will be described with reference to FIGS. 65A and 65B. The comparative example in FIGS. 65A and 65B is similar to the above-described comparative example shown in FIG. 62. Like reference signs refer like components. As shown in FIG. 65A, at the center of an angular field, incident light L is incident in a direction vertical to the drawing sheet (in the drawing, incident light L enters from the upper side to the lower side for the convenience of illustration). Waveguides 23 for pixels R, Gr, Gb, and B are arranged near corresponding transfer gate electrodes 115. Thus, as indicated by circle f, part of incident light L transmitted through the waveguides 23 is likely eclipsed by the transfer gate electrodes 115. In contrast, as shown in FIG. 65B, at an edge of the angular field (in the drawing, a left-edge pixel section is illustrated for example), the incident light L enters obliquely from the right side to the left side. Since photo diodes PD1 and PD2 are shaded by the transfer gate electrodes 115, as indicated by circle g, part of the incident light L incident on the first green pixel Gb and the red pixel R is eclipsed by the transfer gate electrodes 115. As indicated by circle f, the incident light L incident on the second green pixel Gr and the blue pixel B is also likely eclipsed by the transfer gate electrodes 115. Also, at the center and edge of the angular field, the waveguides 23 of the second green pixel Gr and the blue pixel B are located near amplifier gate electrodes 121. As indicated by circle e, part of the incident light L is eclipsed by the amplifier gate electrodes 121. Accordingly, the difference in sensitivity between the first and second green pixels Gb and Gr occurs, and the color shading appears.

With a solid state image pickup device 63 according to the sixth embodiment, as shown in FIG. 36A at the center of the angular field and FIG. 36B at the edge of the angular field, waveguides 152 of pixels R, Gr, Gb, and B in a unit pixel group 42 are shifted in the horizontal direction away from respective transfer gate electrodes 43 as indicated by arrow X. Accordingly, in the pixels R, Gr, Gb, and B, the obliquely incident light L, and part of the vertically incident light L at the center of the angular filed are hardly eclipsed by the transfer gate electrodes 43. Thus, the eclipse of the incident light L by the transfer gate electrodes 43 is decreased or eliminated.

Also, similar to the description according to the fourth embodiment, the waveguide 152 of the second green pixel Gr is shifted away from an amplifier gate electrode 49, and a waveguide 152 of the blue pixel B is shifted away from an amplifier gate electrode 159.

Accordingly, referring to FIG. 35, the solid state image pickup device 63 according to the sixth embodiment is shifted by a predetermined shift amount in a direction indicated by arrows. In particular, the waveguide 152 of the second green pixel Gr is shifted toward the obliquely upper right side (see arrow Y) away from the transfer gate electrode 43 and the amplifier gate electrode 49. The waveguide 152 of the blue pixel B is shifted toward the obliquely lower right side (see arrow Z) to be symmetric to the waveguide 152 of the second green pixel Gr. The waveguides 152 of the first green pixel Gb and the red pixel R are shifted toward the horizontally left side away from the transfer gate electrode 43. The layout of the waveguides 152 in the unit pixel group 42 is equivalent in an entire pixel section 40.

The other configuration is similar to that described according to the fourth embodiment. In FIGS. 35, 36A and 36B, like reference signs refer like components in FIGS. 31A and 31B.

With the solid state image pickup device 63 according to the sixth embodiment, the difference in sensitivity between the first and second green pixels Gb and Gr can be decreased or eliminated. Noise, such as grating noise, can be decreased. In addition, the sensitivities of the red pixel R and the blue pixel B can be controlled. Variation in sensitivity for the pixel section 40 can be decreased, and the color shading can be decreased. Since the variation in sensitivity for the pixel section 40 can be decreased, the correction circuit can be reduced, and the size of the circuit can be decreased.

### 7. Seventh Embodiment

Exemplary Configuration of Solid State Image Pickup Device

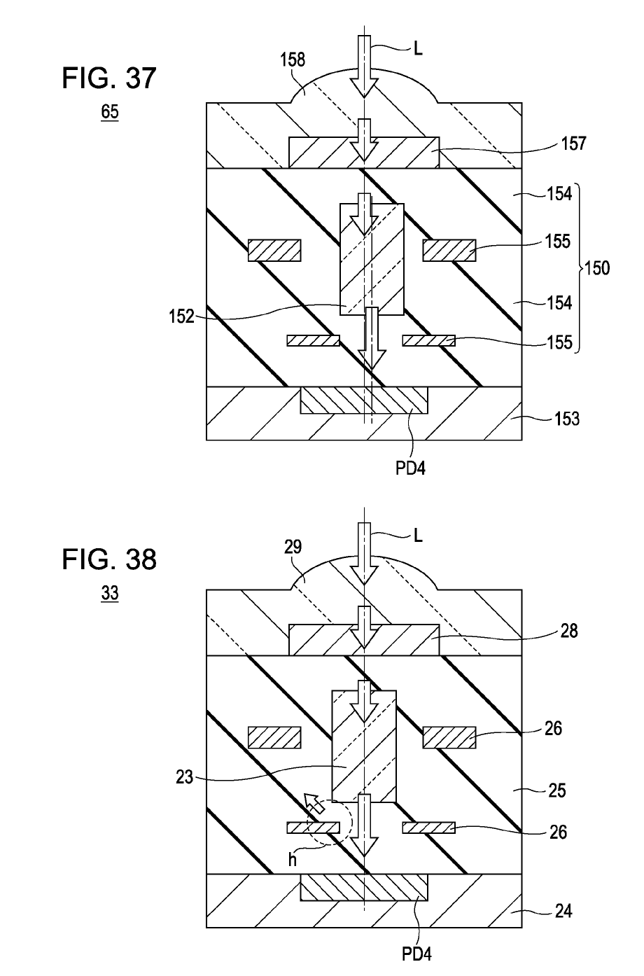

FIG. 37 illustrates a solid state image pickup device according to a seventh embodiment of the present invention. A solid state image pickup device of this embodiment is a MOS solid state image pickup device of four-pixel-sharing type that four pixels share one floating diffusion, one amplifier transistor, and one select transistor. FIG. 37 is a cross-sectional view showing a second green pixel Gr in a unit pixel group.

The asymmetric arrangement in a base layer may occur not only for gate electrodes made of polysilicon, but also for wiring patterns. The solid state image pickup device according to the seventh embodiment can obtain optical symmetry in the base layer for wiring portions 155.

First, for the convenience of understanding of the seventh embodiment, a comparative example before improvement will be described with reference to FIG. 38. FIG. 38 is a cross-sectional view showing a second green pixel Gr in a unit pixel group of four-pixel-sharing type that four pixels share one floating diffusion, one amplifier transistor, and one select transistor. In a solid state image pickup device 33 of the comparative example, referring to FIG. 38, a photo diode PD4 as a photoelectric transducer is formed on a surface of a semiconductor substrate 24, and a plurality of layers including wiring portions 26 are formed above the semiconductor substrate 24 with an interlayer insulating film 25 interposed therebetween. A waveguide 23 is formed above the photo diode PD4 such that the waveguide 23 is embedded in the interlayer insulating film 25. A color filter layer 28 is formed above the waveguide 23. A microlens 29 (also called on chip lens) is formed on the color filter layer 28. In this example, the waveguide 23 is provided above a wiring portion 26 in the bottom layer. A part of the wiring portion 26 in the bottom layer protrudes to an area above the photo diode PD4, and the base layer including the wiring portion 26 has an asymmetric arrangement in the unit pixel group. Though not shown, in the other pixels including a first green pixel Gb, a red pixel R, and a blue pixel B, wiring portions 26 in bottom layers below waveguides 23 do not protrude to areas above photo diodes PD1, PD2, and PD3.

In the solid state image pickup device 33 of the comparative example, as indicated by circle h in FIG. 38, part of incident light L incident on the second green pixel Gr is eclipsed by the wiring portion 26 in the bottom layer, resulting in the sensitivity of the second green pixel Gr being decreased. Accordingly, the difference in sensitivities between the first and second green pixels Gb and Gr appears. If a part of the wiring portion 26 in the bottom layer extends to an area above the photo diode of another color pixel, and if the layout of the base layer including the wiring portion 26 is asymmetric, color shading may occur.

In a solid state image pickup device 65 according to the seventh embodiment, a photo diode PD4 as a photoelectric transducer is formed on a surface of a semiconductor substrate 153, and a plurality of layers including wiring portions 155 are formed above the semiconductor substrate 153 with an interlayer insulating film 154 interposed therebetween. The wiring portion 155 is basically open in an area corresponding to the photo diode PD4. A waveguide 152 is formed above the photo diode PD4 such that the waveguide 152 is embedded in the interlayer insulating film 154. The waveguide 152 guides incident light to the photo diode PD. The surface of the interlayer insulating film 154 is planarized. A color filter layer 157 is formed on the surface of the interlayer insulating film 154. A microlens 158 (also called on chip lens) is formed on the color filter layer 157. In this embodiment, the waveguide 152 is provided above the wiring portion 155 in the bottom layer, and part of the wiring portion 155 in the bottom layer protrudes to the area above the photo diode PD4. Though not shown, in the other pixels including a first green pixel Gb, a red pixel R, and a blue pixel B, wiring portions 155 in bottom layers below waveguides 152 do not protrude to areas above photo diodes PD1, PD2, and PD3. Thus, the layout of the base layer including the wiring portions 155 in the unit pixel group 42 has an asymmetric arrangement.

In this embodiment, the waveguide 152 of the second green pixel Gr is shifted away from the wiring portion 155 protruding to the area above the photo diode PD4. The waveguides 152 of the other color pixels R, Gb, and B are arranged at equivalent positions with respect to respective photo diodes. Since only the waveguide 152 of the second green pixel Gr is shifted from the initial state, the waveguide 152 of the second green pixel Gr in the unit pixel group 42 is asymmetrically arranged to the waveguides 152 of the other color pixels Gb, R, and B with respect to the boundaries between the second green pixel Gr and the other adjacent pixels Gb, R, and B. The layout of the waveguides 152 in the unit pixel group 42 is equivalent in an entire pixel section 40.

The other configuration of the four-pixel-sharing type that four pixels share one floating diffusion, one amplifier transistor, and one select transistor is similar to that described according to the fourth embodiment. The redundant description will be omitted.

With the solid state image pickup device 65 according to the seventh embodiment, the waveguide 152 of the second green pixel Gr is shifted away from the wiring portion 155 protruding to the area above the photo diode PD4. Hence, the incident light L is not eclipsed by the wiring portion 155 and is incident on the photo diode PD4, resulting in the sensitivity of the second green pixel Gr being increased. Thus, the difference in sensitivity between the first and second green pixels Gb and Gr can be decreased or eliminated. The sensitivities of both green pixels Gb and Gr can be equalized. Accordingly, by decreasing the difference in sensitivity between the first and second green pixels Gb and Gr, noise such as grating noise can be decreased, and a solid state image pickup device with high image quality can be provided.

If a part of the wiring portion 155 in the bottom layer protrudes to an area above a photo diode PD of another color pixel, the waveguide of that pixel is shifted. With this configuration, the incident light is not eclipsed by the wiring portion 155, and the color shading can be decreased.

### 8. Eighth Embodiment

Exemplary Configuration of Solid State Image Pickup Device

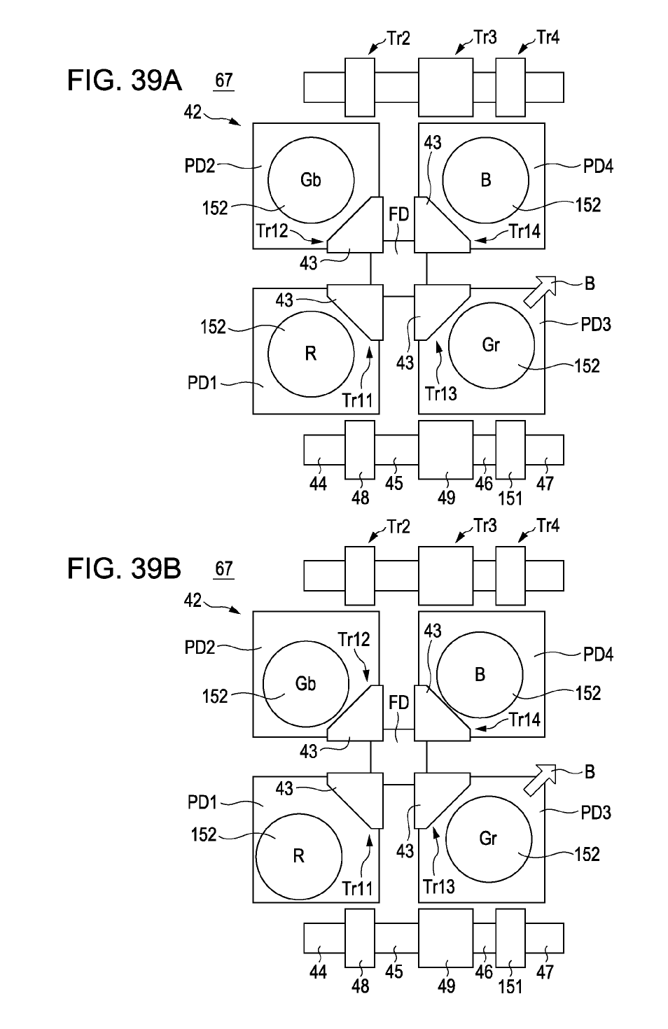

FIGS. 39A and 39B illustrate a solid state image pickup device according to an eighth embodiment of the present invention. A solid state image pickup device of this embodiment is a MOS solid state image pickup device of four-pixel-sharing type that four pixels share one floating diffusion, one amplifier transistor, and one select transistor. FIGS. 39A and 39B are schematic configuration diagrams showing unit pixel groups at the center of an angular field and at an edge of the angular field in a final state according to the eighth embodiment.

The solid state image pickup device according to this embodiment decreases difference in sensitivity between green pixels Gr and Gb, and decreases color shading, by combining shifting of a waveguide which has been described according to any of the fourth to seventh embodiments with pupil correction for the waveguide.

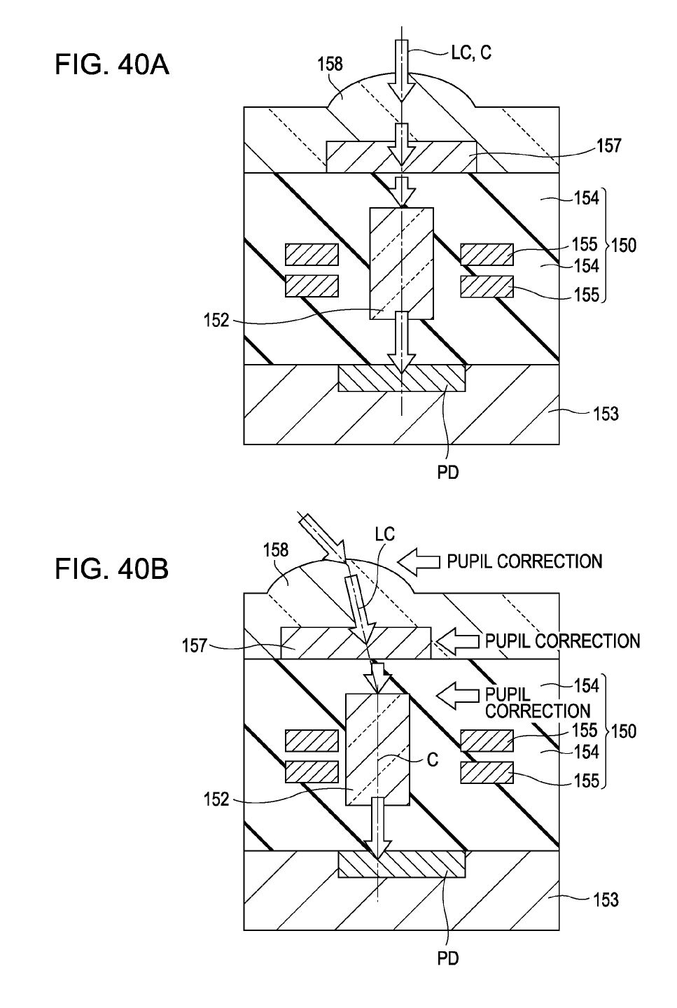

First, pupil correction for a waveguide will be described with reference to FIGS. 40A to 43. In cross-sectional views in FIGS. 40A to 43, for the convenience of description, pixel transistors are not illustrated. FIG. 40A illustrates a pixel at the center of an angular filed. FIG. 40B illustrates a pixel at an end of the angular field. Referring to FIGS. 40A and 40B, in pixel of a solid state image pickup device, a photo diode PD serving as an photoelectric transducer is formed on a surface of a semiconductor substrate 153, and a plurality of layers including wiring portions 155 with an interlayer insulating film 154 interposed therebetween are formed above the semiconductor substrate 153 in an area except the area above the photo diode PD. A waveguide 152 is formed above the photo diode PD such that the waveguide 152 is embedded in the interlayer insulating film 154. The waveguide 152 guides incident light to the photo diode PD. The surface of the interlayer insulating film 154 is planarized. A color filter layer 157 to correspond to the waveguide 152 is formed on the planarized surface. A microlens 158 (also called on chip lens) is formed on the color filter layer 157.

The waveguide 152 is formed such that a waveguide hole is formed in the interlayer insulating film 154 in the area above the photo diode PD, and the waveguide hole is filled with a light-transmissive material having a higher refractive index than that of the interlayer insulating film 154. The material is, for example, a silicon nitride film, a diamond film, or a resin material. The microlens 158 and the color filter layer 157 are subjected to pupil correction so as to efficiently condense even oblique light. The pupil correction amount becomes larger from the center of a angular field (e.g., the center of the pixel section) toward an edge of the angular field.

The waveguide 152 formed to correspond to the photo diode PD in the pixel section 40 has a columnar body with a constant cross section from an end of light incident side to an end of light exit side, as described above. For example, the columnar body with a constant cross section may be a cylinder, a prism, or an oval cylinder (including an elliptic cylinder). The center LC of rays of the incident light which is incident on the end of light incident side of the waveguide 152 is aligned with the central axis C of the waveguide 152.

In this case, in the pixel at the center of the angular field in FIG. 40A, the incident light is incident on the microlens 158 in the central-axis direction. The incident light condensed by the microlens 158 is transmitted through and divided by the color filter layer 157, and is incident on the end of light incident side of the waveguide 152. The incident light is guided along the central axis C of the waveguide 152 and exited from the end of light exit side of the waveguide 16. The light is emitted on the center of the photo diode PD. That is, the incident light transmitted through the center of the microlens 158 is transmitted along the center of the color filter layer 157 and the central axis C of the waveguide 152, and emitted on the center of the photo diode PD. Thus, pupil correction is not performed for the waveguide 152.

In the pixel at a position shifted from the center of the angular field, or in the pixel at the edge of the angular field in the drawing, pupil correction is performed for the microlens 158 and the color filter layer 157 so as to efficiently condense even oblique light, as described above. Also, the center LC of rays of the incident light which is incident on the end of light incident side of the waveguide 152 is aligned with the central axis C of the waveguide 152. That is, pupil correction is performed for the waveguide 152.

In the photo diodes PD, on which incident light with equivalent wavelengths is incident, in the pixel section 40, the shift amount of the central axis C of each waveguide 152 with respect to the center of the corresponding photo diode PD becomes larger from the photo diode PD at the center of the pixel section 40 toward the outside. The pupil correction is performed for the microlens 158 from the center of the pixel section 40 toward the outside, however, the pupil correction is not sufficient. Owing to this, for the incident light with the equivalent wavelengths, the shift amount of the central axis of the waveguide 152 with respect to the center of the photo diode PD is increased, so that the center of rays of light from the microlens 158 is aligned with the central axis C of the waveguide 152.

The waveguide 152 has a diameter which allows the incident light from the end of light exit side of the waveguide 152 to be emitted on an area within the surface of the photo diode PD. Hence, the size of the waveguide 152 is not equivalent to the size of the surface of the photo diode PD, unlike the waveguide of related art. The diameter of the waveguide 152 is desirably larger than the spot diameter of the incident light transmitted through the color filter layer 157 on the end of light incident side of the waveguide 152. The spot diameter varies depending on the wavelength of incident light. For example, when the color filter layers 157 divide the incident light into red light, green light, and blue light, the spot diameter of the red light is the largest, the spot diameter of the green light is smaller than that of the red light, and the spot diameter of the blue light is smaller than that of the green light. If the diameter of the waveguide 152 varies depending on the color, the layout may become complicated. For example, the diameter of the waveguide 152 is determined on the basis of the green light which has an intermediate wavelength range of the incident light. Alternatively, if a margin is provided between the waveguide 152 and the wiring portion 155 of the wiring layer 150, the diameter of the waveguide 152 may be determined on the basis of the red light.

The margin for the pupil correction can be increased by decreasing the diameter of the waveguide 152 to be smaller than the diameter of the waveguide of related art. In addition, the margin for the pupil correction of the waveguide 152 can be further increased by decreasing the width of the wiring portion 155 arranged around the waveguide 152.

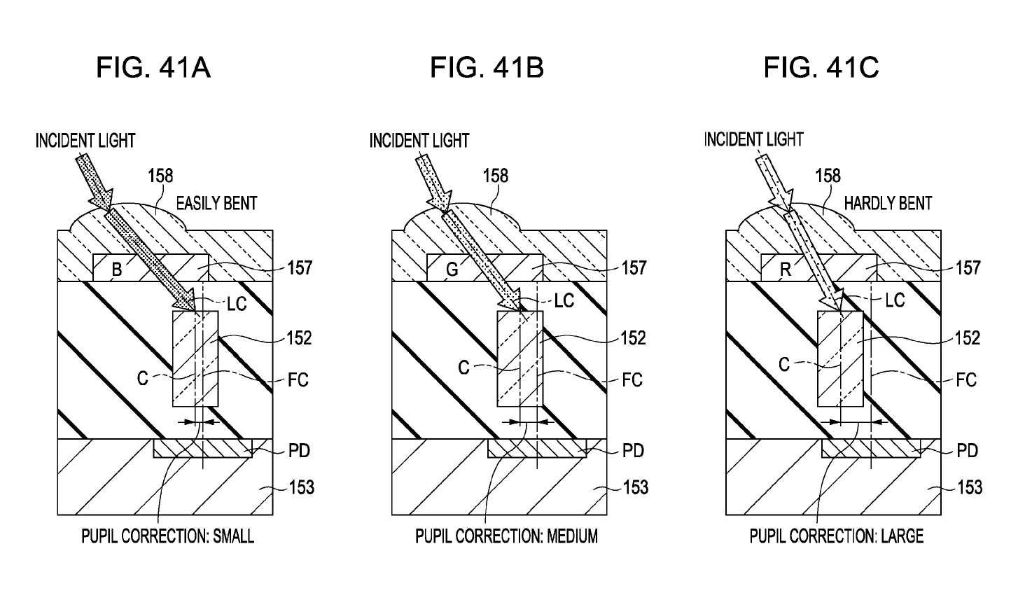

Referring to FIGS. 41A to 41C, in the photo diodes PD, on which incident light with equivalent wavelengths is incident, in the pixel section 40, the shift amount of the central axis C of each waveguide 152 with respect to the center of the corresponding photo diode PD becomes larger from the center of the pixel section 40 toward the outside. In other words, regarding the photo diodes PD at equivalent distances from the center of the pixel section 40, the shift amount of the central axis C of each waveguide 152 with respect to the central axis FC of the corresponding photo diode PD is larger as the wavelength of the light that is incident on the photo diode PD is larger. The pupil correction amounts for the waveguides 152 satisfy the relationship of “blue light (B)<green light (G)<red light (R).” For the convenience of illustration in the plan layout, the waveguide 152 is smaller than the photo diode PD. As a result, shading can be optimized by each of the waveguides 152.

Typically, the incidence angle of the incident light condensed by the microlens 158 is increased as the position is shifted from the center of the pixel section 20 toward the outside. The pupil correction is performed for the microlens 158, however, the pupil correction amount is not sufficient. Owing to this, as described above, for the incident light with the equivalent wavelengths, the shift amount of the central axis of the waveguide 16 with respect to the center of the photo diode is increased, so that the center of rays of light from the microlens 158 is aligned with the central axis C of the waveguide 16.

Typically, the microlens 158 and the color filter layer 157 are subjected to the pupil correction so that the incident light is incident on the photo diode PD in the central-axis direction. For example, the pupil correction is performed for the microlens 158 and the color filter layer 157 of incident light with a reference wavelength (for example, green light). In this case, referring to FIG. 41A, since the blue light is easily bent by the microlens 158, the incidence angle of the blue light when being incident on the end of light incident side of the waveguide 152 becomes large. Thus, the microlens 158 and the color filter layer 157 are largely shifted to the center of the pixel section relative to the central axis FC of the photo diode PD by the pupil correction. However, even when the microlens 158 and the color filter layer 157 are largely shifted, the light emitted from the color filter layer 157 is incident on the end of light incident side of the waveguide 152, at a position close to the central axis FC of the photo diode PD. Accordingly, almost all incident light incident on the end of light incident side of the waveguide 152 is guided to the waveguide 152. In this case, the position of the waveguide 152 is corrected such that the central axis LC of rays of the incident light which is incident on the end of light incident side of the waveguide 152 is aligned with the central axis C of the waveguide 152.

Referring to FIG. 41C, since the red light is hardly bent by the microlens 158 as compared with the blue light, the incidence angle of the red light when being incident on the end of light incident side of the waveguide 152 becomes smaller than that of the blue light. Also, the microlens 158 and the color filter layer 157 are largely shifted to the center of the pixel section relative to the central axis FC of the photo diode PD by the pupil correction. Owing to this, the light emitted from the color filter layer 157 is incident on the end of light incident side of the waveguide 152, at a position distant from the central axis FC of the photo diode PD. In some cases, the light may be incident such that major part of the light protrudes from the end of light incident side of the waveguide 152. However, in this embodiment of the present invention, the position of the waveguide 152 is corrected such that the central axis LC of rays of the incident light which is incident on the end of light incident side of the waveguide 152 is aligned with the central axis C of the waveguide 152. Thus, almost all incident light emitted from the color filter layer 157 is incident on the end of light incident side of the waveguide 152 and is guided into the waveguide 152.

Also, referring to FIG. 41B, the green light is hardly bent by the microlens 158 as compared with the blue light, and is easily bent by the microlens 158 as compared with the red light. The incidence angle of the incident light which is incident on the end of light incident side of the waveguide 152 is smaller than that of the blue light, and larger than that of the red light. Since the microlens 158 and the color filter layer 157 are shifted to the center of the pixel section relative to the central axis FC of the photo diode PD by the pupil correction, the light emitted from the color filter layer 157 is incident on the end of light incident side of the waveguide 152, at a position distant from the central axis FC of the photo diode PD. However, in this embodiment of the present invention, the position of the waveguide 152 is corrected such that the central axis LC of rays of the incident light which is incident on the end of light incident side of the waveguide 152 is aligned with the central axis C of the waveguide 152. Thus, almost all incident light emitted from the color filter layer 157 is incident on the end of light incident side of the waveguide 152 and is guided into the waveguide 152.

As described above, the shift amount of the central axis C of each waveguide 152 with respect to the center of the corresponding photo diode PD is smaller as the wavelength of the light that is divided by the color filter layer 157 is smaller. Accordingly, even when the wavelengths of the incident light on the ends of light incident side of the waveguides 152 are different from one another, the waveguides 152 are respectively arranged in accordance with the wavelengths, the sensitivities of the pixels are equivalent, and color shading does not occur.

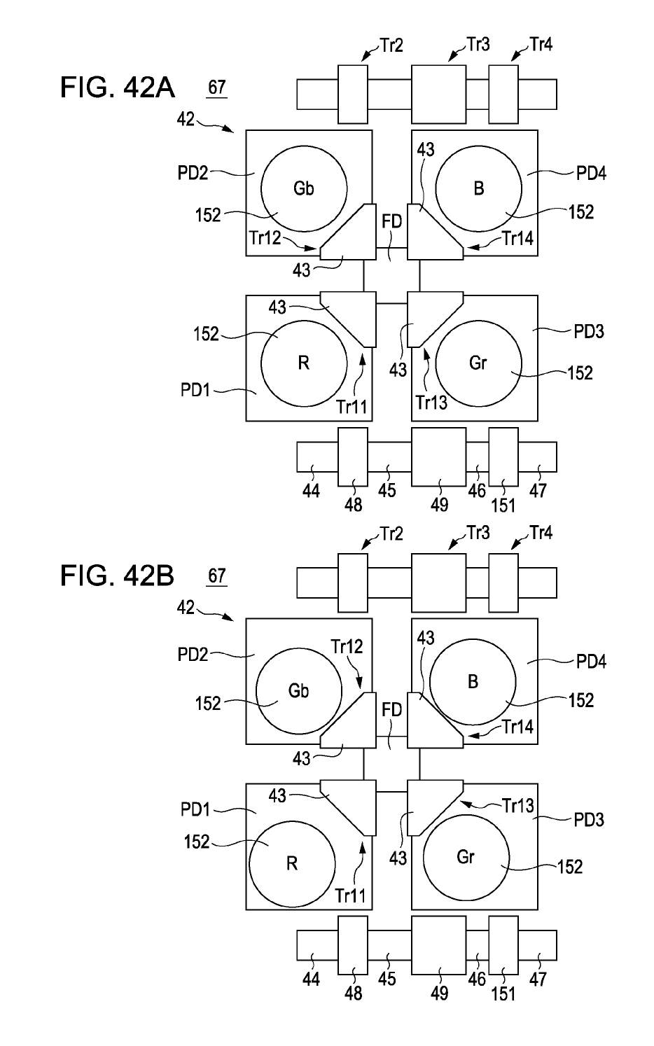

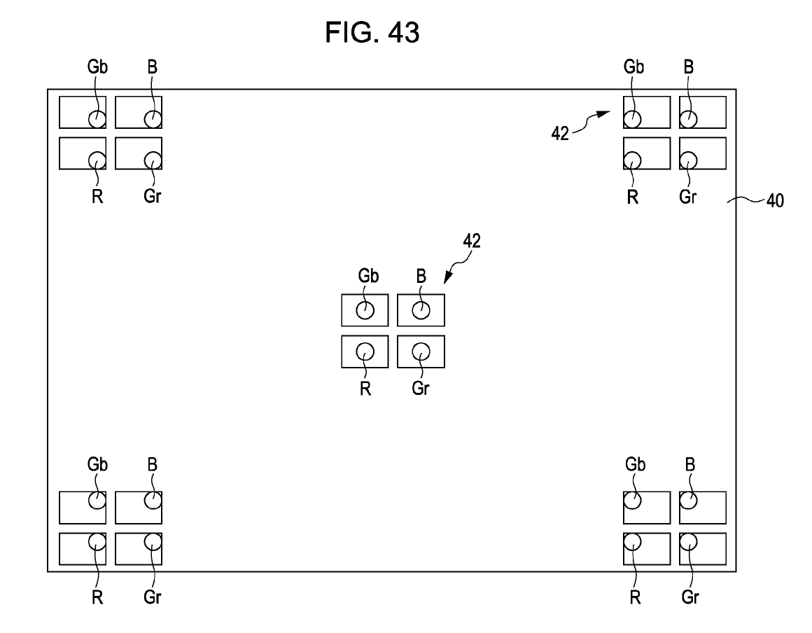

FIGS. 42A, 42B, and 43 each illustrate a solid state image pickup device of four-pixel-sharing type that four pixels share one floating diffusion, one amplifier transistor, and one select transistor, in which pupil correction is performed for the above-described waveguide. FIG. 42A illustrates a layout of waveguides 152 in a unit pixel group 42 of four-pixel-sharing type that four pixels share one floating diffusion, one amplifier transistor, and one select transistor, at the center of an angular field of a pixel section 40 shown in FIG. 43. FIG. 42B illustrates a layout of waveguides 152 in a unit pixel group 42 of four-pixel-sharing type that four pixels share one floating diffusion, one amplifier transistor, and one select transistor, at an upper right edge of the angular field of the pixel section 40 shown in FIG. 43. Layouts of waveguides 152 in unit pixel groups 42 of four-pixel sharing type at lower right, upper left, and lower left edges of the angular field of the pixel section 40 are symmetric to the layout of the waveguide 152 shown in FIG. 42B with respect to the center of the angular field.

A solid state image pickup device 67 according to the eighth embodiment is configured by adding the layout in which only the waveguide 152 of the second green pixel Gr according to the fourth embodiment is added to the layout of the waveguide 152 with the pupil correction performed as shown in FIGS. 40A to 43.

Since the solid state image pickup device 67 according to the eighth embodiment has the configuration in which the pupil correction is performed for the waveguide 152, color shading can be decreased. Also, the difference in sensitivity between the first and second green pixels Gb and Gr can be decreased, and a solid state image pickup device with high image quality can be provided.

Alternatively, the eighth embodiment may have a configuration in which any of the fifth to seventh embodiments is combined with the pupil correction for the waveguide described with reference to FIGS. 40A to 43.

### 9. Ninth Embodiment

Exemplary Configuration of Solid State Image Pickup Device

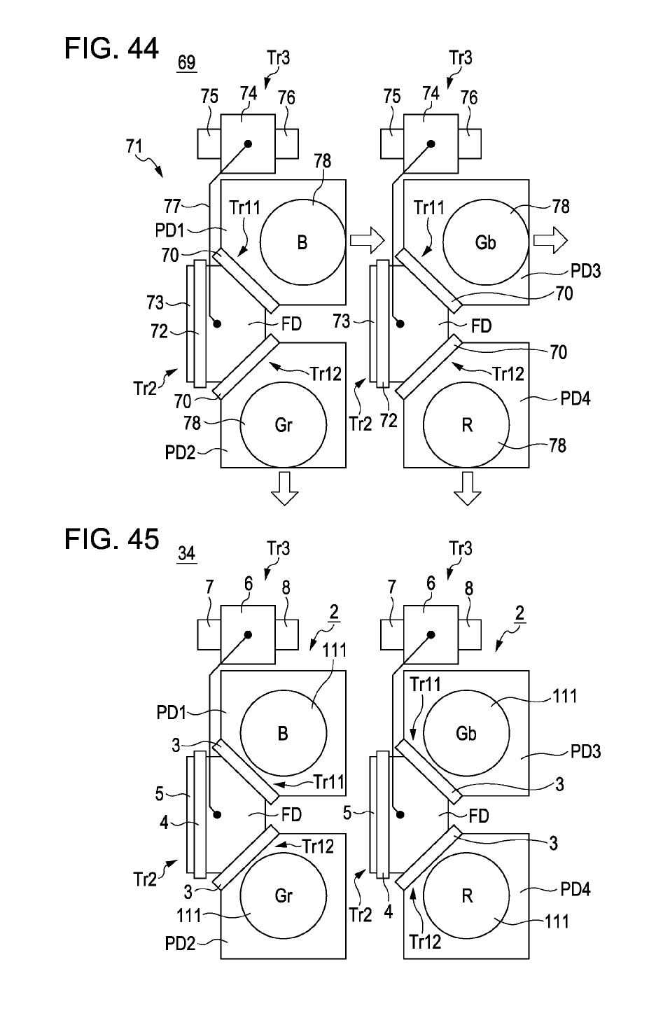

FIG. 44 illustrates a solid state image pickup device according to a ninth embodiment of the present invention. A solid state image pickup device of this embodiment is a MOS solid state image pickup device of two-pixel-sharing type that two pixels share one floating diffusion, one amplifier transistor, and one select transistor.

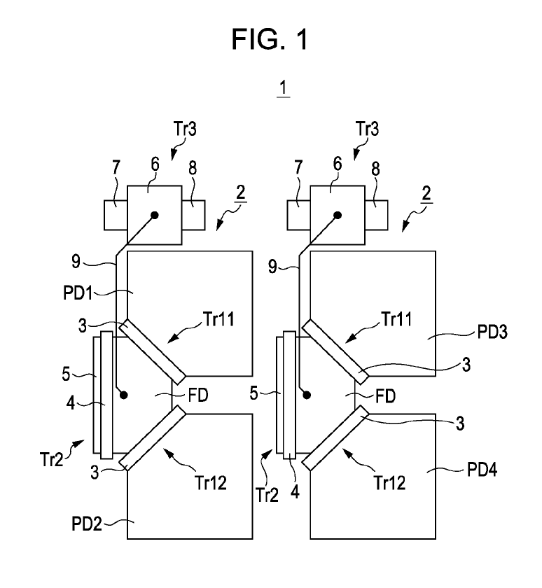

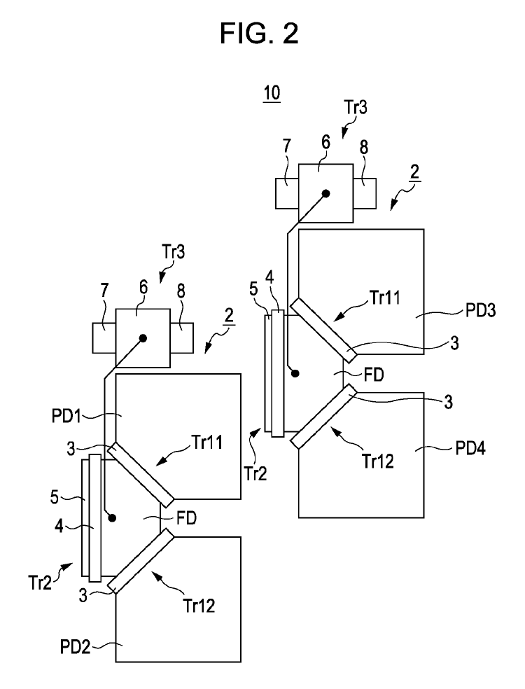

First, for the convenience of understanding of the ninth embodiment, a comparative example of a solid state image pickup device 34 of two-pixel-sharing type that two pixels share one floating diffusion, one amplifier transistor, and one select transistor before improvement will be described with reference to FIG. 45. The solid state image pickup device 34 has an exemplary configuration including a waveguide 111. The solid state image pickup device 34 is configured by adding a waveguide 111 to each pixel in the above-described solid state image pickup device 1 shown in FIG. 1. The other configuration is similar to that described with reference to FIG. 1. In FIG. 45, like reference signs refer like components in FIG. 1. In the solid state image pickup device 34, in a unit pixel group 2 of two-pixel-sharing type that two pixels share one floating diffusion, one amplifier transistor, and one select transistor, transfer gate electrodes 3 are asymmetric to each other with respect to the boundary between adjacent pixels. In particular, transfer gate electrodes 3 of pixels B and Gr are asymmetric to each other with respect to the boundary between the pixels B and Gr, and transfer gate electrodes 3 of pixels Gb and R are asymmetric to each other with respect to the boundary between the pixels Gb and R. Assuming groups of four pixels including a red pixel R, first and second green pixels Gb and Gr, and a blue pixel Gb with Bayer pattern, since the layouts of the transfer gate electrodes 3 are asymmetric to each other in the base layer, the difference in sensitivity between the green pixels Gb and Gr appears, and color shading may occur.

Referring to FIG. 44, a solid state image pickup device 69 according to the ninth embodiment has a pixel section in which unit pixel groups 71 of two-pixel-sharing type that two pixels share one floating diffusion, one amplifier transistor, and one select transistor, are repeatedly two-dimensionally arrayed. Each unit pixel group 71 of two-pixel-sharing type includes two photo diodes PD1 and PD2 (or PD3 and PD4), two transfer transistors Tr11 and Tr12, a floating diffusion FD, a reset transistor Tr2, and an amplifier transistor Tr3. Waveguides 78 are respectively formed for the photo diodes PD1 and PD2 (or PD3 and PD4). In this embodiment, since the color filter with Bayer pattern is used, a unit pixel group 71 of two-pixel-sharing type including the red pixel R and the first green pixel Gb, and a unit pixel group 71 of two-pixel-sharing type including the blue pixel B and the second green pixel Gr are repeatedly arrayed. Adjacent two unit pixel groups 71 of two-pixel-sharing type define a group of four pixels Gr, R, Gb, and B.

The transfer transistors Tr11 and Tr12 include respective transfer gate electrodes 70 made of polysilicon, respective photo diodes PD (PD1, PD2, PD3, PD4), and a floating diffusion FD. The reset transistor Tr2 includes a reset gate electrode 72 made of polysilicon, the floating diffusion FD, and a source region 73. The amplifier transistor Tr3 includes an amplifier gate electrode 74 made of polysilicon, a source region 75, and a drain region 76. The floating diffusion FD and the amplifier gate electrode 74 are connected to one another by a wiring portion 77. The source region 7 of the amplifier transistor Tr3 is connected to a vertical signal line (not shown).

In this embodiment, waveguides 78 in the respective pixels R, G, Gr, and B are shifted in directions in which the base layer having asymmetric layouts, i.e., in this embodiment, the base layer including the transfer gate electrodes 70 made of polysilicon hardly affects the waveguides 78. In this embodiment, the waveguides 78 of the first green pixel Gb and the blue pixel B are shifted horizontally rightward, and the waveguides 78 of the second green pixel Gr and the red pixel R are shifted vertically downward. The shift directions in this embodiment are merely examples. Any shift direction may be selected depending on the asymmetric arrangement of the base layer. The configuration according to any of the fourth to eighth embodiments may be also selected. When the four pixels R, Gb, Gr, and B define a group, the layout of the waveguides 78 in each group is equivalent in an entire pixel section.

With the solid state image pickup device 69 according to the ninth embodiment, since the waveguides 78 of the respective pixels are distant from the transfer gate electrodes 70 by which the waveguides 78 are affected. Thus, the difference in sensitivity between the green pixels Gb and Gr, and color shading can be decreased. Optical symmetry can be provided for the respective pixels, and a solid state image pickup device with high image quality can be provided.

### 10. Tenth Embodiment

Exemplary Configuration of Solid State Image Pickup Device

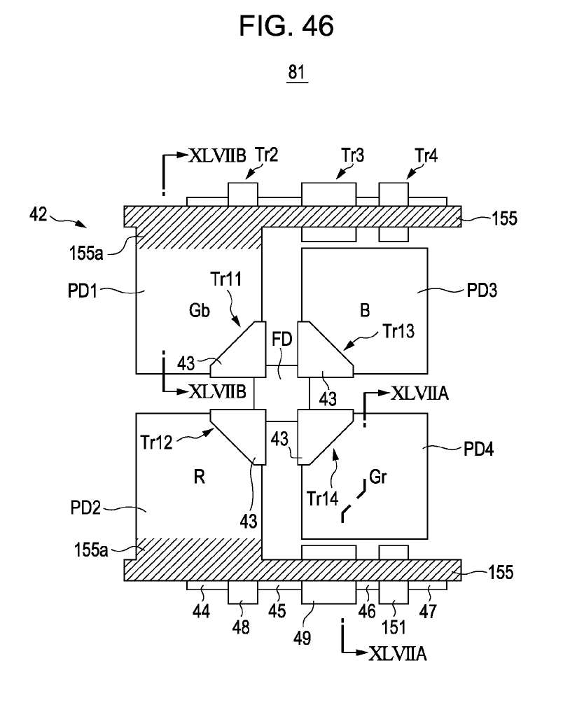

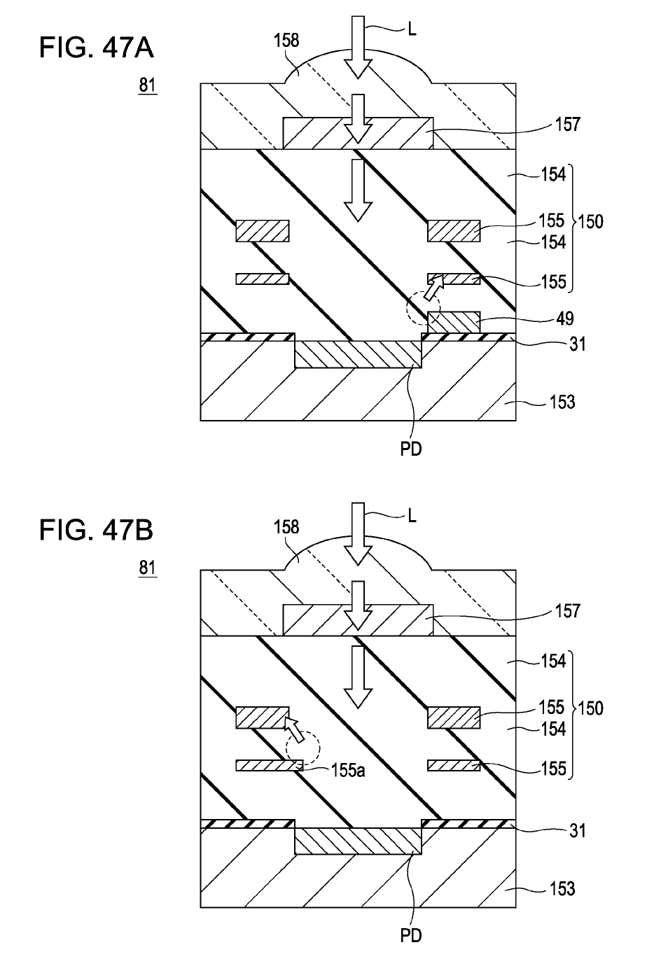

FIGS. 46, 47A, and 47B each illustrate a solid state image pickup device according to a tenth embodiment of the present invention. A solid state image pickup device of this embodiment is a MOS solid state image pickup device of four-pixel-sharing type that four pixels share one floating diffusion, one amplifier transistor, and one select transistor. FIG. 47A is a schematic cross-sectional view taken along line XLVIIA-XLVIIA in FIG. 46. FIG. 47B is a schematic cross-sectional view taken along line XLVIIB-XLVIIB in FIG. 46.

This embodiment does not use a waveguide as adjusting means, but uses a wiring portion to adjust a light amount and hence to obtain optical symmetry.

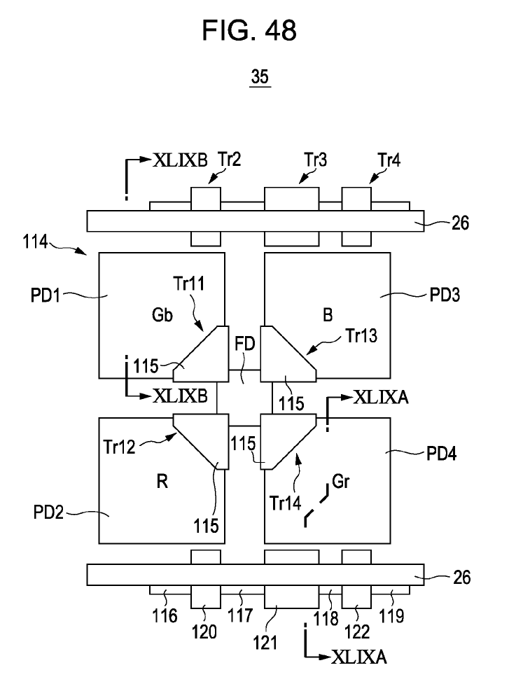

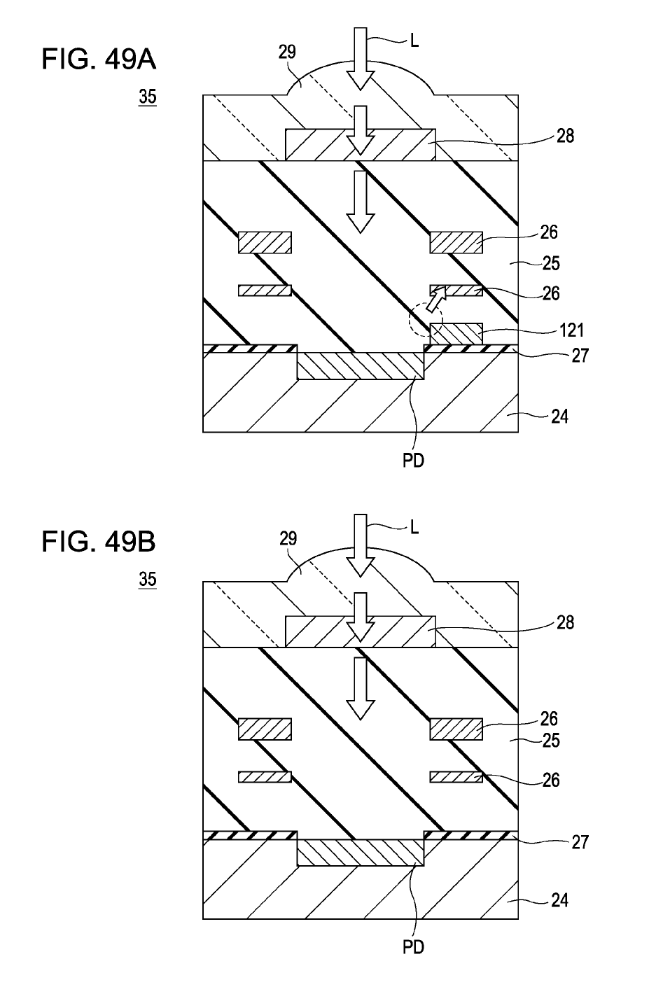

First, for the convenience of understanding of the tenth embodiment, a comparative example of a solid state image pickup device 35 of four-pixel-sharing type that four pixels share one floating diffusion, one amplifier transistor, and one select transistor before improvement will be described with reference to FIGS. 48, 49A, and 49B. A unit pixel group 114 of the solid state image pickup device 35 of the comparative example is similar to the configuration shown in FIG. 62 except that the solid state image pickup device 35 does not have a waveguide in areas above photo diodes PD (PD1 to PD4). In a plan view in FIG. 48, a wiring portion 26 is added. The wiring portion 26 is arranged so as not to be located above the photo diode PD. Referring to FIGS. 48, 49A, and 49B, like reference signs refer like components in FIGS. 62, 63A, and 63B, and the redundant description will be omitted.

In a unit pixel group 114 of the solid state image pickup device 35 of the comparative example, referring to the cross-sectional view in FIG. 49A taken along line XLIXA-XLIXA in FIG. 48, part of incident light incident on a second green pixel Gr is eclipsed by an amplifier gate electrode 121 in the base layer and arranged near a photo diode PD4. In contrast, referring to the cross-sectional view in FIG. 49B taken along line XLIXB-XLIXB in FIG. 48, light incident on a first green pixel Gb is not eclipsed by the gate electrode is the base layer, and is incident on a photo diode PD1. Incident light incident on a blue pixel B is eclipsed by the amplifier gate electrode 121. Incident light incident on a first green pixel Gb is not eclipsed by the amplifier gate electrode 121. Accordingly, the amount of incident light on the green pixel Gr is different from the amount of incident light on the green pixel Gb. Hence, a difference in sensitivity appears. Also, a difference in amount of incident light appears between the pixels Gr and B, and the pixels Gb and R. Optical asymmetry occurs.

A solid state image pickup device 81 according to the tenth embodiment, referring to FIGS. 46, 47A, and 47B, the configuration of a unit pixel group 42 of four-pixel-sharing type that four pixels share one floating diffusion, one amplifier transistor, and one select transistor is similar to the configuration of the fourth embodiment shown in FIGS. 31A, 31B, and 32 except for waveguides and wiring portions. In particular, referring to FIG. 46, the solid state image pickup device 81 according to the tenth embodiment includes a unit pixel group 42 of four-pixel-sharing type that four pixels share one floating diffusion, one amplifier transistor, and one select transistor, in which four photo diodes PD serving as photoelectric transducers are shared by a single pixel transistor unit. More specifically, the unit pixel group 42 includes four photo diodes PD (PD1 to PD4), four transfer transistors Tr (Tr11 to Tr14), and a single floating diffusion FD. Further, the unit pixel group 42 includes a single reset transistor Tr2, an amplifier transistor Tr3, and a select transistor Tr4. A waveguide is not formed above the photo diode PD of each pixel.

The floating diffusion FD is arranged at the center of the four photo diodes PD1 to PD4 in an array of 2×2. Transfer gate electrodes 43 made of polysilicon are arranged between the floating diffusion FD and the photo diodes PD1 to PD4. Thus, the four transfer transistors Tr11 to Tr14 for the four photo diodes PD are formed. The reset transistor Tr2, the amplifier transistor Tr3, and the select transistor Tr4 are continuously horizontally arranged below the four photo diodes PD1 to PD4.

As shown in FIGS. 47A and 47B, in each of the pixels R, Gr, Gb, and B, a photo diode PD serving as a photoelectric transducer is formed on a surface of a semiconductor substrate 153, and a wiring layer 150 is formed on the semiconductor substrate 153 with an interlayer insulating film 154 interposed therebetween. The wiring layer 150 includes a plurality of layers of wiring portions 155. Also, a color filter layer 157 and a microlens 158 (also called on chip lens) are laminated on the wiring layer 150.

This embodiment uses the wiring portions 155 as adjusting means for obtaining optical symmetry. In this embodiment, a protruding portion 155a protrudes from the wiring portion 155 in an upper layer. The protruding portion 155a shields light for parts of photo diodes PD1 and PD2 of a first green pixel Gb and a red pixel R which are not affected by amplifier gate electrodes in a base layer. The adjustment amount of the incident light amount by the protruding portion 155a, that is, the protruding amount by which the protruding portion 155a overlaps with each of the photo diodes PD1 and PD2 is determined such that the light incident amount for each of the photo diodes PD1 and PD2 is equivalent to the other photo diodes PD3 and PD4. The layout of the protruding portion 155a of the wiring portion 155 is equivalent for unit pixel groups 42 in an entire pixel section 40.

The other configuration is similar to that described with reference to FIGS. 31A, 31B, and 32. Referring to FIGS. 46, 47A, and 47B, like reference signs refer like components in FIGS. 31A, 31B, and 32, and the redundant description will be omitted.

With the solid state image pickup device 81 according to the tenth embodiment, the protruding amount of the protruding portion 155a of the wiring portion 155 is adjusted for the pixel that is not affected by the amplifier gate electrode 49, in this embodiment, the first green pixel Gb and the red pixel R, thereby adjusting the incident light amount. Accordingly, the difference in sensitivity between the first and second green pixels Gb and Gr can be decreased or eliminated. Also, the incident light amounts for the respective pixels R, Gr, Gb, and B can be equalized. Also, color shading can be decreased. Thus, optical symmetry can be obtained, and a solid state image pickup device with high image quality can be provided.

### 11. Eleventh Embodiment

Exemplary Configuration of Solid State Image Pickup Device

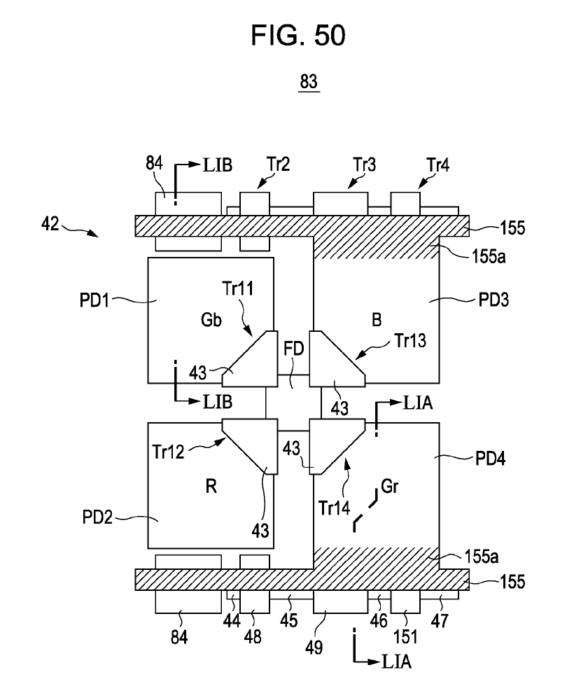

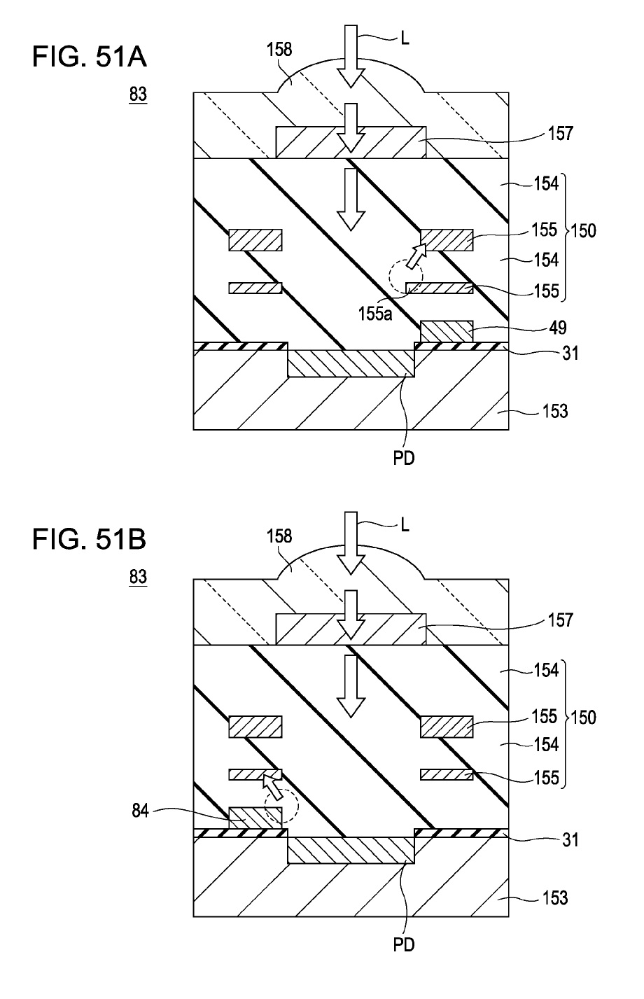

FIGS. 50, 51A, and 51B each illustrate a solid state image pickup device according to an eleventh embodiment of the present invention. A solid state image pickup device of this embodiment is a MOS solid state image pickup device of four-pixel-sharing type that four pixels share one floating diffusion, one amplifier transistor, and one select transistor. This embodiment does not use a waveguide, but uses a dummy electrode made of polysilicon as adjusting means to obtain optical symmetry.

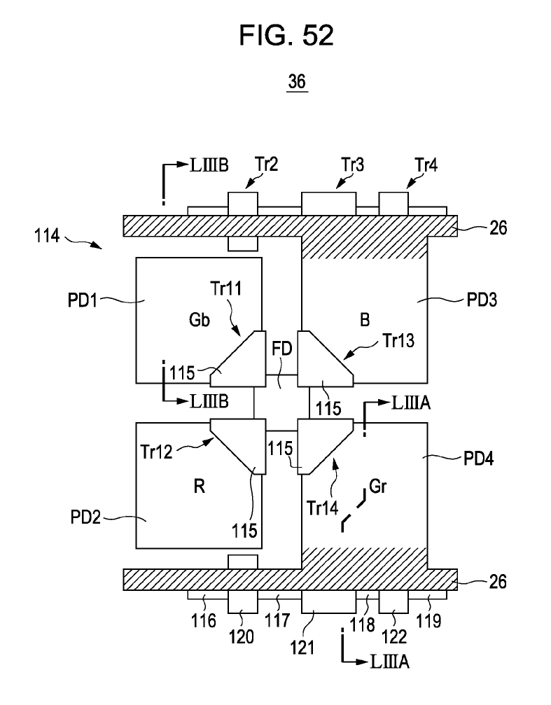

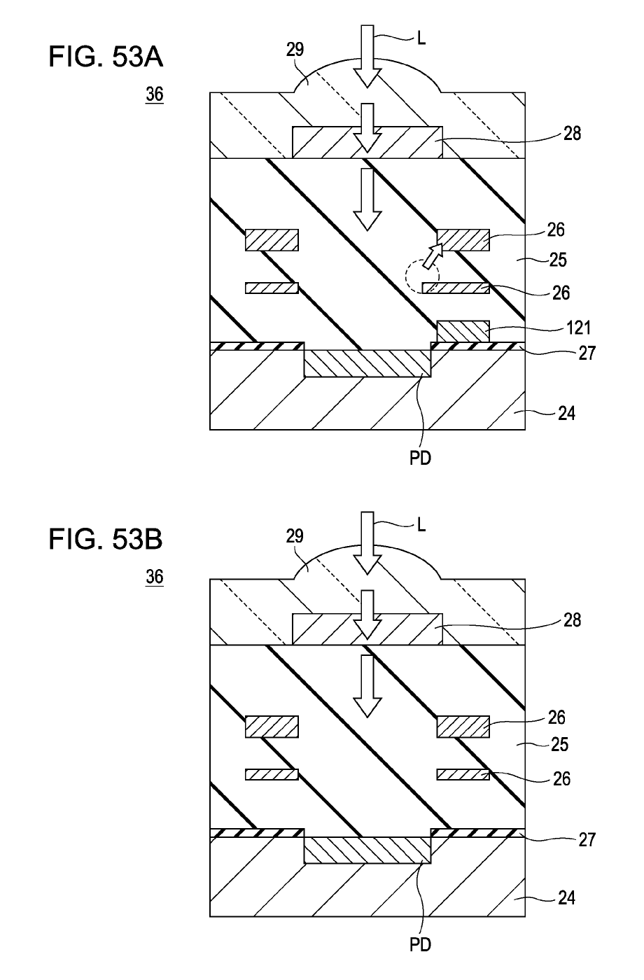

First, for the convenience of understanding of the tenth embodiment, a comparative example of a solid state image pickup device 36 of four-pixel-sharing type that four pixels share one floating diffusion, one amplifier transistor, and one select transistor without a waveguide before improvement will be described with reference to FIGS. 52, 53A, and 53B. The unit pixel group 114 of the solid state image pickup device 36 of the comparative example is similar to the configuration shown in FIGS. 48, 49A, and 49B except that the solid state image pickup device 36 does not have a waveguide in areas above photo diodes PD (PD1 to PD4), and the layouts of a waveguide and a wiring portion are omitted. In the solid state image pickup device 36, the layouts of wiring portions 26 are asymmetric. In this example, in the unit pixel group 114, wiring portions 26 are formed to overlap with parts of a blue pixel B and a second green pixel Gr. Referring to FIGS. 52, 53A, and 53B, like reference signs refer like components in FIGS. 48, 49A, and 49B, and the redundant description will be omitted.

As described with the solid state image pickup device 36 of the comparative example, if the wiring portions 26 are inevitably asymmetric, part of incident light incident on the blue pixel B and the second green pixel Gr is eclipsed by the wiring portions 26. The amount of incident light may vary among pixels, resulting in optical symmetry not being provided.

A solid state image pickup device 83 according to the eleventh embodiment has a pixel section 40 in which unit pixel groups 42 of four-pixel-sharing type that four pixels share one floating diffusion, one amplifier transistor, and one select transistor with no waveguide provided above photo diodes PD are arrayed in a similar manner to the configuration described in the tenth embodiment. The layouts of wiring portions 155 are asymmetric in a similar manner to the comparative example in FIGS. 52, 53A, and 53A. In particular, the wiring portions 155 are formed to overlap with parts of a blue pixel B and a second green pixel Gr.

This embodiment uses dummy electrodes 84 made of polysilicon and serving as adjusting means for obtaining optical symmetry. The dummy electrodes 84 are formed simultaneously with gate electrodes of a pixel transistor. That is, in this embodiment, the dummy electrodes 84 formed near photo diodes PD1 and PD2 of a first green pixel Gb and a red pixel R which are not affected by the wiring portions 155. Each dummy electrode 84 is formed at a position at which part of incident light is eclipsed by the dummy electrode 84. The adjustment amount of the incident light amount by the dummy electrode 84, that is, the lengths along the photo diodes PD1 and PD2 are determined such that the light incident amount for each of the photo diodes PD1 and PD2 is equivalent to the other photo diodes PD3 and PD4. The layout of the dummy electrode 84 is equivalent for unit pixel groups 42 in an entire pixel section 40.

The other configuration is similar to that described with reference to FIGS. 46, 47A, and 47B. Referring to FIGS. 50, 51A, and 51B, like reference signs refer like components in FIGS. 46, 47A, and 47B, and the redundant description will be omitted.

With the solid state image pickup device 83 according to the eleventh embodiment, referring to FIG. 51A, part of incident light L incident on the second green pixel Gr is eclipsed by the protruding wiring portion 155, and hence the incident light amount for the second green pixel Gr is decreased. Similarly, part of incident light L incident on the blue pixel B is eclipsed by a protruding portion 155a of the wiring portion 155, resulting in the incident light amount for the blue pixel B being decreased. In contrast, referring to FIG. 51B, regarding the first green pixel Gb that is not affected by the wiring portion 155, part of incident light L incident on the first green pixel Gb is eclipsed by the dummy electrode 84, resulting in the incident light amount for the first green pixel Gb being decreased. The decrease amounts of the incident light amounts can be equivalent for the pixels by controlling the size of the dummy electrode 84.

With the solid state image pickup device 83 according to the eleventh embodiment, if the wiring portions 155 are inevitably asymmetric in the unit pixel group 42, the dummy electrodes 84 may be arranged in the base layer, at positions close to the pixels which are not affected by the wiring portions 155. Thus, optical symmetry can be obtained. That is, the difference in sensitivity between the first and second green pixels Gb and Gr can be decreased or eliminated. Also, the incident light amounts for the respective pixels R, Gr, Gb, and B can be equalized. Also, color shading can be decreased.

### 12. Twelfth Embodiment

Exemplary Configuration of Solid State Image Pickup Device

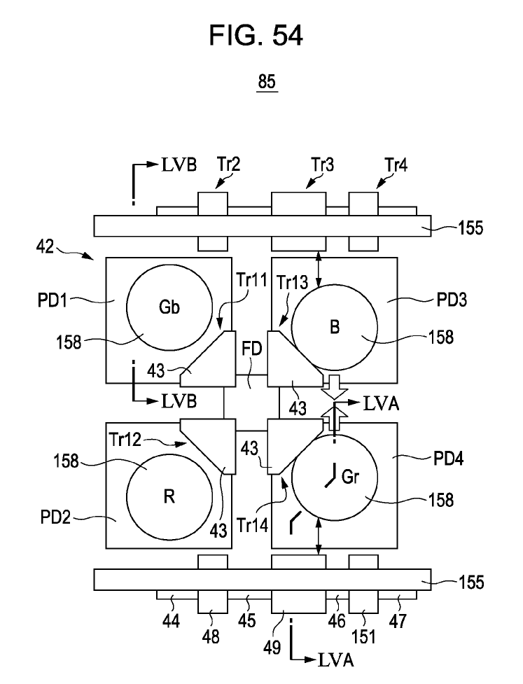

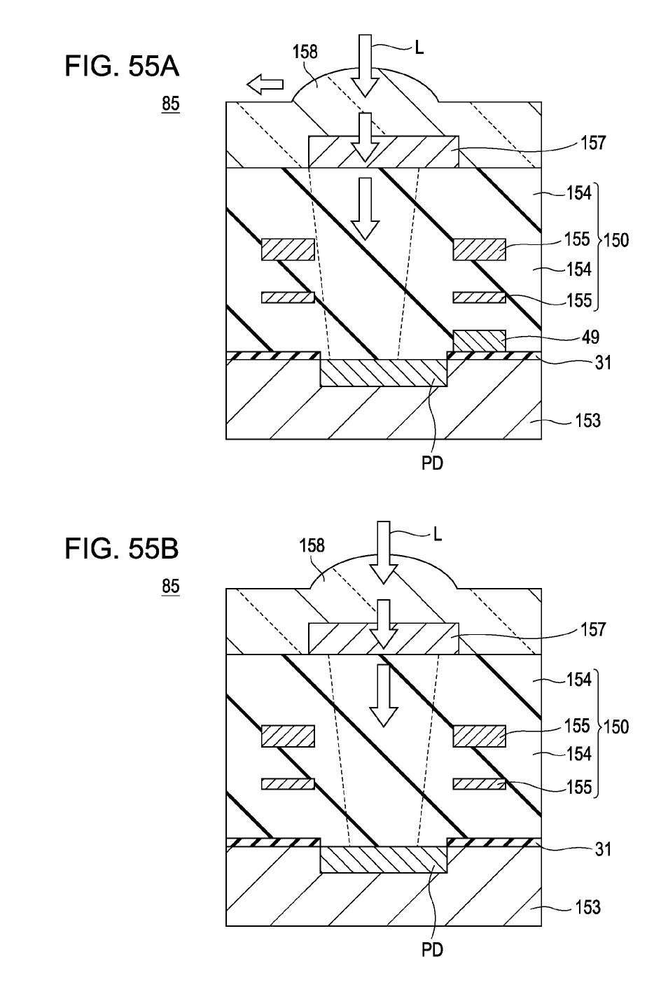

FIGS. 54, 55A, and 55B each illustrate a solid state image pickup device according to a twelfth embodiment of the present invention. A solid state image pickup device of this embodiment is a MOS solid state image pickup device of four-pixel-sharing type that four pixels share one floating diffusion, one amplifier transistor, and one select transistor. This embodiment does not use a waveguide, but uses a microlens as adjusting means to obtain optical symmetry.

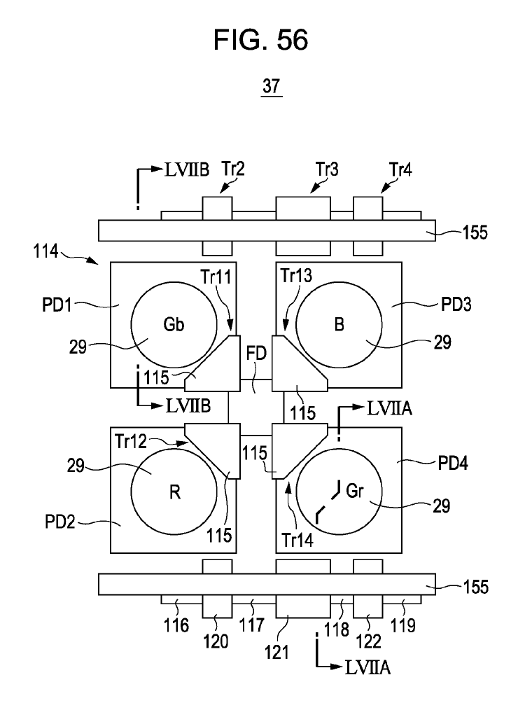

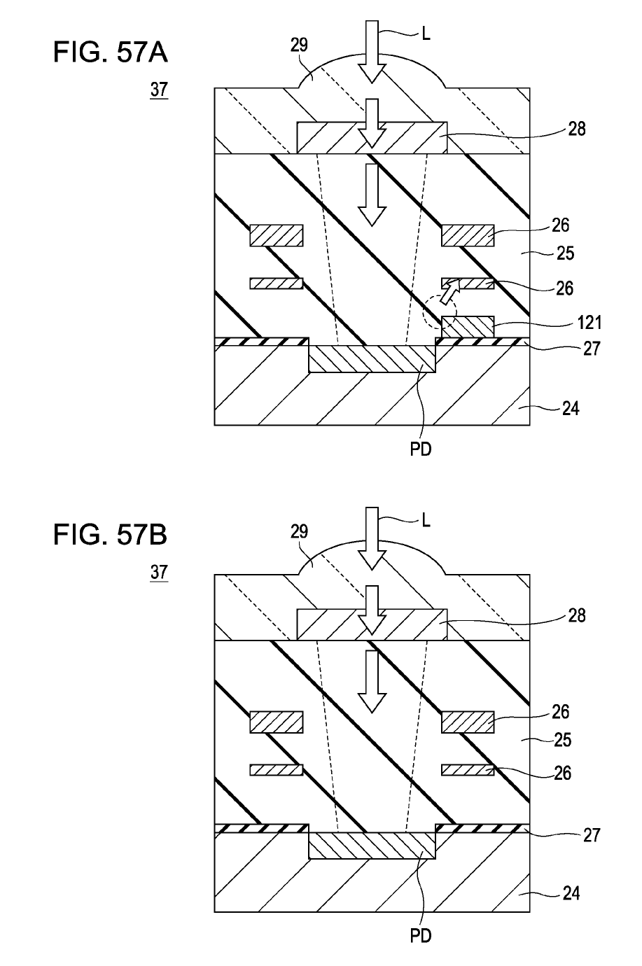

First, for the convenience of understanding of the twelfth embodiment, a comparative example of a solid state image pickup device 37 of four-pixel-sharing type that four pixels share one floating diffusion, one amplifier transistor, and one select transistor without a waveguide before improvement will be described with reference to FIGS. 56, 57A, and 57B. The unit pixel group 114 of the solid state image pickup device 37 of the comparative example is similar to the configuration shown in FIGS. 48, 49A, and 49B except that the solid state image pickup device 35 does not have a waveguide in areas above photo diodes PD (PD1 to PD4). Referring to FIGS. 56, 57A, and 57B, like reference signs refer like components in FIGS. 48, 49A, and 49B, and the redundant description will be omitted.

In a unit pixel group 114 of the solid state image pickup device 37 of the comparative example, referring to the cross-sectional view in FIG. 57A taken along line LVIIA-LVIIA in FIG. 56, part of incident light incident on a second green pixel Gr is eclipsed by an amplifier gate electrode 121 in a base layer and arranged near a photo diode PD4. In contrast, referring to the cross-sectional view in FIG. 57B taken along line LVIIB-LVIIB in FIG. 56, light incident on a first green pixel Gb is not eclipsed by the gate electrode in the base layer, and is incident on a photo diode PD1. Incident light incident on a blue pixel B is eclipsed by the amplifier gate electrode 121. Incident light incident on a first green pixel Gb is not eclipsed by the amplifier gate electrode 121. Accordingly, the amount of incident light on the green pixel Gr is different from the amount of incident light on the green pixel Gb. Hence, a difference in sensitivity appears. Also, a difference in amount of incident light appears between the pixels Gr and B, and the pixels Gb and R. Optical asymmetry occurs.

Referring to FIGS. 54, 55A, and 55B, a solid state image pickup device 85 according to the twelfth embodiment includes a unit pixel group 42 of four-pixel-sharing type that four pixels share one floating diffusion, one amplifier transistor, and one select transistor having no waveguide above a photo diode PD. A plurality of unit pixel groups 42 of four-pixel-sharing type are arrayed to define a pixel section 40. As described above, the unit pixel group 42 includes four photo diodes PD (PD1 to PD4), four transfer transistors Tr (Tr11 to Tr14), and a single floating diffusion FD. Further, the unit pixel group 42 includes a single reset transistor Tr2, an amplifier transistor Tr3, and a select transistor Tr4.

As shown in FIGS. 55A and 55B, in each of the pixels R, Gr, Gb, and B, a photo diode PD serving as a photoelectric transducer is formed on a surface of a semiconductor substrate 153, and a wiring layer 150 is formed on the semiconductor substrate 153 with an interlayer insulating film 154 interposed therebetween. The wiring layer 150 includes a plurality of layers of wiring portions 155. Also, a color filter layer 157 and a microlens 158 (also called on chip lens) are stacked on the wiring layer 150.

The solid state image pickup device 85 in this embodiment uses the microlens 158 as adjusting means for obtaining optical symmetry. In this embodiment, only microlenses 158 of a second green pixel Gr and a blue pixel B, which are affected by amplifier gate electrodes 49 as a base layer, are shifted to positions at which incident light L transmitted through the microlenses 158 are not eclipsed by the gate electrodes. In particular, the focal points of the microlenses 158 of the second green pixel Gr and the blue pixel B are shifted away from the amplifier gate electrodes 49. The layout of the microlenses 158 in a unit pixel group 42 is equivalent for unit pixel groups 42 in the entire pixel section 40.

In the twelfth embodiment, as shown in FIG. 55A, the microlens 158 of the second green pixel Gr is shifted away from the amplifier gate electrode. Hence, incident light L for the second green pixel Gr is not eclipsed by the amplifier gate electrode 49, and is incident on the photo diode PD4. Also, the microlens 158 of the blue pixel B is shifted, in a similar manner to the second green pixel Gr. In contrast, the microlens 158 of the first green pixel Gb is not shifted, and incident light is incident on the photo diode PD1 without being affected by the gate electrode as a base layer. Also, incident light is incident on the red pixel R without being affected by the gate electrode as a base layer, in a similar manner to the first green pixel Gb.

With the solid state image pickup device 85 according to the twelfth embodiment, the light amount can be adjusted by shifting the microlenses 158 of the pixel Gr and B. Thus, the difference in sensitivity between the first and second green pixels Gb and Gr can be equalized. Also, the incident light amounts for the respective pixels R, Gr, Gb, and B can be equalized. Also, color shading can be decreased. Thus, optical symmetry can be obtained.

### 13. Thirteenth Embodiment

Exemplary Configuration of Solid State Image Pickup Device

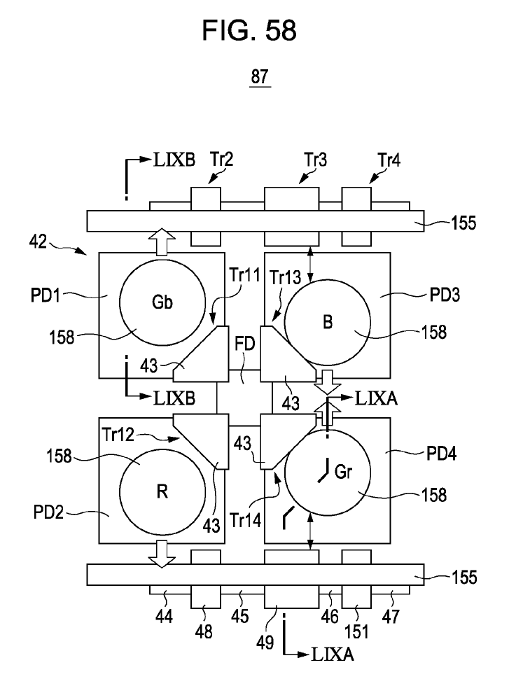

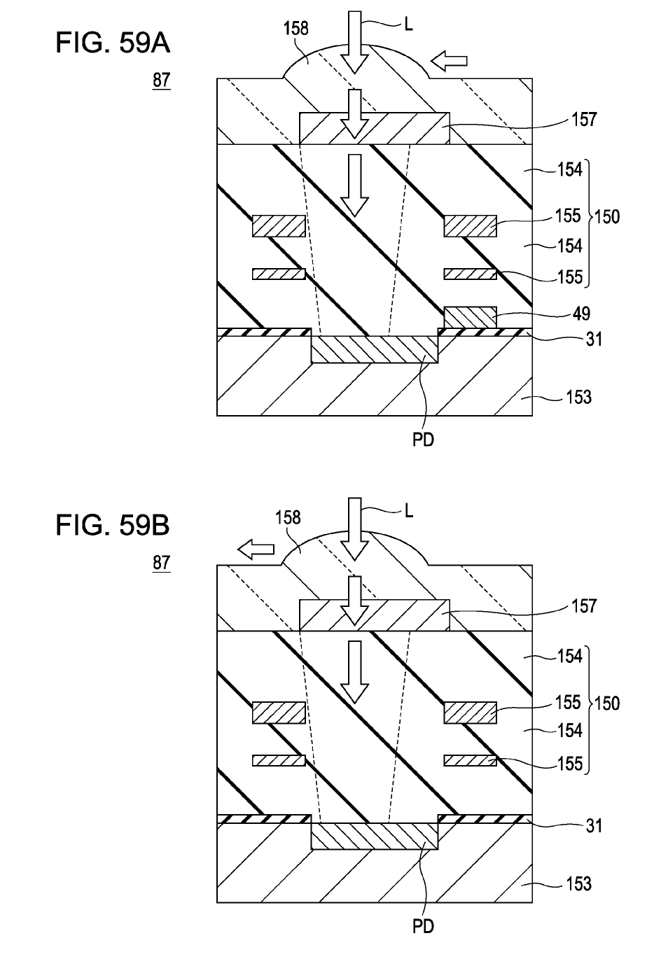

FIGS. 58, 59A, and 59B each illustrate a solid state image pickup device according to a thirteenth embodiment of the present invention. A solid state image pickup device of this embodiment is a MOS solid state image pickup device of four-pixel-sharing type. This embodiment provides an improvement if adjustment for the difference in sensitivity is not sufficient even by the light amount adjustment according to the twelfth embodiment.

A solid state image pickup device 87 according to the thirteenth embodiment includes a unit pixel group 42 of four-pixel-sharing type that four pixels share one floating diffusion, one amplifier transistor, and one select transistor, in which microlenses 158 of a second green pixel Gr and a blue pixel B are shifted away from amplifier gate electrodes 49 in a base layer. Also, microlenses 158 of a first green pixel Gb and a red pixel R are shifted toward wiring portions 155 in the base layer.

With the solid state image pickup device 87 according to the thirteenth embodiment, the microlenses 158 of the second green pixel Gr and the blue pixel B are shifted away from the amplifier gate electrodes 49, to move the focal points. Hence, the loss in incident light amount is restricted, and the sensitivity is increased. In contrast, the microlenses 158 of the first green pixel Gb and the red pixel R are shifted toward the wiring portions 155, so that adjustment is performed to decrease the incident light amount by the wiring portions 155. Hence, the sensitivity is decreased. As a result, the difference in sensitivity between the first and second green pixels Gb and Gr can be decreased. The incident light amounts for the respective pixels R, Gr, Gb, and B can be equalized. Also, color shading can be decreased. Thus, optical symmetry can be obtained.

### 14. Fourteenth Embodiment

Exemplary Configuration of Solid State Image Pickup Device

Though not shown, a solid state image pickup device with the configuration for obtaining optical symmetry as described in any of the fourth to thirteenth embodiments may be applied to a CCD solid state image pickup device. Even when the configuration is applied to the CCD solid state image pickup device, light amount adjustment similar to that described above can be performed, and optical symmetry can be obtained for respective pixels.

In the above-described embodiments, the configuration has been applied to a solid state image pickup device of two-pixel-sharing type that two pixels share one floating diffusion, one amplifier transistor, and one select transistor or four-pixel-sharing type that four pixels share one floating diffusion, one amplifier transistor, and one select transistor. However, the configuration can be applied to a solid state image pickup device of another-number-of-pixel-sharing type that another-number-of-pixels share one floating diffusion, one amplifier transistor, and one select transistor.

In the above-described embodiments, the configuration is applied to a solid state image pickup device having a color filter 101 with Bayer pattern. However, the configuration may be applied to a solid state image pickup device having a color filter layer 102 with the honeycomb pattern of an oblique array shown in FIG. 61.

In the above-described embodiments, the configuration is applied to a color solid state image pickup device. However, the configuration may be applied to a single-color (such as black and white) solid state image pickup device. In this case, a waveguide, a wiring portion, a dummy electrode, an on chip lens, etc., may be used as adjusting means.

### 15. Fifteenth Embodiment

Exemplary Configuration of Electronic Device

The solid state image pickup device according to any of the above-described embodiments may be applied to an electronic device, such as a camera system like a digital camera or a video camera; a mobile phone having an image pickup function; or another device having an image pickup function.

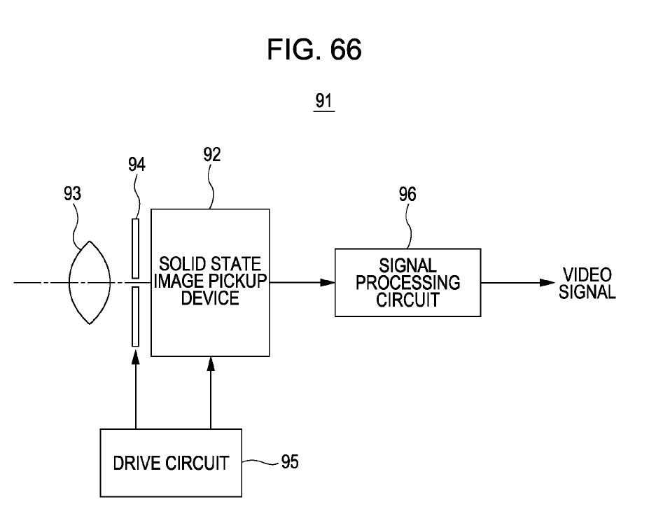

FIG. 66 illustrates a fifteenth embodiment, in which the solid state image pickup device is applied to a camera as an example of the electronic device. The camera in this embodiment is, for example, a video camera that can capture a still image or a movie. A camera 91 in this embodiment includes a solid state image pickup device 92, an optical system 93 that guides incident light to a photo-sensor of the solid state image pickup device 92, and a shutter device 94. Also, the camera 91 includes a drive circuit 95, and a signal processing circuit 96 that processes an output signal from the solid state image pickup device 92.

The solid state image pickup device 92 may be any of the solid state image pickup devices according to the above-described embodiments. The optical system (optical lens) 93 causes image light (incident light) from an object to be focused on an image pickup surface of the solid state image pickup device 92. Accordingly, a signal charge is accumulated in the solid state image pickup device 92 for a predetermined period. The optical system 93 may be an optical lens system including a plurality of optical lenses. The shutter device 94 controls a light irradiation period and a light shielding period for the solid state image pickup device 92. The drive circuit 95 supplies drive signals for controlling a transfer operation of the solid state image pickup device 92, and a shutter operation of the shutter device 94. In response to the drive signal (timing signal) supplied from the drive circuit 95, a signal from the solid state image pickup device is transferred. The signal processing circuit 96 performs various signal processing. A video signal after the signal processing is stored in a storage medium such as a memory, or is output to a monitor.

With the electronic device such as the camera according to the fifteenth embodiment, optical symmetry can be obtained, for example, such that the sensitivities of the green pixels Gb and Gr can be equalized in the solid state image pickup device 92, and hence image quality can be increased. Thus, a reliable electronic device can be provided.

Any of the above-described embodiments may be implemented with another of the embodiments. Optical symmetry can be obtained accordingly.

The present application contains subject matter related to that disclosed in Japanese Priority Patent Application JP 2009-081100 filed in the Japan Patent Office on Mar. 30, 2009, and Japanese Priority Patent Application JP 2009-240774 filed in the Japan Patent Office on Oct. 19, 2009, the entire content of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A solid state image pickup device comprising:
a pixel section defined by unit pixels arrayed in line and row directions of a semiconductor substrate,
wherein each of the unit pixels includes
a photoelectric transducer that is formed on the semiconductor substrate and converts incident light into a signal charge,
a waveguide that is formed above the photoelectric transducer and guides the incident light to the photoelectric transducer, and
a microlens that is formed above the waveguide and guides the incident light to an end of light incident side of the waveguide, and
wherein the waveguide has a columnar body with a constant cross section from the end of light incident side to an end of light exit side, and is arranged such that a center of rays of the incident light incident from the microlens on the end of light incident side of the waveguide is aligned with a central axis of the waveguide.

2. The solid state image pickup device according to claim 1, further comprising:
a color filter layer that is formed between the waveguide and the microlens and divides the incident light,
wherein pupil correction is performed for the microlens and the color filter layer on the basis of a reference color of the incident light.

3. The solid state image pickup device according to claim 1, wherein, for the photoelectric transducers on which incident light with equivalent wavelengths is incident in the pixel section, a shift amount of the central axis of each of the waveguides with respect to the center of the corresponding photoelectric transducer becomes larger toward outside from a center of the pixel section.

4. The solid state image pickup device according to claim 1, wherein, for the photoelectric transducers located at equivalent distances from a center of the pixel section, a shift amount of the central axis of each of the waveguides with respect to the center of the corresponding photoelectric transducer is smaller as a wavelength of light which is divided by the color filter layer and is incident on the photoelectric transducer is longer.

5. The solid state image pickup device according to claim 1, wherein the waveguide has a diameter that allows the incident light from the end of light exit side of the waveguide to be emitted on an area within a surface of the photoelectric transducer.

6. The solid state image pickup device according to claim 1, further comprising:
a unit pixel group,
wherein the unit pixel group includes
a first unit pixel including the photoelectric transducer on which light with a first wavelength divided by the color filter layer is incident,
a second unit pixel including the photoelectric transducer on which light with a second wavelength divided by the color filter layer is incident, the second wavelength being smaller than the first wavelength, and
a third unit pixel including the photoelectric transducer on which light with a third wavelength divided by the color filter layer is incident, the third wavelength being larger than the first wavelength, and
wherein, for the photoelectric transducers in the unit pixel group, a shift amount of a central axis of each of the waveguides with respect to a center of the corresponding photoelectric transducer is smaller as a wavelength of light divided by the color filter layer is smaller.

7. The solid state image pickup device according to claim 1,
wherein the waveguide includes
a first waveguide that defines a peripheral portion of the waveguide, and
a second waveguide that is formed inside the first waveguide and has a refractive index lower than a refractive index of the first waveguide.

8. A method of manufacturing a solid state image pickup device, the method comprising the steps of:
forming in a wiring layer a waveguide hole, the waveguide hole guiding incident light onto a photoelectric transducer that converts the incident light into a signal charge, the photoelectric transducer being formed at a semiconductor substrate, the wiring layer formed at the semiconductor substrate and including an interlayer insulating film having a plurality of layers of wiring portions;
filling the waveguide hole with a waveguide material film having a higher refractive index than a refractive index of the interlayer insulating film and forming a waveguide in the waveguide hole;
forming a color filter layer that divides the incident light, on the waveguide material film with a planarizing and insulating film interposed therebetween; and
forming a microlens on the color filter layer, the microlens guiding the incident light onto the photoelectric transducer,
wherein a plurality of unit pixels each having the photoelectric transducer are arrayed in line and row directions of the semiconductor substrate, to define a pixel section, and
wherein the waveguide formed for the corresponding photoelectric transducer has a columnar body with a constant cross section from an end of light incident side to an end of light exit side, and is arranged such that a center of rays of the incident light incident on the end of light incident side of the waveguide is aligned with a central axis of the waveguide.

9. The method of manufacturing the solid state image pickup device according to claim 8,
wherein the formation of the waveguide includes
forming a first waveguide on an inner surface of the waveguide hole, and
filling the waveguide hole having the first waveguide formed therein with a material having a lower refractive index than a refractive index of the first waveguide and forming a second waveguide.

10. An image pickup device comprising:
a light condensing optical unit that condenses incident light;
an image pickup unit including a solid state image pickup device that receives the light condensed by the light condensing optical unit and performs photoelectric transduction for the light; and
a signal processing unit that processes a signal obtained by the photoelectric transduction by the solid state image pickup device,
wherein the solid state image pickup device includes
a pixel section defined by unit pixels arrayed in line and row directions of a semiconductor substrate,
wherein the unit pixel group includes
a photoelectric transducer that is formed on the semiconductor substrate and converts incident light into a signal charge,
a waveguide that is formed above the photoelectric transducer and guides the incident light to the photoelectric transducer, and
a microlens that is formed above the waveguide and guides the incident light to an end of light incident side of the waveguide, and
wherein the waveguide has a columnar body with a constant cross section from the end of light incident side to an end of light exit side, and is arranged such that a center of rays of the incident light incident from the microlens on the end of light incident side of the waveguide is aligned with a central axis of the waveguide.

11. A solid state image pickup device comprising:
a pixel section in which a plurality of pixels are arrayed;
a base layer that is formed in a group of a plurality of pixels at a position below a light incidence surface of the group and has layouts including electrodes and wirings, the layouts being asymmetric with respect to a boundary between predetermined adjacent pixels; and
adjusting means for causing optical asymmetry between pixels due to the base layer to be optical symmetry.

12. The solid state image pickup device according to claim 11, wherein an adjustment direction and an adjustment amount of a positional shift of the adjusting means are equivalent in the entire pixel section.

13. The solid state image pickup device according to claim 12, further comprising:
a color filter layer that is formed above the photoelectrical transducer of the pixel and divides incident light;
an on chip lens on the color filter layer; and
a base layer formed below the color filter layer.

14. The solid state image pickup device according to claim 13,
wherein the pixel section includes a plurality of unit pixel groups, each of the unit pixel groups has a plurality of pixels that share a single predetermined transistor, and
wherein the asymmetric base layer is a base layer including a gate electrode and a wiring portion of the pixel transistor.

15. The solid state image pickup device according to claim 14,
wherein the adjusting means is a waveguide for each pixel,
wherein the color filter layer is formed above the waveguide,
wherein the base layer is a base layer located below the waveguide and including the gate electrode and the wiring portion, and
wherein, in a state in which the waveguides are arranged at a regular interval in the entire pixel section as a reference state, a waveguide of at least a specific pixel is shifted from a position in the reference state, in the unit pixel group, or in a plurality of the adjacent unit pixel groups.

16. The solid state image pickup device according to claim 15, wherein a waveguide of at least a first common color pixel is shifted away from a gate electrode of a shared pixel transistor located close to the waveguide, from among waveguides of common color pixels, from which the same color signals are output, so that a difference in sensitivity becomes equivalent between the common color pixels in the unit pixel group or in the plurality of adjacent unit pixel groups.

17. The solid state image pickup device according to claim 16, wherein a waveguide of at least a second common color pixel is shifted toward a gate electrode of a shared pixel transistor, from among the waveguides of the common color pixels, so that a difference in sensitivity becomes equivalent between the common color pixels in the unit pixel group or in the plurality of adjacent unit pixel groups.

18. The solid state image pickup device according to claim 14, wherein, for the photoelectric transducers located at equivalent distances from a center of the pixel section, waveguide pupil correction is performed such that a shift amount of the central axis of the waveguide with respect to the center of the photoelectric transducer is larger as a wavelength of light which is divided by the color filter layer and is incident on the photoelectric transducer is longer.

19. The solid state image pickup device according to claim 12,
wherein the adjusting means is a protruding portion of the wiring portion, and
wherein the protruding portion of the wiring portion protrudes to an area above a photoelectric transducer that does not affect the base layer, in the unit pixel group or in the plurality of adjacent unit pixel groups.

20. An electronic device comprising:
a solid state image pickup device;
an optical system that guides incident light onto a photoelectric transducer of the solid state image pickup device; and
a signal processing circuit that processes an output signal from the solid state image pickup device,
wherein the solid state image pickup device is the solid state image pickup device according to any one of claims 1 to 4.
